(19) United States
(12) Patent Application Publication
(10) Pub. No.: US 2017/0063351 A1
(43) Pub. Date: Mar. 2, 2017

(54) SEMICONDUCTOR DEVICE OR ELECTRONIC DEVICE INCLUDING THE SEMICONDUCTOR DEVICE

(71) Applicant: Semiconductor Energy Laboratory Co., Ltd., Atsugi-shi (JP)

(72) Inventor: Yoshiyuki KUROKAWA, Sagamihara (JP)

(21) Appl. No.: 15/245,366

(22) Filed: Aug. 24, 2016

(30) Foreign Application Priority Data
Aug. 31, 2015 (JP) 2015-170829

(51) Int. Cl. H03K 3/356; H02M 3/07; H04N 19/42; H01L 29/786

(52) U.S. Cl. CPC H03K 3/356104; H01L 29/7869; H02M 3/07; H04N 19/42

(57) ABSTRACT

To provide a semiconductor device with a small circuit size and low power consumption or an electronic device including the semiconductor device and compressing a large volume of image data. A semiconductor device of a Hopfield neural network is formed using neuron circuits and synapse circuits. The synapse circuit includes an analog memory and a writing control circuit, and the writing control circuit is formed using a transistor including an oxide semiconductor in a channel formation region. Thus, data retention lifetime of the analog memory can be extended and refresh operation for data retention can be omitted, so that power consumption of the semiconductor device can be reduced. The semiconductor device enables judgement whether learned image data and arbitrary image data match, are similar, or mismatch by comparing video data. Thus, motion compensation prediction, which is one of data compression methods, can be employed for image data.

### TECHNICAL FIELD

One embodiment of the present invention relates to a semiconductor device or an electronic device including the semiconductor device.

Note that one embodiment of the present invention is not limited to the above technical field. The technical field of the invention disclosed in this specification and the like relates to an object, a method, or a manufacturing method. Another embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a power storage device, an imaging device, a memory device, a processor, a converter, an encoder, a decoder, a tuner, an electronic device, a method for driving any of them, a method for manufacturing any of them, a method for testing any of them, and a system including any of them.

### BACKGROUND ART

A neural network is an information processing system modeled on a biological neural network. A computer having a higher performance than a conventional Neumann computer is expected to be provided by utilizing the neural network, and in these years, a variety of researches on a neural network formed over an electronic circuit have been carried out.

In the neural network, units which resemble neurons are connected to each other through units which resemble synapses. By changing the connection strength, a variety of input patterns are learned, and pattern recognition, associative storage, or the like can be performed at high speed. Furthermore, Non-Patent Document 1 discloses a technique relating to a chip having a self-learning function with the neural network.

As a screen of a television (TV) becomes larger, it is desired to be able to watch high-definition video. For this reason, ultra-high definition TV (UHDTV) broadcast has been increasingly put into practical use. Japan, which has promoted UHDTV broadcast, started 4K broadcast services utilizing a communication satellite (CS) and an optical line in 2015. The test broadcast of UHDTV (4K and 8K) by a broadcast satellite (BS) will start in the future. Therefore, various electronic devices which correspond to 8K broadcast are developed (see Non-Patent Document 2). In practical 8K broadcasts, 4K broadcasts and 2K broadcasts (full-high vision broadcast) will be also employed.

Imaging elements are provided in a wide variety of electronic devices such as digital cameras or mobile phones. As described above, UHDTV broadcast has been put into practical use, and accordingly, in recent years, the number of pixels in imaging elements has been increased. Accordingly, the volume of data treated in imaging also has been inevitably increased. Therefore, higher speed of reading or transfer of data has been required. A technique in which image data is compressed in order to deal with the increase in volume of image data in accordance with the increase in number of pixels in imaging elements has been known. Patent Document 1 discloses an imaging element module in which differential data between captured image data of the previous period and captured image data of the present period is calculated in taking a moving image or in continuous shooting and data is compressed.

### REFERENCE

### Patent Document

[Patent Document 1] Japanese Published Patent Application No. 2009-296353

### Non-Patent Document

[Non-Patent Document 1] Y. Arima et al., “A Self-Learning Neural Network Chip with 125 Neurons and 10K Self-Organization Synapses,” IEEE Journal of Solid-State Circuits, Vol. 26, No. 4, April 1991, pp. 607-611
[Non-Patent Document 2] S. Kawashima et al., “13.3-In. 8K×4K 664-ppi OLED Display Using CAAC-OS FETs,” SID 2014 DIGEST, pp. 627-630

### DISCLOSURE OF INVENTION

In order to form a neural network using a semiconductor device, a synapse circuit that stores a connection strength between a first neuron circuit and a second neuron circuit and performs a multiply-accumulate operation in which output of the first neuron circuit and the connection strength are multiplied and accumulated needs to be provided. In other words, a memory that holds a connection strength, a multiplier circuit and an adder circuit that perform a multiply-accumulate operation, and the like are necessarily mounted on the semiconductor device.

In the case where the memory, the multiplier circuit, the adder circuit, and the like are formed using digital circuits, the memory needs to be able to store multi-bit data and moreover, the multiplier circuit and the adder circuit need to be able to perform multi-bit arithmetic operation. In other words, a large-scale memory, a large-scale multiplier circuit, and a large-scale adder circuit are required to form a neural network using digital circuits; therefore, the chip area of the digital circuits is increased.

Furthermore, in the case where the memory, the multiplier circuit, the adder circuit, and the like are formed using analog circuits, the memory needs to be able to store analog data and moreover, the multiplier circuit and the adder circuit need to be able to perform analog arithmetic operation. That is, an analog memory is necessarily used as the memory. For example, a memory cell of a dynamic random access memory (DRAM) can be used as an analog memory; however, a capacitor having large capacitance or a circuit that can perform refresh operation regularly is needed, and the chip area of the analog circuit is increased. Furthermore, since refresh operation of analog data is performed regularly, power consumption is also increased.

As a video encoding method in 8K broadcast, a new standard of H.265|MPEG-H high efficiency video coding (hereinafter referred to as HEVC) is employed. The resolution (the number of pixels in the horizontal and perpendicular directions) of an image in 8K broadcast is 7680×4320, which is 4 times as high as those in 4K (3840×2160) broadcast and is 16 times as high as those in 2K (1920×1080) broadcast. Thus, a large volume of image data are required to be processed in 8K broadcast.

In order to transmit a large volume of image data for 8K broadcast in a limited broadcast band, compression (encoding) of the image data is important. An encoder enables the compression of image data by intra-frame prediction (acquisition of differential data between adjacent pixels), inter-frame prediction (acquisition of differential data in each pixel between frames), motion-compensated prediction (acquisition of differential data in each pixel between a predicted image of a moving object based on a predicted motion and an actual image of the object based on the actual motion), orthogonal transform (discrete cosine transform), encoding, or the like.

Highly efficient compression of image data is required to transmit broadcast signals in real time. That is, a highly efficient encoder is required to transmit a large volume of image data for 8K broadcast.

An object of one embodiment of the present invention is to provide a novel semiconductor device. Another object of one embodiment of the present invention is to provide a module including the novel semiconductor device. Another object of one embodiment of the present invention is to provide an electronic device using the module including the novel semiconductor device. Another object of one embodiment of the present invention is to provide a novel module, a novel electronic device, a novel system, and the like.

Another object of one embodiment of the present invention is to provide a novel semiconductor device having a learning function, a pattern recognition function, or the like. Another object of one embodiment of the present invention is to provide a novel semiconductor device with a decreased circuit size. Another object of one embodiment of the present invention is to provide a novel semiconductor device with lower power consumption.

Another object of one embodiment of the present invention is to provide a method for compressing a large volume of data by a novel semiconductor device. Another object of one embodiment of the present invention is to provide a method for efficiently compressing data by a novel semiconductor device.

Note that the objects of the present invention are not limited to the above objects. The objects described above do not disturb the existence of other objects. The other objects are the ones that are not described above and will be described below. The other objects will be apparent from and can be derived from the description of the specification, the drawings, and the like by those skilled in the art. One embodiment of the present invention solves at least one of the above objects and the other objects. One embodiment of the present invention need not solve all the above objects and the other objects.

(1)

One embodiment of the present invention is a semiconductor device including first to fourth circuits. The first circuit includes a first charge pump circuit, a second charge pump circuit, an analog memory, and a logic circuit. The first charge pump circuit and the second charge pump circuit each include a first transistor. The first transistor includes an oxide semiconductor in a channel formation region. The logic circuit includes a first input terminal, a second input terminal, a first output terminal, and a second output terminal. The second circuit includes a third input terminal and a third output terminal. The third circuit has the same circuit structure as the second circuit. The third circuit includes a fourth input terminal and a fourth output terminal. The fourth circuit includes a fifth input terminal, a sixth input terminal, and a fifth output terminal. The first input terminal is electrically connected to the fifth input terminal and the third output terminal. The second input terminal is electrically connected to the fourth output terminal. The first output terminal is electrically connected to the first charge pump circuit. The second output terminal is electrically connected to the second charge pump circuit. The analog memory is electrically connected to the first charge pump circuit, the second charge pump circuit, and the sixth input terminal. The fifth output terminal is electrically connected to the fourth input terminal.

(2)

Another embodiment of the present invention is the semiconductor device according to (1), further including a fifth circuit. The fifth circuit has the same circuit structure as the fourth circuit. The fifth circuit includes a seventh input terminal, an eighth input terminal, and a sixth output terminal. The seventh input terminal is electrically connected to the second input terminal and the fourth output terminal. The eighth input terminal is electrically connected to the sixth input terminal and the analog memory. The sixth output terminal is electrically connected to the third input terminal.

(3)

Another embodiment of the present invention is the semiconductor device according to (1) or (2), in which the fourth circuit includes second to fifth transistors and an inverter. A first terminal of the second transistor is electrically connected to a first terminal of the third transistor. A first terminal of the fourth transistor is electrically connected to a first terminal of the fifth transistor. A gate of the third transistor is electrically connected to an input terminal of the inverter and the fifth input terminal. A gate of the fourth transistor is electrically connected to the sixth input terminal. A gate of the fifth transistor is electrically connected to an output terminal of the inverter.

(4)

Another embodiment of the present invention is the semiconductor device according to (1) or (2), in which the fourth circuit includes second to fifth transistors and an inverter. A first terminal of the second transistor is electrically connected to a first terminal of the third transistor. A first terminal of the fourth transistor is electrically connected to a first terminal of the fifth transistor. A gate of the third transistor is electrically connected to an output terminal of the inverter. A gate of the fourth transistor is electrically connected to the sixth input terminal. A gate of the fifth transistor is electrically connected to an input terminal of the inverter and the fifth input terminal.

(5)

Another embodiment of the present invention is the semiconductor device according to any one of (1) to (4), in which the second circuit includes a resistor, a comparator, a flip-flop circuit, and a selector. An output terminal of the flip-flop circuit is electrically connected to a first input terminal of the selector. A non-inverting input terminal of the comparator is electrically connected to the resistor and the third input terminal. An output terminal of the comparator is electrically connected to a second input terminal of the selector. An output terminal of the selector is electrically connected to the third output terminal.

(6)

Another embodiment of the present invention is the semiconductor device according to any one of (1) to (5), in which first transistor includes a back gate.

(7)

Another embodiment of the present invention is the semiconductor device according to any one of (1) to (6), further including a sixth transistor. A first terminal of the sixth transistor is electrically connected to the analog memory.

(8)

Another embodiment of the present invention is an electronic device including an encoder configured to encode video data with the semiconductor device according to any one of (1) to (8). The video data includes first data and second data. When the first data and the second data are input to the semiconductor device, the semiconductor device compares the first data and the second data. In the case where the first data and the second data match, a displacement vector from the first data to the second data is obtained.

According to one embodiment of the present invention, a novel semiconductor device can be provided. According to one embodiment of the present invention, a module including the novel semiconductor device can be provided. According to one embodiment of the present invention, an electronic device using the module including the novel semiconductor device can be provided. According to one embodiment of the present invention, a novel module, a novel electronic device, a novel system, and the like can be provided.

According to one embodiment of the present invention, a novel semiconductor device having a learning function, a pattern recognition function, or the like. According to one embodiment of the present invention, a novel semiconductor device with a decreased circuit size. According to one embodiment of the present invention, a novel semiconductor device with lower power consumption.

According to one embodiment of the present invention, a method for compressing a large volume of data by a novel semiconductor device can be provided. According to one embodiment of the present invention, a method for efficiently compressing data by a novel semiconductor device can be provided.

Note that the effects of one embodiment of the present invention are not limited to the above effects. The effects described above do not disturb the existence of other effects. The other effects are the ones that are not described above and will be described below. The other effects will be apparent from and can be derived from the description of the specification, the drawings, and the like by those skilled in the art. One embodiment of the present invention has at least one of the above effects and the other effects. Accordingly, one embodiment of the present invention does not have the aforementioned effects in some cases.

### BRIEF DESCRIPTION OF DRAWINGS

FIG. 1 illustrates an example of a circuit in a semiconductor device.

FIG. 2 illustrates an example of a circuit in a semiconductor device.

FIG. 3 illustrates an example of a semiconductor device.

FIG. 4 illustrates an example of a semiconductor device.

FIG. 5 illustrates an example of a semiconductor device.

FIG. 6 illustrates an example of a circuit in a semiconductor device.

FIG. 7 illustrates an example of a circuit in a semiconductor device.

FIG. 8 illustrates an example of a circuit in a semiconductor device.

FIG. 9 illustrates an example of a circuit in a semiconductor device.

FIG. 10 is a flowchart showing an operation example of a semiconductor device.

FIG. 11 is a flowchart showing an operation example of a semiconductor device.

FIGS. 12A to 12F illustrate operation of a semiconductor device.

FIG. 13 is a flowchart showing an operation example of a semiconductor device.

FIG. 14 is a block diagram illustrating a configuration example of a broadcast system.

FIG. 15 is a schematic view illustrating data transmission in a broadcast system.

FIG. 16 illustrates a structure example of an image distribution system in the medical field.

FIGS. 17A to 17D illustrate structure examples of a receiver.

FIG. 18 is a block diagram illustrating a structure example of a semiconductor device of one embodiment of the present invention.

FIGS. 19A to 19C illustrate structure examples of an image sensor.

FIGS. 20A to 20D illustrate structure examples of an image sensor.

FIGS. 21A and 21B illustrate structure examples of an image sensor.

FIGS. 22A to 22C are circuit diagrams illustrating structure examples of an image sensor.

FIG. 23 is an exploded view illustrating a structure example of a display module.

FIG. 24A is a block diagram illustrating a structure example of a display portion, and FIGS. 24B and 24C are circuit diagrams illustrating configuration examples of a pixel.

FIGS. 25A to 25C illustrate structure examples of a display panel.

FIGS. 26A and 26B are cross-sectional views each illustrating a structural example of a display panel.

FIGS. 27A and 27B are cross-sectional views each illustrating a structural example of a display panel.

FIGS. 28A to 28F are schematic views each illustrating a structure example of an electronic device.

FIG. 29A is a top view and FIGS. 29B and 29C are cross-sectional views illustrating a structure example of a transistor.

FIG. 30A is a cross-sectional view and FIG. 30B is an energy band diagram illustrating a structure example of a transistor.

FIGS. 31A and 31B are cross-sectional views illustrating oxygen diffusion paths.

FIG. 32A is a top view and FIGS. 32B and 32C are cross-sectional views illustrating a structure example of a transistor.

FIG. 33A is a top view and FIGS. 33B and 33C are cross-sectional views illustrating a structure example of a transistor.

FIG. 34A is a top view and FIGS. 34B and 34C are cross-sectional views illustrating a structure example of a transistor.

FIG. 35A is a top view and FIGS. 35B and 35C are cross-sectional views illustrating a structure example of a transistor.

FIG. 36A is a top view and FIGS. 36B to 36D are cross-sectional views illustrating structure example of a transistor.

FIG. 37A is a top view and FIG. 37B is a cross-sectional view illustrating a structure example of a transistor.

FIGS. 38A to 38E show structural analysis of a CAAC-OS and a single crystal oxide semiconductor by XRD and selected-area electron diffraction patterns of a CAAC-OS.

FIGS. 39A to 39E show a cross-sectional TEM image and plan-view TEM images of a CAAC-OS and images obtained through analysis thereof.

FIGS. 40A to 40D show electron diffraction patterns and a cross-sectional TEM image of an nc-OS.

FIGS. 41A and 41B are cross-sectional TEM images of an a-like OS.

FIG. 42 shows a change of crystal parts of an In—Ga—Zn oxide owing to electron irradiation.

### BEST MODE FOR CARRYING OUT THE INVENTION

In this specification, an oxide semiconductor is referred to as an OS in some cases. A transistor including an oxide semiconductor in a channel formation region is referred to as an OS transistor in some cases.

In this specification, a position (hereinafter referred to as an address in some cases) of one of objects arranged in a matrix is denoted by [x, y] (each of x and y is an integer of 1 or more). In particular, x is a row number from the top and y is a column number from the left. For example, [2, 3] shows the position in the second row from the top and the third column from the left.

### Embodiment 1

In this embodiment, an example of a semiconductor device according to the disclosed invention will be described.

### Structure Example

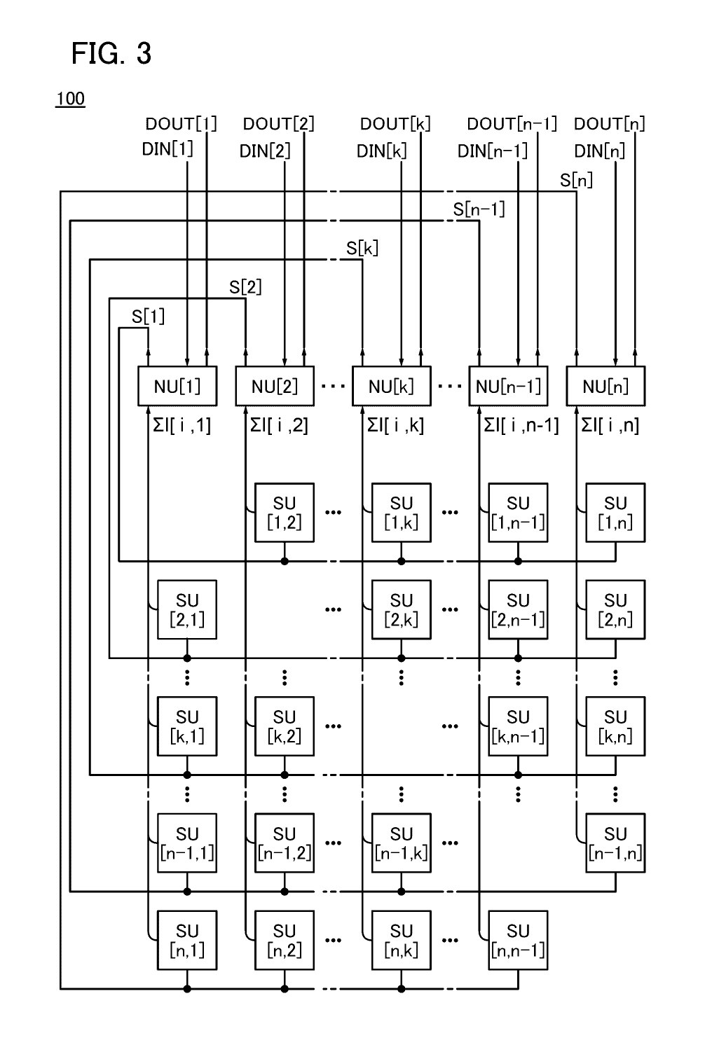

FIG. 3 illustrates a semiconductor device of one embodiment of the present invention. A semiconductor device 100 includes neuron circuits NU[1] to NU[n] and (n²−n) synapse circuits SU (n is an integer of 2 or more).

The synapse circuits SU are arranged so that n circuits are arranged per side. In FIG. 3, the synapse circuit SU in an i-th row and a j-th column is denoted by SU[i, j]. Note that i is an integer of 1 or more and n or less, and j is an integer of 1 or more and n or less. The synapse circuit SU is not provided at the address [i, j] that satisfies i=j. Accordingly, the number of synapse circuits SU included in the semiconductor device 100 is (n²−n).

The neuron circuit NU[1] is electrically connected to the synapse circuits SU[2, 1] to SU[n, 1] in the first column and the synapse circuits SU[1, 2] to SU[1, n] in the first row.

The neuron circuit NU[k] is electrically connected to the synapse circuits SU[1, k] to SU[n, k] in the k-th column and the synapse circuits SU[k, 1] to SU[k, n] in the k-th row (k is an integer of 2 or more and (n−1) or less).

The neuron circuit NU[n] is electrically connected to the synapse circuits SU[1, n] to SU[n−1, n] in the n-th column and the synapse circuits SU[n, 1] to SU[n, n−1] in the n-th row.

With the above structure, a neural network called a Hopfield network can be formed in the semiconductor device 100.

External input signals DIN[1] to DIN[n] are input to the neuron circuits NU[1] to NU[n], respectively, from the outside, and processing is carried out in the semiconductor device 100. The processing results are output from the neuron circuits NU[1] to NU[n] as external output signals DOUT[1] to DOUT [n], respectively.

Note that the external input signals DIN[1] to DIN[n] do no need to be input to all the neuron circuits NU[1] to NU[n], and circuits to which input signals are input may be selected from the neuron circuits NU[1] to NU[n] in accordance with the number of necessary input signals. Similarly, the external output signals DOUT[1] to DOUT[n] do not need to be output from all the neuron circuits NU[1] to NU[n], and circuits from which output signals are output may be selected from the neuron circuits NU[1] to NU[n] in accordance with the number of necessary output signals.

The neuron circuit NU[1] outputs a signal S[1] to be input to the synapse circuits SU[1, 2] to SU[1, n] in the first row.

The neuron circuit NU[k] outputs a signal S[k] to be input to the synapse circuits SU[k, 1] to SU[k, n] in the k-th row.

The neuron circuit NU[n] outputs a signal S[n] to be input to the synapse circuits SU[n, 1] to SU[n, n−1] in the n-th row.

When focusing on the first column, signals S[2] to S[n] are input to the synapse circuits SU[2, 1] to SU[n, 1] in the first column, respectively. The synapse circuits SU[2, 1] to SU[n, 1] output signals corresponding to signal strength obtained by multiplying the signals S[2] to S[n] input to respective circuits by connection strengths w[2, 1] to w[n, 1]. The connection strength will be described later. Specifically, the synapse circuits SU[2, 1] to SU[n, 1] output signals (currents) I[2, 1] to I[n, 1], respectively. Consequently, a sum signal (current) ΣI[i, 1], i.e., the sum of signals (currents) I[2, 1] to I[n, 1], is input to the neuron circuit NU[1]. Note that i used in this paragraph is an integer of 2 or more and n or less.

Similarly, the signals S[1] to S[n] (except the signal S[k]) are input to the synapse circuits SU[1, k] to SU[n, k] in the k-th column, respectively. The synapse circuits SU[1, k] to SU[n, k] output signals corresponding to signal strength obtained by multiplying the signals S[1] to S[n] (except the signal S[k]) input to the respective circuits by connection strengths w[1, k] to w[n, k], respectively. Specifically, the synapse circuits SU[1, k] to SU[n, k] output the signals (currents) I[1, k] to I[n, k], respectively. Consequently, a sum signal (current) ΣI[i, k], i.e., the sum of signals (currents) I[1, k] to I[n, k], is input to the neuron circuit NU[k]. Note that i used in this paragraph is an integer of 1 or more and n or less and is not k.

Similarly, the signals S[1] to S[n−1] are input to the synapse circuits SU[1, n] to SU[n−1, n] in the n-th column, respectively. The synapse circuits SU[1, n] to SU[n−1, n] output signals corresponding to signal strength obtained by multiplying the signals S[1] to S[n−1] input to the respective circuits by connection strengths w[1, n] to w[n−1, n]. Specifically, synapse circuits SU[1, n] to SU[n−1, n] output signals (currents) I[1, n] to I[n−1, n], respectively. Consequently, a sum signal (current) ΣI[i, n], i.e., the sum of signals (currents) I[1, n] to I[n−1, n], are input to the neuron circuit NU[n]. Note that i used in this paragraph is an integer of 1 or more and (n−1) or less.

A connection strength w[i, j] is determined by analog data stored in the synapse circuit SU[i, j]. Here, since the semiconductor device 100 forms a Hopfield network, the connection strength w[i, j] is equivalent to the connection strength w[j, i]. In other words, the analog data of the synapse circuit SU[i, j] can be shared with the synapse circuit SU[j, i]. The synapse circuit SU[i, j] and the synapse circuit SU[j, i] each include an analog memory and a writing control circuit WCTL. The semiconductor device 100 can have a structure in which the analog memory AM and the writing control circuit WCTL are shared between the synapse circuits SU[i, j] and SU[j, i]. The semiconductor device having such a structure will be described in detail below.

In this specification, the sum of connection strengths held in all the synapse circuits SU included in the semiconductor device 100 is denoted by a connection strength Win some cases. Furthermore, the connection strength W can be referred to as an n×n square matrix in some cases. In that case, W represents a symmetric matrix with all diagonal elements of 0.

In FIG. 3, only the following elements are illustrated, and the other circuits, wirings, signals, reference numerals, and the like are not shown: the neuron circuit NU[1], the neuron circuit NU[2], the neuron circuit NU[k], the neuron circuit NU[n−1], the neuron circuit NU[n], the synapse circuit SU[1, 2], the synapse circuit SU[1, k], the synapse circuit SU[1, n−1], the synapse circuit SU[1, n], the synapse circuit SU[2, 1], the synapse circuit SU[2, k], the synapse circuit SU[2, n−1], the synapse circuit SU[2, n], the synapse circuit SU[k, 1], the synapse circuit SU[k, 2], the synapse circuit SU[k, n−1], the synapse circuit SU[k, n], the synapse circuit SU[n−1, 1], the synapse circuit SU[n−1, 2], the synapse circuit SU[n−1, k], the synapse circuit SU[n−1, n], the synapse circuit SU[n, 1], the synapse circuit SU[n, 2], the synapse circuit SU[n, k], the synapse circuit SU[n, n−1], the signal S[1], the signal S[2], the signal S[k], the signal S[n−1], the signal S[n], the sum signal (current) ΣI[i, 1], the sum signal (current) ΣI[i, 2], the sum signal (current) ΣI[i, k], the sum signal (current) ΣI[i, n−1], the sum signal (current) ΣI[i, n], the external input signal DIN[1], the external input signal DIN[2], the external input signal DIN[k], the external input signal DIN[n−1], the external input signal DIN[n], the external output signal DOUT[1], the external output signal DOUT[2], the external output signal DOUT[k], the external output signal DOUT[n−1], and the external output signal DOUT[n].

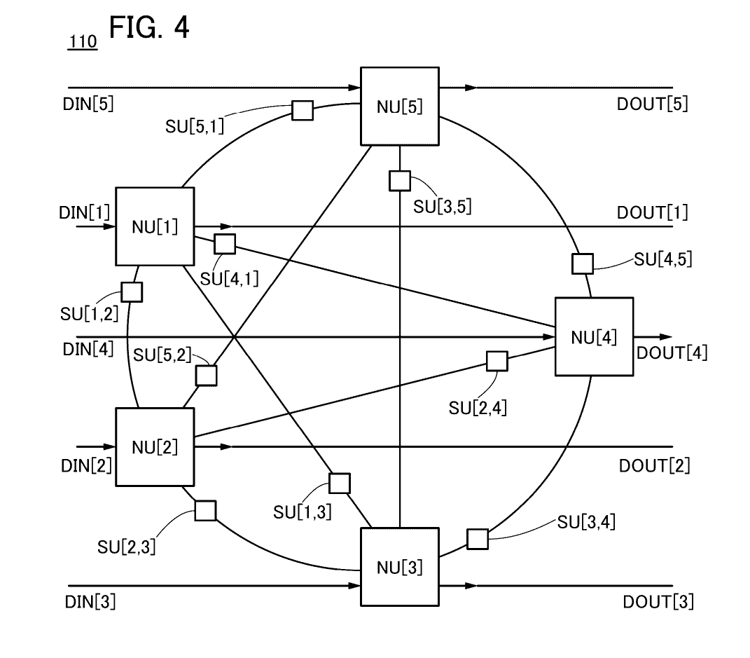

Note that in this structure example, a circuit structure in which synapse circuits SU are arranged in a square matrix with a side of n circuits is described; however, one embodiment of the present invention is not limited thereto. For example, the neuron circuits NU[1] to NU[n] may be arranged in a circle, and the synapse circuits may be arranged between neuron circuits. FIG. 4 illustrates a circuit structure where n=5 is satisfied. The semiconductor device 110 illustrated in FIG. 4 includes a neuron circuit NU[1], a neuron circuit NU[2], a neuron circuit NU[3], a neuron circuit NU[4], a neuron circuit NU[5], a synapse circuit SU[1, 2], a synapse circuit SU[1, 3], a synapse circuit SU[2, 3], a synapse circuit SU[2, 4], a synapse circuit SU[3, 4], a synapse circuit SU[3, 5], a synapse circuit SU[4, 5], a synapse circuit SU[4, 1], a synapse circuit SU[5, 1], and a synapse circuit SU[5, 2]. In the semiconductor device 110, when the external input signal DIN[1], the external input signal DIN[2], the external input signal DIN[3], the external input signal DIN[4], and the external input signal DIN[5] are input, the external output signal DOUT[1], the external output signal DOUT[2], the external output signal DOUT[3], the external output signal DOUT[4], and the external output signal DOUT[5] are obtained. In FIG. 4, only connection relationships between the neuron circuits and the synapse circuits included in the semiconductor device 110 are illustrated, and specific lines such as signal transmission lines from the neuron circuits to the synapse circuits and signal transmission lines from the synapse circuits to the neuron circuits are omitted.

### <<Neuron Circuit>>

Next, a neuron circuit will be described.

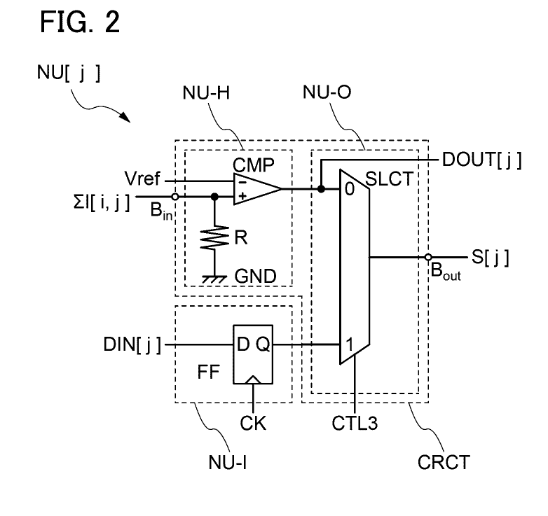

FIG. 2 illustrates a structure example of the neuron circuit. A neuron circuit NU[j] illustrated in FIG. 2 includes an input neuron circuit portion NU-I, a hidden neuron circuit portion NU-H, and an output neuron circuit portion NU-O. The neuron circuit NU[j] further includes an internal input terminal Bᵢₙ and an internal output terminal Bout as terminals for receiving and sending signals with the synapse circuits SU. Note that the hidden neuron circuit portion NU-H and the output neuron circuit portion NU-O are collectively referred to as a circuit CRCT.

### [Hidden Neuron Circuit Portion]

The hidden neuron circuit portion NU-H includes a comparator CMP and a resistor R.

A non-inverting input terminal of the comparator CMP is electrically connected to a first terminal of the resistor R, and a non-inverting input terminal of the comparator CMP is electrically connected to an internal input terminal Bᵢₙ. A sum signal (current) ΣI[i, j] is input to the internal input terminal Bᵢₙ (here, i is an integer of 1 or more and n or less and is not j), and a reference potential Vref is input to an inverting input terminal of the comparator CMP. A ground potential GND is input to a second terminal of the resistor R.

Only a signal generated in the semiconductor device 100 is input to the hidden neuron circuit portion NU-H.

In the hidden neuron circuit portion NU-H, the sum signal (current) ΣI[i, j] generated in the semiconductor device 100 is converted into a voltage by the resistor R. Then, the voltage and the reference potential Vref are input to the comparator CMP, and a signal corresponding to the comparison result is output from an output terminal of the comparator CMP. Here, when the voltage into which the sum signal (current) ΣI[i, j] is converted by the resistor R exceeds the reference potential Vref, a signal “1” is output from the output terminal of the comparator CMP. This operation result corresponds to “firing” of the neuron circuit. When the voltage into which the sum signal (current) ΣI[i, j] is converted by the resistor R is lower than the reference potential Vref, a signal “0” is output from the output terminal of the comparator CMP.

Note that the reference potential Vref can be determined in accordance with the threshold value of the neuron circuit NU[j] as appropriate.

The external output signals DOUT[1] to DOUT[n] are collectively referred to as expected data in some cases. By inputting data to the semiconductor device 100, connection strengths W corresponding to the data are held in all the synapse circuits, and the external output signals DOUT[1] to DOUT[n] are formed using their connection strengths W.

### [Input Neuron Circuit Portion]

The input neuron circuit portion NU-I includes a flip-flop circuit FF.

An external input signal DIN is input to an input terminal D of the flip-flop circuit FF, an output signal is output from an output terminal Q of the flip-flop circuit FF, and a clock signal CK is input to a clock terminal of the flip-flop circuit FF.

The flip-flop circuit FF can hold an external input signal DIN[j] and can output the external input signal DIN[j] from the output terminal Q when the clock signal CK is a high-level potential.

### [Output Neuron Circuit Portion]

The output neuron circuit portion NU-O includes a selector SLCT.

The selector SLCT includes a first input terminal (denoted by “1” in FIG. 2), a second input terminal (denoted by “0” in FIG. 2), an output terminal, and a control signal input terminal. The first input terminal, the second input terminal, and the output terminal of the selector SLCT are electrically connected to the output terminal Q of the flip-flop circuit FF, the output terminal of the comparator CMP, and the internal output terminal Bout, respectively.

The external output signal DOUT is output from the output terminal of the comparator CMP, and the signal S[j] is output from the output terminal of the selector SLCT. A control signal CTL3 is input to the control signal input terminal of the selector SLCT. When the value of the control signal CTL3 is “1”, a signal input to the first input terminal is output from the output terminal of the selector SLCT, and when the value of the control signal CTL3 is “0”, a signal input to the second input terminal is output from the output terminal of the selector SLCT. Specifically, in first learning described later, when the neuron circuit NU[j] functions as an input neuron, data “1” is input as the control signal CTL3; when the neuron circuit NU[j] functions as a hidden neuron, data “0” is input as the control signal CTL3; and when the neuron circuit NU[j] functions as an output neuron, data “1” is input as the control signal CTL3. In second learning described later, when the neuron circuit NUN functions as an input neuron, data “1” is input as the control signal CTL3; when the neuron circuit NU[j] functions as a hidden neuron, data “0” is input as the control signal CTL3; and when the neuron circuit NU[j] functions as an output neuron, data “0” is input as the control signal CTL3. In comparison operation described later, when the neuron circuit NU[j] functions as an input neuron, data “1” is input as the control signal CTL3; when the neuron circuit NU[j] functions as a hidden neuron, data “0” is input as the control signal CTL3; and when the neuron circuit NU[j] functions as an output neuron, data “0” is input as the control signal CTL3.

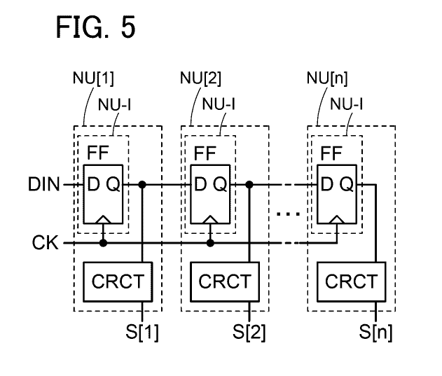

Furthermore, as illustrated in FIG. 5, the number of terminals through which data is input from the outside may be reduced with a shift register formed by connecting flip-flop circuits FF of input neuron circuit portions NU-I of the neuron circuits NU[1] to NU[n]. For example, when the semiconductor device 100 is formed with a small number of chip input terminals, data input from the outside to the semiconductor device 100 can be easily performed by the operation of the shift register. In FIG. 5, only the signals S[1], S[2], and S[n] are illustrated, and the other output signals are omitted. Note that in the case of a small number of external input signals, a flip-flop circuit FF is not provided and the external input signals may be directly input from a chip input terminal.

### <<Synapse Circuit>>

Next, an example of the synapse circuit is described.

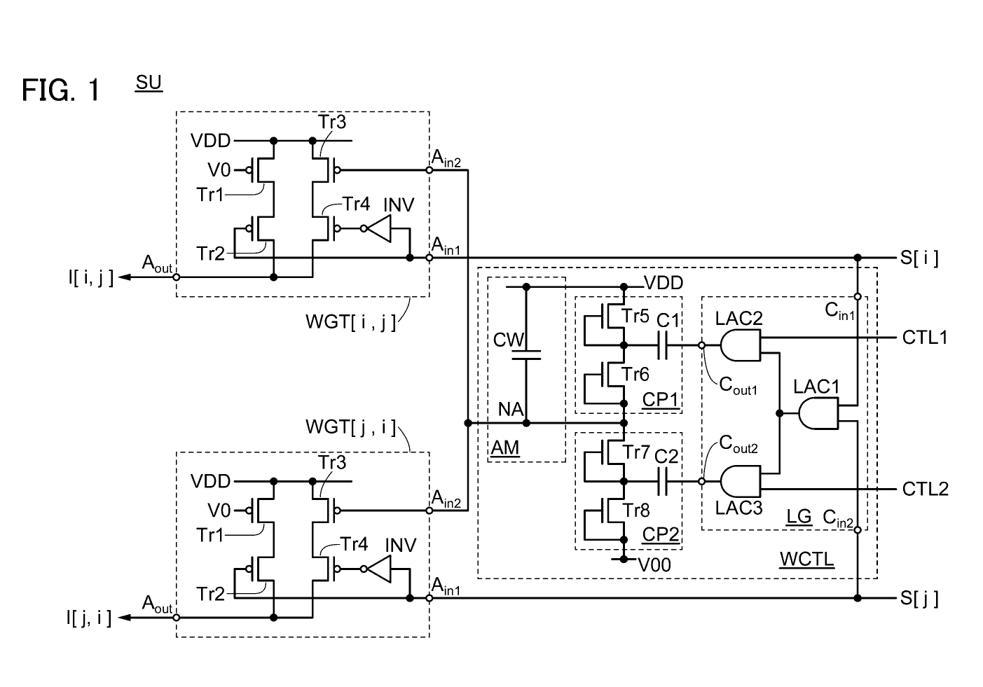

The synapse circuits SU illustrated in FIG. 1 each include the writing control circuit WCTL, a weighting circuit WGT[j, i], and a weighting circuit WGT[i, j]. The writing control circuit WCTL includes an analog memory AM.

As for the example of the synapse circuit SU described here, the writing control circuit WCTL is shared between the synapse circuits SU[j, i] and SU[i, j]. In other words, the analog memory AM included in the writing control circuit WCTL and data held in the analog memory AM are shared. Furthermore, the weighting circuits WGT[j, i] and WGT[i, j] are provided in the synapse circuits SU[j, i] and SU[i, j], respectively. In other words, the writing control circuit WCTL and the weighting circuit WGT[j, i] function as the synapse circuit SU[j, i], and the writing control circuit WCTL and the weighting circuit WGT[i, j] function as the synapse circuit SU[i, j].

The weighting circuit WGT[i, j] includes transistors Tr1 to Tr4, an inverter INV, an internal input terminal Aᵢₙ₁, an internal input terminal Aᵢₙ₂, and an internal output terminal Aₒᵤₜ. Note that the transistors Tr1 and Tr3 are each appropriately biased to operate in a saturation region.

A first terminal of the transistor Tr1 is electrically connected to a first terminal of the transistor Tr2; a first terminal of the transistor Tr3 is electrically connected to a first terminal of the transistor Tr4; and a second terminal of the transistor Tr2 is electrically connected to a second terminal of the transistor Tr4 and the internal output terminal Aₒᵤₜ. A gate of the transistor Tr2 is electrically connected to an input terminal of the inverter INV and the internal input terminal Aᵢₙ₁; a gate of the transistor Tr4 is electrically connected to an output terminal of the inverter INV; and a gate of the transistor Tr3 is electrically connected to a node NA in the analog memory AM through the internal input terminal Aᵢₙ₂.

A potential VDD is input to a second terminal of the transistor Tr1 and a second terminal of the transistor Tr3, and a potential V0 is input to a gate of the transistor Tr1.

For the description of the structure of the weighting circuit WGT[j, i] the above description of the weighting circuit WGT[i, j] is referred to.

In the weighting circuit WGT[i, j], the signal S[i] from the neuron circuit NU[i] is input to the input terminal of the inverter INV and the gate of the transistor Tr2 as an input signal. The signal (current) I[i, j] is output from the second terminal of the transistor Tr2 or the second terminal of the transistor Tr4 in accordance with the value of the signal S[i].

In the weighting circuit WGT[j, i], the signal S[j] from the neuron circuit NU[j] is input to the input terminal of the inverter INV and the gate of the transistor Tr2 as an input signal. The signal (current) I[j, i] is output from the second terminal of the transistor Tr2 or the second terminal of the transistor Tr4 in accordance with the value of the signal S[j].

The analog memory AM includes a capacitor CW and the node NA.

A first terminal of the capacitor CW is electrically connected to the node NA. The potential VDD is input to a second terminal of the capacitor CW.

A potential corresponding to a connection strength w[i, j] is held by the capacitor CW in the analog memory AM.

The writing control circuit WCTL includes, in addition to the above-described analog memory AM, a charge pump circuit CP1, a charge pump circuit CP2, and a logic circuit LG.

The charge pump circuit CP1 includes a transistor Tr5, a transistor Tr6, and a capacitor C1. The charge pump circuit CP2 includes a transistor Tr7, a transistor Tr8, and a capacitor C2. The logic circuit LG includes AND circuits LAC1 to LAC3, an internal input terminal Cᵢₙ₁, an internal input terminal Cᵢₙ₂, an internal output terminal Cₒᵤₜ₁, and an internal output terminal Cₒᵤₜ₂.

A first terminal of the transistor Tr5 is electrically connected to a gate of the transistor Tr5, a first terminal of the transistor Tr6, and a first terminal of the capacitor C1. A second terminal of the transistor Tr6 is electrically connected to a gate of the transistor Tr6, a first terminal of the transistor Tr7, and the node NA in the analog memory AM. A second terminal of the transistor Tr7 is electrically connected to a gate of the transistor Tr7, a first terminal of the transistor Tr8, and a first terminal of the capacitor C2. A second terminal of the transistor Tr8 is electrically connected to a gate of the transistor Tr8. A second terminal of the capacitor C1 is electrically connected to the internal output terminal Cₒᵤₜ₁, and a second terminal of the capacitor C2 is electrically connected to the internal output terminal Cₒᵤₜ₂.

In the synapse circuit in FIG. 1, the transistors Tr1 to Tr4 are p-channel transistors and the transistors Tr5 to Tr8 are n-channel transistors.

The potential VDD is input to a second terminal of the transistor Tr5, and a potential V00 is input to the second terminal and gate of the transistor Tr8. Note that the potential VDD is higher than the potential V0, and the potential V00 is lower than the potential V0.

A first input terminal of the AND circuit LAC1 is electrically connected to the internal input terminal Cᵢₙ₁; a second input terminal of the AND circuit LAC1 is electrically connected to the internal input terminal Cᵢₙ₂; and an output terminal of the AND circuit LAC1 is electrically connected to a first input terminal of the AND circuit LAC2 and a first input terminal of the AND circuit LAC3. An output terminal of the AND circuit LAC2 is electrically connected to the internal output terminal Cₒᵤₜ₁, and an output terminal of the AND circuit LAC3 is electrically connected to the internal output terminal Cₒᵤₜ₂.

The signal S[i] from the neuron circuit NU[i] is input to the internal input terminal Cᵢₙ₁, and the signal S[j] from the neuron circuit NU[j] is input to the internal input terminal Cᵢₙ₂. A control signal CTL1 is input to a second input terminal of the AND circuit LAC2, and a control signal CTL2 is input to a second input terminal of the AND circuit LAC3.

As each of the transistors Tr5 to Tr8 in the writing control circuit WCTL, a transistor including an oxide semiconductor in a channel formation region, i.e., an OS transistor, is preferably used. When formed using OS transistors, the transistors Tr5 to Tr8 can have extremely low off-state currents. In other words, leakage current which is generated in the transistors Tr5 to Tr8 in an off state can be extremely reduced. Thus, charge retention characteristics of the capacitor CW can be improved. Furthermore, regular refresh operation for data retention is not necessary, which leads to a reduction in power consumption. In addition, a circuit for refresh operation does not need to be provided, which leads to a reduction in chip area in the semiconductor device 100. The structure of the OS transistor will be described in Embodiment 5.

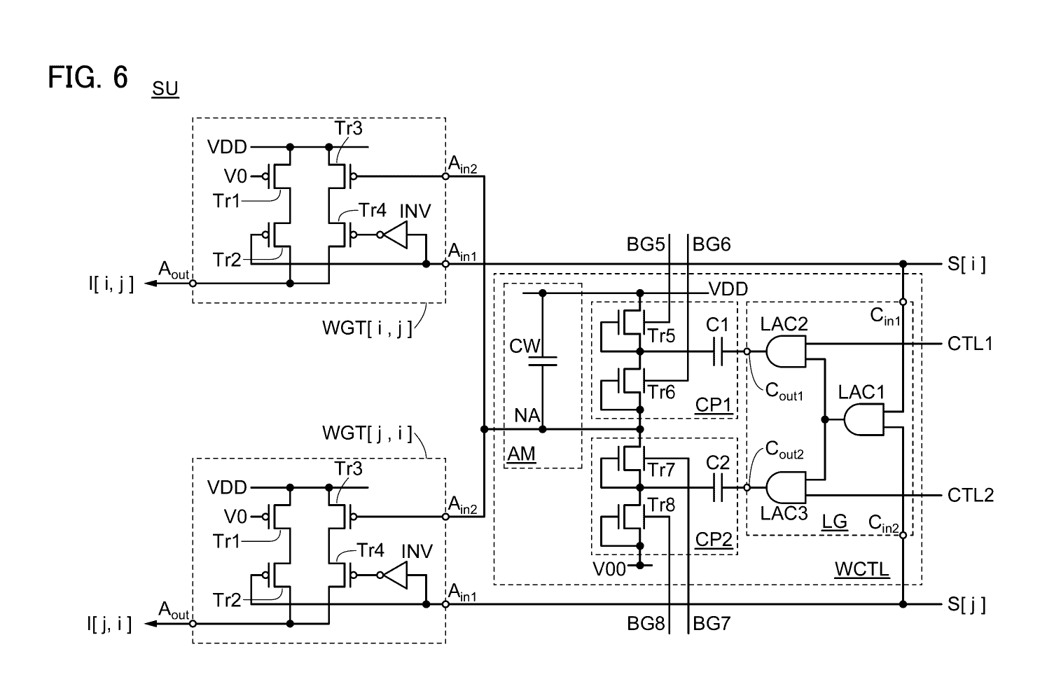

In the synapse circuit SU, a back gate may be provided in each of the transistors Tr5 to Tr8 as illustrated in FIG. 6. A back gate of the transistor Tr5 is electrically connected to a wiring BG5; a back gate of the transistor Tr6 is electrically connected to a wiring BG6; a back gate of the transistor Tr7 is electrically connected to a wiring BG7; and a back gate of the transistor Tr8 is electrically connected to a wiring BG8. With such a structure, voltages can be input to the back gates of the transistors Tr5 to Tr8 through the wirings BG5 to BG8, and threshold voltages of the transistors Tr5 to Tr8 can be controlled.

In the synapse circuit SU illustrated in FIG. 1, the transistors Tr1 to Tr4 are p-channel transistors; however, one embodiment of the present invention is not limited thereto. In the synapse circuit SU, the transistors Tr1 to Tr4 may be n-channel transistors.

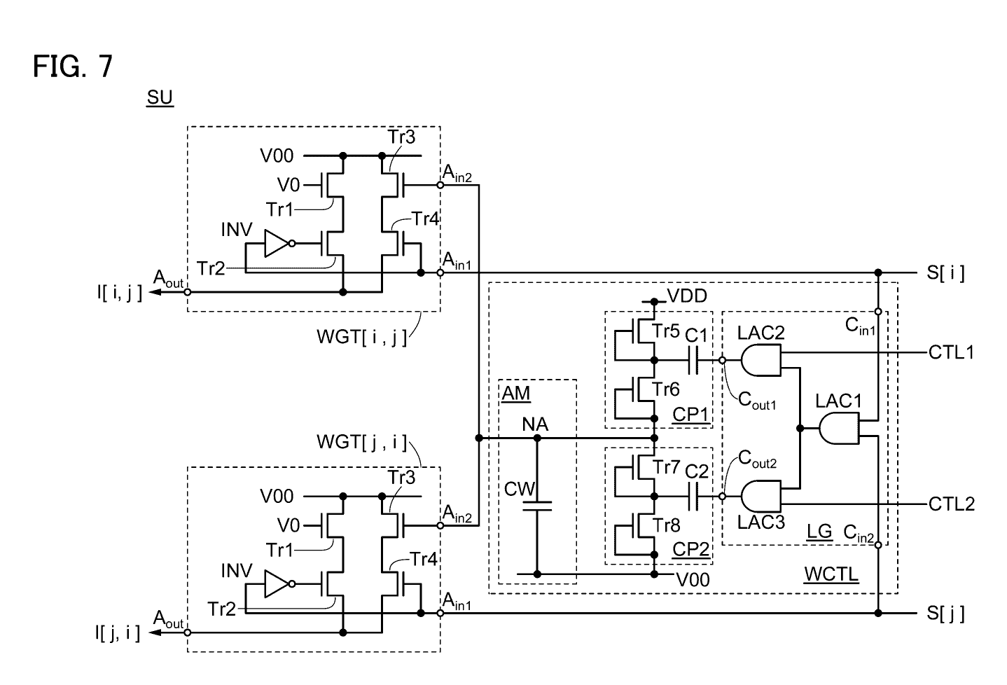

FIG. 7 illustrates a circuit structure of the synapse circuit SU where the transistors Tr1 to Tr4 are n-channel transistors. The first terminal of the transistor Tr1 is electrically connected to the first terminal of the transistor Tr2; the first terminal of the transistor Tr3 is electrically connected to the first terminal of the transistor Tr4; and the second terminal of the transistor Tr2 is electrically connected to the second terminal of the transistor Tr4. The gate of the transistor Tr4 is electrically connected to the input terminal of the inverter INV; the gate of the transistor Tr2 is electrically connected to the output terminal of the inverter INV; and the gate of the transistor Tr3 is electrically connected to the node NA in the analog memory AM.

The potential V00 is input to the second terminal of the transistor Tr1 and the second terminal of the transistor Tr3, and the potential V0 is input to the gate of the transistor Tr1.

For the description of the structure of the weighting circuit WGT[j, i] the above description of the weighting circuit WGT[i, j] is referred to.

In the weighting circuit WGT[i, j], the signal S[i] from the neuron circuit NU[i] is input to the input terminal of the inverter INV and the gate of the transistor Tr4 as an input signal. The signal (current) I[i, j] is output from the second terminal of the transistor Tr2 or the second terminal of the transistor Tr4 in accordance with the value of the signal S[i].

In the weighting circuit WGT[j, i], the signal S[j] from the neuron circuit NU[j] is input to the input terminal of the inverter INV and the gate of the transistor Tr4 as an input signal. The signal (current) I[j, i] is output from the second terminal of the transistor Tr2 or the second terminal of the transistor Tr4 in accordance with the value of the signal S[j].

The analog memory AM includes the capacitor CW and the node NA.

The first terminal of the capacitor CW is electrically connected to the node NA. The potential V00 is input to the second terminal of the capacitor CW.

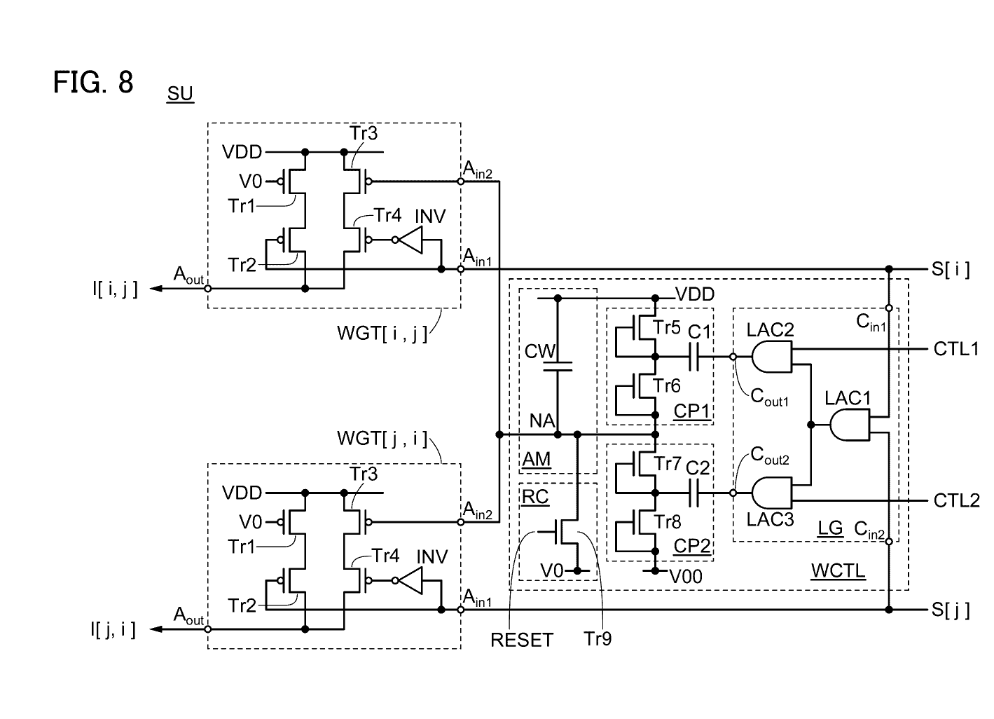

The synapse circuit may include a reset circuit for initializing the potential held in the analog memory AM in the synapse circuit SU. FIG. 8 illustrates a circuit structure where a reset circuit RC is provided in the synapse circuit SU in FIG. 1.

The writing control circuit WCTL includes the reset circuit RC, and the reset circuit RC includes a transistor Tr9. A first terminal of the transistor Tr9 is electrically connected to the node NA in the analog memory AM; a second terminal of the transistor Tr9 is electrically connected to a wiring through which the potential V0 is supplied; and a gate of the transistor Tr9 is electrically connected to a wiring RESET.

To initialize the semiconductor device 100, a high-level potential is input to the wiring RESET so that the transistor Tr9 is turned on, and the potential of the node NA is set to V0. The reset circuit RC enables easy initialization of the potential held in the analog memory. A structure where an arbitrary value can be set to each of the nodes NA after the initialization may be employed. Different values may be set to the nodes NA.

Next, an operation example of the synapse circuit SU in FIG. 1 is described.

When the signal S[i] from the neuron circuit NU[i] is input to the synapse circuit SU, the weighting circuit WGT[i, j] outputs the signal (current) I[i, j] corresponding to signal strength obtained by multiplying the signal S[i] by the connection strength w[i, j].

Since the weighting circuits WGT[i, j] and WGT[j, i] output currents, the sum of output signals of the plurality of synapse circuits SU can be easily obtained by sharing the output signal line between the plurality of synapse circuits SU. For example, as illustrated in FIG. 3, when an output signal line is shared between the synapse circuits SU[2, 1] to SU[n, 1] in the first column, a sum signal (current) ΣI[i, 1] that is the sum of output signals can be easily input to the neuron circuit NU[1] (here, i is an integer of 1 or more and n or less). Similarly, when an output signal line is shared between the synapse circuits SU[1, k] to SU[n, k] in the k-th column, the sum signal (current) ΣI[i, k] that is the sum of output signals can be easily input to the neuron circuit NU[k] (here, i is an integer of 1 or more and n or less and is not k). Similarly, when an output signal line is shared between the synapse circuits SU[1, n] to SU[n−1, n] in the n-th column, the sum signal (current) ΣI[i, n] that is the sum of output signals can be easily input to the neuron circuit NU[n] (here, i is an integer of 1 or more and (n−1) or less).

The signal S[i] input to the weighting circuit WGT[i, j] is input to the gate of the transistor Tr2 and to the gate of the transistor Tr4 through the inverter INV; thus, the signal S[i] can control on/off states of the transistors Tr2 and Tr4. When the signal S[i] is “0,” the transistor Tr2 is turned on and the transistor Tr4 is turned off, so that the signal (current) I₀ corresponding to the potential V0 is output from the weighting circuit WGT[i, j] as the signal (current) I[i, j] through the transistors Tr1 and Tr2. Note that I₀ refers to a reference current in the weighting circuit WGT[i, j], and the potential V0 is set so that the corresponding current I₀ flows in the case where the signal (current) w[i, j]S[i] is “0.” When the signal S[i] is “1,” the transistor Tr2 is turned off and the transistor Tr4 is turned on, so that the signal (current) w[i, j]S[i] corresponding to the potential of the node NA is output from the weighting circuit WGT[i, j] as the signal (current) I[i, j] through the transistors Tr3 and Tr4. In the case where the potential of the node NA is set to V0 after the initialization, when the signal S[i] is “1,” in the synapse circuit SU, the signal (current) I₀ that is a reference current is output from the weighting circuit WGT[i, j] as the signal (current) I[i, j].

The signal (current) w[i, j]S[i] output when the signal S[i] is “1” is determined depending on the potential of the node NA. For example, the lower the potential of the node NA is, the higher the output signal (current) w[i, j]S[i] is, and the higher the potential of the node NA is, the lower the output signal (current) w[i, j]S[i] is.

The lower the potential of the node NA is, the higher the signal (current) w[i, j]S[i] is, and a voltage applied to the resistor R in the hidden neuron circuit portion NU-H is increased. This is because of a high connection strength w[i, j]. In contrast, the higher the potential of the node NA is, the lower the signal (current) w[i, j]S[i] is, and a voltage applied to the resistor R in the hidden neuron circuit portion NU-H is decreased. This is because of a low connection strength w[i, j].

The weighting circuit WGT[j, i] operates in a manner similar to that of the weighting circuit WGT[i, j]. When the signal S[j] input from the neuron circuit NU[j] to the synapse circuit SU is “0,” the signal (current) I₀ corresponding to the potential V0 is output as the signal (current) I[j, i], and when the signal S[j] is “1,” the signal (current) w[j, i]S[j] corresponding to the signal strength obtained by multiplying the signal S[j] by the connection strength w[j, i] is output as the signal (current) I[j, i].

The signal S[j] input to the weighting circuit WGT[j, i] is input to the gate of the transistor Tr2 and to the gate of the transistor Tr4 through the inverter INV; thus, the signal S[j] can control on/off states of the transistors Tr2 and Tr4. When the signal S[j] is “0,” the transistor Tr2 is turned on and the transistor Tr4 is turned off, so that the signal (current) Iₒ corresponding to the potential V0 is output from the weighting circuit WGT[j, i] through the transistors Tr1 and Tr2. Here, the signal (current) Iₒ refers to a reference current in the weighting circuit WGT[j, i]. For the signal (current) Iₒ, the description of the weighting circuit WGT[i, j] is referred to. When the signal S[j] is “1,” the transistor Tr2 is turned off and the transistor Tr4 is turned on, so that the signal (current) w[j, i]S[ⱼ] corresponding to the potential of the node NA is output from the weighting circuit WGT[j, i] as the signal (current) I[j, i] through the transistors Tr3 and Tr4. In the case where the potential of the node NA is V0 after the initialization, when the signal S[i] is “1,” in the synapse circuit SU, the signal (current) Iₒ that is a reference current is output from the weighting circuit WGT[i, j] as the signal (current) I[i, j].

The signal (current) w[j, i]S[j] output when the signal S[j] is “1” is determined depending on the potential of the node NA. For example, the lower the potential of the node NA is, the higher the output signal (current) w[j, i]S[j] is, and the higher the potential of the node NA is, the lower the output signal (current) w[j, i]S[j] is.

The lower the potential of the node NA is, the higher the signal (current) w[j, i]S[j] is, and a voltage applied to the resistor R in the hidden neuron circuit portion NU-H is increased. This is because of a high connection strength w[j, i]. In contrast, the higher the potential of the node NA is, the lower the signal (current) w[j, i]S[j] is, and a voltage applied to the resistor R in the hidden neuron circuit portion NU-H is decreased. This is because of a low connection strength w[j, i].

The potential of the node NA of the analog memory AM can be changed in the range from the potential V00 to the potential VDD by the operation of the writing control circuit WCTL. Specifically, the potential of the node NA can be decreased by the charge pump circuit CP1 in the writing control circuit WCTL or the potential of the node NA can be increased by the charge pump circuit CP2 in the writing control circuit WCTL.

Note that using OS transistors as the transistors Tr5 to Tr8 is a preferable way to improve the efficiency of the charge pump circuits CP1 and CP2. Since the OS transistor has an extremely low off-state current, the potential of the node NA in the analog memory AM can be retained by the OS transistor for a long time. Furthermore, back gates are preferably provided in the transistors Tr5 to Tr8 as illustrated in FIG. 6. The transistors Tr5 to Tr8 including back gates can have higher on-state currents.

The writing control circuit WCTL operates by receiving the signal S[i] from the neuron circuit NU[i], the signal S[j] from the neuron circuit NU[j], the control signal CTL1, and the control signal CTL2. In other words, when these signals are received, the charge pump circuit CP1 or the charge pump circuit CP2 can be operated.

When the signal S[i] from the neuron circuit NU[i] is “1” and the signal S[j] from the neuron circuit NU[j] is “1,” they are input to the first input terminal and the second input terminal of the AND circuit LAC1; consequently, a signal “1” is output from the output terminal of the AND circuit LAC1. In that case, the signal “1” is input to the first input terminal of the AND circuit LAC2 and the first input terminal of the AND circuit LAC3.

In this state, when the control signal CTL1 input to the second input terminal of the AND circuit LAC2 is “1,” the signal “1” is output to the output terminal of the AND circuit LAC2; and when the control signal CTL1 input to the second input terminal of the AND circuit LAC2 is “0,” the signal “0” is output to the output terminal of the AND circuit LAC2. In other words, when the control signal CTL1 is a pulse signal, the charge pump circuit CP1 operates and the potential of the node NA can be decreased.

On the other hand, when the control signal CTL2 input to the second input terminal of the AND circuit LAC3 is “1,” the signal “1” is output to the output terminal of the AND circuit LAC3; and when the control signal CTL2 input to the second input terminal of the AND circuit LAC3 is “0,” the signal “0” is output to the output terminal of the AND circuit LAC3. In other words, when the control signal CTL2 is a pulse signal, the charge pump circuit CP2 operates and the potential of the node NA can be increased.

In other words, when the signal S[i] of “1” and the signal S[j] of “1” are input and the pulsed control signal CTL1 is input to the synapse circuits SU, the potential of the node NA corresponding to the connection strength w[j, i] held in the analog memory AM is decreased, so that the connection strength w[j, i] is increased. When the signal S[i] of “1” and the signal S[j] of “1” are input and the pulsed control signal CTL2 is input to the synapse circuits SU, the potential of the node NA corresponding to the connection strength w[j, i] held in the analog memory AM is increased, so that the connection strength w[j, i] is decreased. Therefore, when the connection strength w[j, i] is increased, the signal (current) w[j, i]S[j] output from the weighting circuit WGT[j, i] is increased, and when the connection strength w[j, i] is decreased, the signal (current) w[j, i]S[j] output from the weighting circuit WGT[j, i] is decreased.

Note that in the case where the synapse circuit SU is initialized, the following setting is effective: one of the signal S[i] and the signal S[j] is “0”; a pulse signal is input as the control signal CTL1; and the connection strength w[j, i] becomes low. Alternatively, the following setting is effective: at least one of the signal S[i] and the signal S[j] is “0”; a pulse signal is input as the control signal CTL2; and the connection strength w[j, i] becomes high.

Here, as the principle of the semiconductor device of one embodiment of the present invention, first learning, second learning, and convergence of a connection strength W are described.

The first learning refers to operation in which the control signal CTL3 of “1” is input to the neuron circuit NU corresponding to the input neuron and output neuron and a pulse signal is input as the control signal CTL1. In other words, by the first learning, the charge pump circuit CP1 operates to increase the connection strength w[i, j]. Note that when the one of the signal S[i] and the signal S[j] is “0,” the connection strength w[i,j] is not updated.

The second learning refers to operation in which the control signal CTL3 of “0” is input to the neuron circuit NU corresponding to the output neuron and a pulse signal is input as the control signal CTL2. In other words, by the second learning, the charge pump circuit CP2 operates to increase the connection strength w[i, j]. Note that when at least one of the signal S[i] and the signal S[j] is “0,” the connection strength w[i, j] is not updated.

Energy E of the network of the connection strength W where the semiconductor device 100 forming the Hopfield neural network circuit uses external input signals DIN[1] to DIN[n] (learning data) is represented by Formula 1.

$$\begin{matrix}[ Formula 1 ] & \\ E = - \frac{1}{2} {\sum }_{j = 1}^{n} {\sum }_{i \neq j}^{n} {w}_{ji} {O}_{j} {O}_{i} + {\sum }_{j = 1}^{n} {θ}_{j} {O}_{j} & ( 1 )\end{matrix}$$

It is known that output of the Hopfield network is changed, which leads to a reduction in the energy E of the network.

In Formula 1, wⱼᵢ corresponds to the connection strength w[i, j] of the synapse circuit SU[i, j], Oᵢ a corresponds to an external output signal DOUT[i], i.e., expected data, and θⱼ corresponds to the threshold value of the neuron circuit NU[j]. In the semiconductor device 100, the threshold value corresponds to the reference potential Vref.

When the external output signal DOUT[i] is 1, Oᵢ is set to “1,” and when the external output signal DOUT[i] is 0, Oᵢ is set to “−1.”

In the sum of first terms in Formula 1, as the number of combinations of i and j where Oᵢ and Oⱼ, i.e., both of the external output signals DOUT[i] and DOUT[j], are “1” or “−1” is large, the energy E becomes lower and the network is more stable. In contrast, as the number of combinations of i and j where one of the external output signals DOUT[i] and DOUT[j] is “1” and the other thereof is “−1” is large, the energy E becomes higher and the network is more unstable. In other words, when the neuron circuit NU[i] and the neuron circuit NU[j] are fired and strongly connected to each other, or not fired and strongly connected, the network is stable.

Furthermore, in the second term in Formula 1, the level of the energy E is determined by the product of the threshold value θⱼ and the external output signal DOUT[j]. For example, in the case where the threshold value θⱼ required for “firing” of the neuron circuit NU[i] is high, the energy E of the network when the neuron circuit NU[i] is “fired” becomes high and the energy E of the network when the neuron circuit NU[i] is not “fired” becomes low.

Here, the energy E when ΣθⱼOⱼ of the threshold value θⱼ of the neuron circuit NU is the reference level of the energy is represented by the following formula.

$$\begin{matrix}[ Formula 2 ] & \\ E = - \frac{1}{2} {\sum }_{j = 1}^{n} {\sum }_{i \neq j}^{n} {w}_{ji} {O}_{j} {O}_{i} & ( 2 )\end{matrix}$$

In Formula 2, as in Formula 1, as the number of combinations of i and j where both of the external output signals DOUT[i] and DOUT[j] are “1” or “−1” is large, the energy E becomes lower and the network is more stable. In contrast, as the number of combinations of i and j where one of the external output signals DOUT[i] and DOUT[j] is “1” and the other thereof is “−1” is large, the energy E becomes higher and the network is more unstable.

In the case of using Formula 2, since the threshold value θⱼ is 0, the energy E of the Hopfield network is determined by only the external output signal DOUT[i], the external output signal DOUT[j], and the connection strength w[i,j].

Here, the case where the first learning is repeated is described. By repeating the first learning, the connection strength w[i, j] when both of the signals S[i] and S[j] are “1” is increased. By this operation, expected data and the connection strength W are each converged to a certain value, so that the energy E becomes the local minimum value in Formula 1 or Formula 2.

Meanwhile, the case where the second learning is repeated is described. By repeating the second learning, the connection strength w[i, j] when both of the signals S[i] and S [j] are “1” is decreased. In other words, when the connection strength W is decreased, the energy E is increased in Formula 1 or Formula 2.

The second learning is performed to obtain a connection strength W and expected data of the network corresponding to the energy E which has the minimum value in a wide range in the energy function obtained by Formula 1 or Formula 2. The energy function obtained by Formula 1 or Formula 2 has a plurality of energies E that are the local minimum values in some cases, and there is a possibility that only performing the first learning repeatedly does not reach the energy E which has the minimum value in a wide range. Therefore, the energy E that has a converged local minimum value is temporarily increased by performing the second learning as appropriate; thus, the energy E can be transferred to energy E that has another local minimum value.

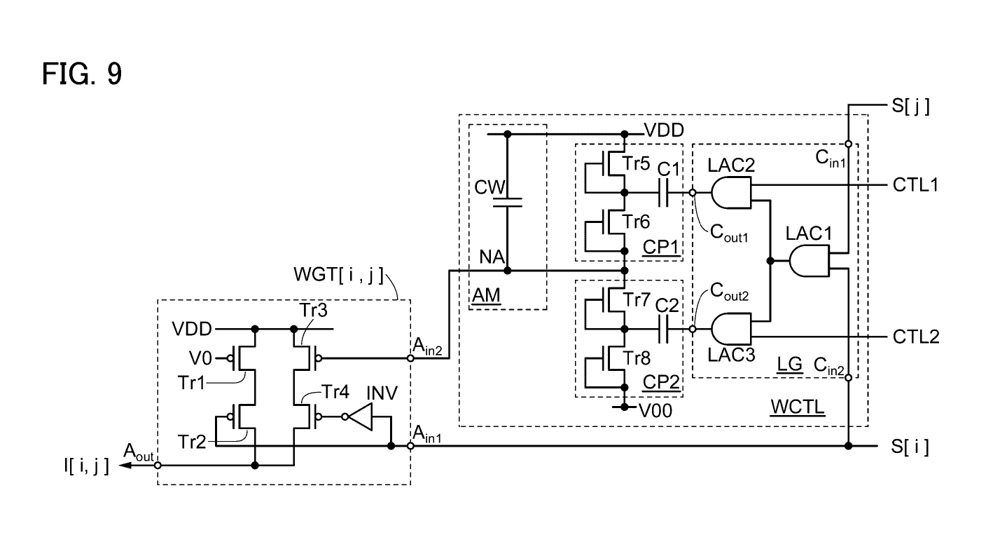

As for the structure and operation of the synapse circuit SU, the synapse circuit SU illustrated in FIG. 1 is described as an example; however, one embodiment of the present invention is not limited thereto. For example, a synapse circuit SU illustrated in FIG. 9 may be used. FIG. 9 illustrates a structure where the analog memory AM and the writing control circuit WCTL are not shared between the synapse circuits SU[j, i] and SU[i, j], and specifically, Each synapse circuit SU includes the analog memory AM and the writing control circuit WCTL. Note that the updating is performed so that the potential of the node NA in the analog memory AM in the synapse circuit SU[j, i] and the potential of the node NA in the analog memory AM in the synapse circuit SU[i, j] have the same value. With such a structure, physical symmetrical arrangement of neurons and synapses can be easily made.

Note that a circuit structure of the charge pump circuits CP1 and CP2 included in the synapse circuit SU, the analog memory, and the weighting circuits WGT[i, j] and WGT[j, i] is described using the circuit structure illustrated in FIG. 1 as an example; however, one embodiment of the present invention is not limited thereto. For example, the circuit structure of the logic circuit LG illustrated in FIG. 1 may be changed by using a circuit equivalent to the logic circuit LG illustrated in FIG. 1. For example, the circuit structure of the charge pump circuit CP1 or CP2 illustrated in FIG. 1 may be changed by using a circuit equivalent to the charge pump circuit CP1 or CP2 illustrated in FIG. 1. For example, in the analog memory AM illustrated in FIG. 1, the capacitor CW is not provided and parasitic capacitance formed of a wiring of the node NA and a wiring through which the potential VDD is supplied may be provided instead of the capacitor CW.

### Operation Example

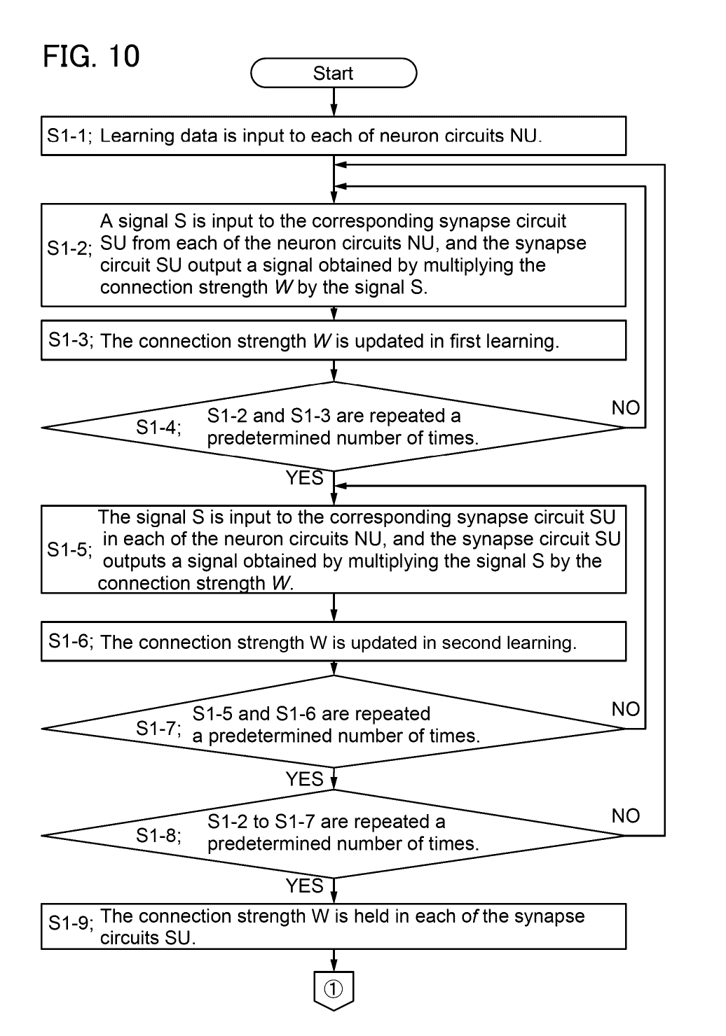

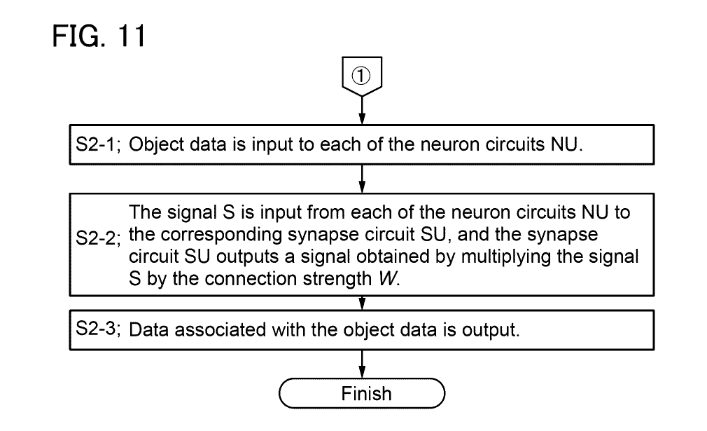

Here, an operation example of the semiconductor device 100 is described. The operation here refers to operation in which learning data is input to the semiconductor device 100 so that the semiconductor device 100 learns the learning data, object data is input to the semiconductor device 100, and judgment whether the learning data and the object data match, are similar, or mismatch is made. FIG. 10 and FIG. 11 are flowcharts of the operation of the semiconductor device 100. Note that the operation example of the semiconductor device 100 including the neuron circuit NU[i] illustrated in FIG. 2 and the synapse circuit SU illustrated in FIG. 1 is described here.

### <<Learning>>

First, operation where the semiconductor device 100 learns data is described with reference to FIG. 10.

### [Step S1-1]

In Step S1-1, learning data is input from the outside to the neuron circuit NU. Note that leaning data is represented in binary here, and the number of neuron circuits to which learning data is input is determined in accordance with the number of bits of the learning data. Therefore, the semiconductor device 100 preferably has a structure in which input/output of data to neuron circuits to which data is not necessarily input/output is electrically disconnected. Here, the volume of learning data is n-bits and the value of an i-th bit of learning data is denoted by learning data [i]. Learning data [1] to [n] are input to the neuron circuits NU[1] to NU[n], respectively. The learning data [i] is input to the neuron circuit NU[i] as the external input signal DIN[i].

### [Step S1-2]

In Step S1-2, the clock signal CK which is a high-level potential is input to the flip-flop circuit FF, and the control signal CTL3 of “1” is input to the selector SLCT. Thus, the neuron circuit NU[i] corresponding to the input neuron and the output neuron outputs a signal corresponding to the learning data [i] as the signal S[i]. The output signal S[i] is input to the synapse circuits SU[i, 1] to SU[i, n]. Note that signals S[1] to S[n] are collectively referred to as a signal S in the flowchart of FIG. 10. The signal S can be expressed as signals in 1×n matrix or signals in n×1 matrix in some cases.

Thus, the signal S corresponding to the learning data is input to the corresponding synapse circuits SU in the neuron circuits NU[1] to NU[n].

The synapse circuit SU[i, j] outputs the current I[i, j] corresponding to the signal S[i] by receiving the signal S[i]. Thus, the sum current ΣI[i, j] output from all the synapse circuits SU in the j-th column is input to the neuron circuit NU[j].

### [Step S1-3]

In Step S1-3, the connection strength W is updated in the first learning. Therefore, when both of the signal S[i] and the signal S[U] input to the synapse circuit SU[i, j] are “1,” the connection strength w[i, j] is increased. When at least one of the signal S[i] and the signal S[j] input to the synapse circuit SU[i, j] is “0,” the connection strength w[i, j] is not updated. In the case where the connection strength w[i, j] is increased, the current I[i, j] output from the synapse circuit SU[i, j] is increased.

### [ Step S1-4]

In Step S1-4, judgement whether a predetermined number of times of Step S1-2 and Step S1-3 has been repeated is made. When the predetermined number of times is satisfied, the process proceeds to Step S1-5, and when the predetermined number of times is not satisfied, the process returns to Step S1-2 and processing is performed again.

Note that the predetermined number of times is ideally the number of repetition times to obtain stable energy of the network; however, it may be an arbitrary number empirically determined.

### [Step S1-5]

In Step S1-5, the control signal CTL3 of “0” is input to the selector SLCT in the neuron circuit NU[i] corresponding to the output neuron, and the control signal CTL3 of “1” is input to the selector SLCT in the neuron circuit NU[i] corresponding to the input neuron. Thus, the neuron circuit NU[i] outputs a signal corresponding to data output from the hidden neuron circuit NU-H as the signal S[i]. The output signal S[i] is input to the synapse circuits SU[i, 1] to SU[i, n].

Thus, the signal S corresponding to the learning data is input to the corresponding synapse circuits SU in the neuron circuits NU[1] to NU[n].

The synapse circuit SU[i, j] outputs the current I[i, j] corresponding to the signal S[i] by receiving the signal S[i]. Thus, the sum current ΣI[i, j] output from all the synapse circuits SU in the j-th column is input to the neuron circuit NU[j].

### [Step S1-6]

In Step S1-6, the connection strength W is updated in the second learning. Therefore, when both of the signal S[i] and the signal S[j] input to the synapse circuit SU[i, j] are “1,” the connection strength w[i, j] is decreased. When at least one of the signal S[i] and the signal S[j] input to the synapse circuit SU[i, j] is “0,” the connection strength w[i, j] is not updated. In the case where the connection strength w[i, j] is decreased, the current I[i, j] output from the synapse circuit SU[i, j] is decreased.

### [Step S1-7]

In Step S1-7, judgement whether a predetermined number of times of Step S1-5 and Step S1-6 has been repeated is made. When the predetermined number of times is satisfied, the process proceeds to Step S1-8, and when the predetermined number of times is not satisfied, the process returns to Step S1-5 and processing is performed again.

Note that the predetermined number of times is ideally the number of repetition times to obtain the energy which is not locally minimum energy; however, it may be an arbitrary number empirically determined.

### [Step S1-8]

In Step S1-8, judgement whether a predetermined number of times of Step S1-2 to Step S1-7 has been repeated is made. When the predetermined number of times is satisfied, the process proceeds to Step S1-9, and when the predetermined number of times is not satisfied, the process returns to Step S1-2 and processing is performed again.

Note that the predetermined number of times is ideally the number of repetition times to obtain stable energy of the network; however, it may be an arbitrary number empirically determined.

### [Step S1-9]

In Step S1-9, the connection strength W of the network in accordance with the learning data, which is obtained by performing Step S1-2, Step S1-3, and Step S1-5 a predetermined number of times, is held, and expected data thereof is obtained. After that, the process proceeds to Step S2-1 to perform comparison.

As described above, in the Hopfield network, the connection strength W of the network is converged to a certain value or a certain matrix in some cases by performing Step S1-2 to Step S1-8 repeatedly. The network when the connection strength W is converged can be regarded as being in a stable state, and the stable state of the network corresponding to the input learning data is stored.

### <<Comparison>>

Next, operation in which object data is input to the semiconductor device 100 where data is learned in advance and a result is output is described with reference to FIG. 11. Among a plurality of data learned here, data expected to be the nearest to the object data is output as a result.

### [Step S2-1]

In Step S2-1, object data is input from the outside to the neuron circuit NU. Note that the object data here is represented in binary and is n-bits which is the same number of bits as the learning data input in Step S1-1, and is input to the neuron circuits NU[1] to NU[n].

Object data [i] is input to the neuron circuit NU[i] as the external input signal DIN[i]. Thus, the object data [i] is input to an input terminal D of the input neuron circuit portion NU-I included in the neuron circuit NU[i]. Then, by inputting a clock signal which is a high-level potential to the flip-flop circuit FF, the input neuron circuit portion NU-I corresponding to the input neuron inputs the object data [i] to the first input terminal of the selector SLCT. In Step S2-1, the control signal CTL3 of “1” is input to the selector SLCT, and the object data [i] is output from the output terminal of the selector SLCT as the signal S[i]. The output signal S[i] is input to the synapse circuits SU[i, 1] to SU[i, n].

Thus, the object data is input to all the synapse circuits SU in the neuron circuits NU[1] to NU[n].

### [Step S2-2]

In Step S2-2, the signal S[i] input to the synapse circuit SU[i, j] controls on/off states of the transistor Tr2 or Tr4 in the weighting circuit WGT[i, j]. When the signal S[i] is “1,” the transistor Tr2 is turned off and the transistor Tr4 is turned on, so that the signal (current) w[i, j]S[i] corresponding to the connection strength w[i, j] held in Step S1-2 or Step S1-6 in learning is output from the synapse circuit SU[i, j] as the signal (current) I[i, j]. When the signal S[i] is “0,” the transistor Tr2 is turned on and the transistor Tr4 is turned off, so that current Iₒ corresponding to the potential V0 flowing through the transistor Tr1 is output from the synapse circuit SU[i, j] as the signal (current) I[i, j].

In Step S2-2, input of the control signal CTL1 and the control signal CTL2 to the synapse circuit SU[i, j] is not performed. In other words, the charge pump circuits CP1 and CP2 included in the writing control circuit WCTL do not operate, and the connection strength w[i,j] is not updated.

### [Step S2-3]

In Step S2-3, as in Step S1-3, the signal (current) I[i, j] output from the synapse circuit SU[i, j] is input to the neuron circuit NU[j]. Signals (currents) output from all the synapse circuits SU in the j-th column are added and input to the neuron circuit NU[j]. In other words, sum signals (currents) ΣI[i, 1] to ΣI[i, n] are input to the neuron circuits NU[1] to NU[n], respectively.

When the sum signal (current) ΣI[i, j] is input to the neuron circuit NU[j], a potential is generated in the first terminal of the resistor R of the hidden neuron circuit portion NU-H. The potential of the first terminal of the resistor R and the reference potential Vref are input to a non-inverting input terminal and an inverting input terminal of the comparator CMP, respectively. The output terminal of the comparator CMP outputs a signal corresponding to a potential difference between the potential of the first terminal of the resistor R and the reference potential Vref. The output signal from the comparator CMP is output to the outside of the semiconductor device as an external output signal DOUT[j] and input to the second input terminal of the selector SLCT.

Here, the external output signals DOUT[1] to DOUT[n] are data expected to be the nearest data among a plurality of learning data. In other words, judgement whether learning data and object data match, are similar, or mismatch can be made.

Through Step S1-1 to Step S1-6 and Step S2-1 to Step S2-4 which are described above, the semiconductor device 100 is made to learn learning data, and then can output data which matches, is similar to, or mismatches learning data by receiving object data. Thus, the semiconductor device 100 can perform processing such as pattern recognition or associative storage.

In Embodiment 1, one embodiment of the present invention has been described. Other embodiments of the present invention are described in Embodiments 2 to 6. Note that one embodiment of the present invention is not limited thereto. In other words, various embodiments of the invention are described in this embodiment and the other embodiments, and one embodiment of the present invention is not limited to a particular embodiment. Although an example in which a channel formation region, a source region, a drain region, or the like of a transistor includes an oxide semiconductor is described as one embodiment of the present invention, one embodiment of the present invention is not limited thereto. Depending on circumstances or conditions, various transistors or a channel formation region, a source region, a drain region, or the like of a transistor in one embodiment of the present invention may include various semiconductors. Depending on circumstances or conditions, various transistors or a channel formation region, a source region, a drain region, or the like of a transistor in one embodiment of the present invention may include, for example, at least one of silicon, germanium, silicon germanium, silicon carbide, gallium arsenide, aluminum gallium arsenide, indium phosphide, gallium nitride, and an organic semiconductor. Alternatively, for example, depending on circumstances or conditions, various transistors or a channel formation region, a source region, a drain region, or the like of a transistor in one embodiment of the present invention does not necessarily include an oxide semiconductor.

This embodiment can be combined with any of the other embodiments in this specification as appropriate.

### Embodiment 2

In this embodiment, an operation example of the case where the semiconductor device 100 described in Embodiment 1 is used as an encoder is described.

### <<Example of Object Motion Detection>>

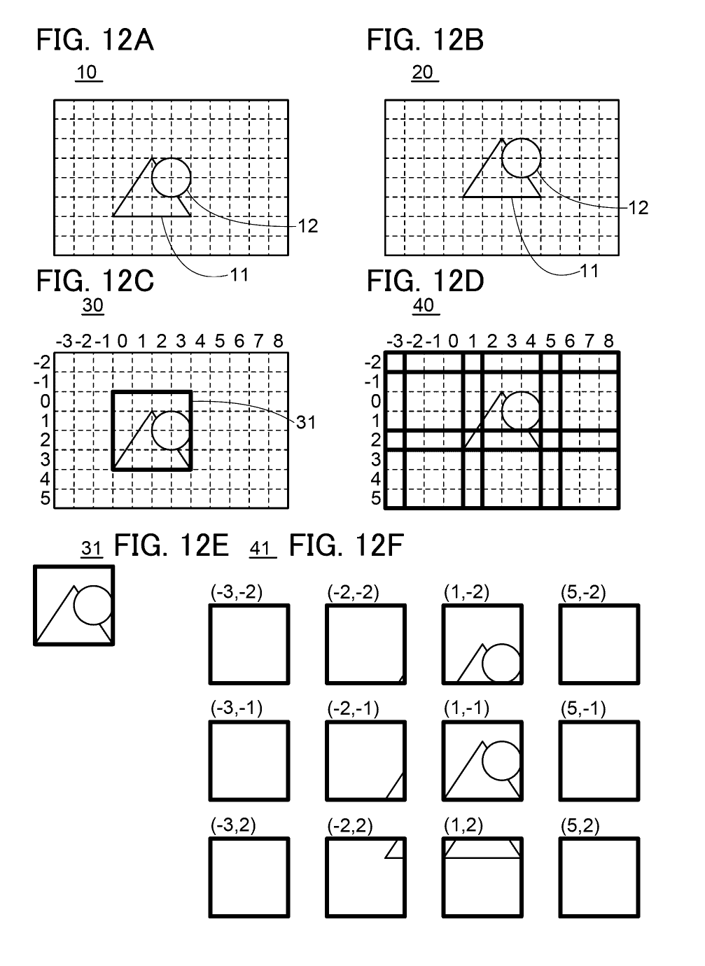

First, an example of a method for detecting an object motion is described. FIGS. 12A to 12F illustrate an algorithm that the semiconductor device 100 performs for detection of an object motion in image data.

FIG. 12A shows image data 10 that has a triangle 11 and a circle 12. FIG. 12B shows image data 20 where the triangle 11 and the circle 12 of the image data 10 are moved to the upper right.

Image data 30 in FIG. 12C shows operation by which a region 31 including the triangle 11 and the circle 12 is extracted from the image data 10. In the image data 30, a cell at the upper left corner of the extracted region 31 is regarded as a reference point (0, 0), and numbers indicating positions in the right/left direction and the upper/lower direction are added to the image data 10. The extracted region 31 of FIG. 12C is shown in FIG. 12E.

Image data 40 in FIG. 12D shows operation by which a plurality of regions 41 are extracted from the image data 20. The numbers indicating positions in the right/left direction and the upper/lower direction given to the image data 30 are added to the image data 20, which is the image data 40. On the basis of the image data 30 and 40, which position the region 31 moves to can be expressed by a displacement (a motion vector). FIG. 12F shows some of the extracted regions 41.

After the operation of extracting the plurality of regions 41, the regions 41 are sequentially compared with the region 31 to detect a motion of the objects. This comparing operation determines that the region 41 with a motion vector (1, −1) corresponds to the region 31, and that the regions 41 except the one with the motion vector (1, −1) do not correspond to the region 31. Accordingly, the motion vector (1, −1) from the region 31 to the region 41 can be obtained.

In this specification, the data of the region 31 is described as learning data in some cases, and the data of one of the plurality of regions 41 is described as object data in some cases.

Although the extraction, comparison, and detection are performed based on the regions each formed of 4×4 cells in FIGS. 12A to 12F, the size of the regions in the present operation example is not limited thereto. The size of the regions may be changed as appropriate in accordance with the size of image data to be extracted. For example, extraction, comparison, and detection may be performed based on the regions each formed of 3×5 cells. There is no limitation on the number of pixels forming a cell; for example, one cell used for forming a region may be formed of 10×10 pixels, or be one pixel. Alternatively, one cell used for forming a region may be formed of 5×10 pixels.

Depending on the video content, image data contained in the region 31 may be changed. For example, the triangle 11 or the circle 12 in the region 31 may be scaled in the image data 40. Alternatively, the triangle 11 or the circle 12 in the region 31 may be rotated in the image data 40. In that case, it is effective to obtain how much degree each of the plurality of regions 41 corresponds to the region 31. Specifically, external output signals of the region 31 and the plurality of regions 41 are calculated and then, a displacement (motion vector) of the region 41 with the minimum difference between the external output signals is obtained. To achieve this, it is preferable that whether or not the region 31 and any of the plurality of regions 41 are identical be determined by characteristics extraction or the like. Motion-compensated prediction becomes possible when image data where the region 31 moves in the motion vector direction is generated from the image data of the region 31 and a difference between the generated data and the plurality of regions 41 is obtained. When the moving amount of the image data of the region 31 is not coincident with an integral multiple of the pixel pitch, the external output signals may be calculated on the basis of comparison between the region 31 and the plurality of regions 41 so that a displacement with the minimum difference between the external output signals is predicted and detected as a displacement (motion vector) of the objects.

### <Judgement of Match, Similarity, or Mismatch of Image Data>

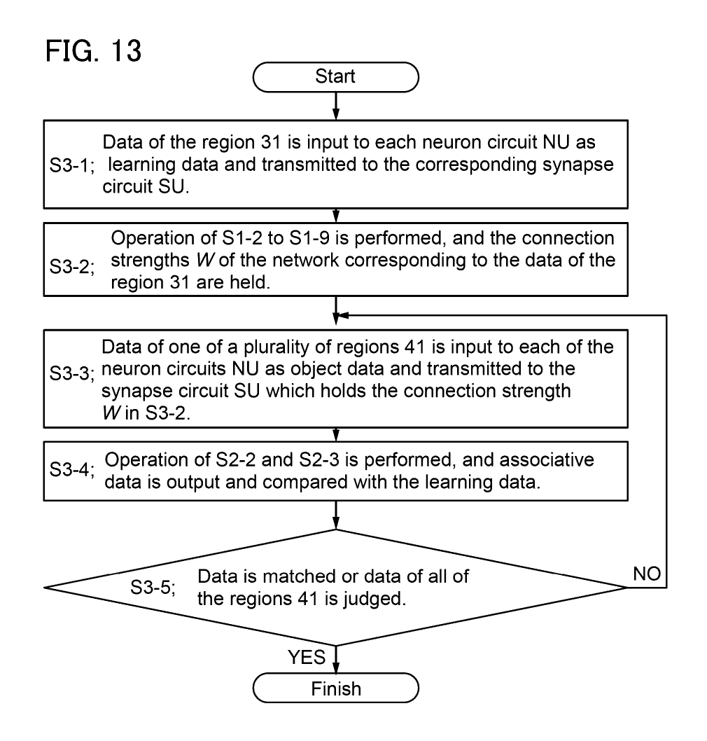

Next, a motion compensation prediction method using the semiconductor device 100 is described with reference to FIG. 13.

### [Step S3-1]

In Step S3-1, data of the region 31 is input to the neuron circuits NU[1] to NU[n] in the semiconductor device 100 as learning data. Note that the learning data is data of the region 31 represented in binary, and is of n-bits.

### [Step S3-2]

In Step S3-2, input of data of the region 31 is performed in operation similar to Step S1-2 to Step S1-6. In other words, in all the synapse circuits SU, connection strengths W are updated repeatedly, and the connection strengths W of all the synapse circuits corresponding to the data of the region 31 are held.

### [Step S3-3]

In Step S3-3, as object data, data of one of the plurality of regions 41 is input to the neuron circuits NU[1] to NU[n] in the semiconductor device 100 having the connection strength W formed in Step S3-2. Note that the object data is data of one of the regions 41 represented in binary, and is of n-bits.

### [Step S3-4]

In Step S3-4, input of data of one of the plurality of regions 41 is performed in operation similar to Step S2-2 to Step S2-4. In other words, by input of data of one of the plurality of regions 41, the semiconductor device 100 which has learned data of the region 31 outputs associative data.

Here, by comparison with data of the region 31 and associative data, judgement whether the data of the region 31 and the data of one of the plurality of regions 41 match, are similar, or mismatch is made.

[Step S3-5]

In Step S3-5, in accordance with the above judgement results, the step to which the process proceeds is determined.

When the judgement result shows a mismatch of the data of the region 31 and the one of the plurality of regions 41, the region 41 different from the one of the plurality of regions 41 is subjected to the operation in Step S3-3 and Step S3-4 again as the object data.

When the judgement result shows a match of the data of the region 31 and data of the one of the plurality of regions 41, a motion vector of one of the plurality of regions 41 using the region 31 as a reference is obtained, so that the operation is terminated. By obtaining the motion vector, motion compensation prediction using the motion vector as a difference can be performed. The motion compensation prediction enables efficient compression of video data.

When the judgement result shows similarity of the data of the region 31 and the data of the one of the plurality of regions 41, as described in Example of object motion detection, displacement in the case where the difference between the external output signals has the minimum value is predicted and the value thereof is obtained as the motion vector of an object. Then, the operation is terminated.

When comparison is performed using data of all of the regions 41 as the object data and the judgement result shows a mismatch or non-similarity of the learning data and all of the object data, it is judged that a motion vector for motion compensation prediction cannot be obtained from the data of the region 31 and data of the plurality of regions 41, and then, the operation is terminated.

Through the above operation, the Hopfield neural network can be used as an encoder which compresses video data. Thus, an encoder with high efficiency which can compress a large volume of image data can be provided.

This embodiment can be combined with any of the other embodiments in this specification as appropriate.

### Embodiment 3

In this embodiment, a broadcast system according to the disclosed invention will be described.

### <Broadcast System>

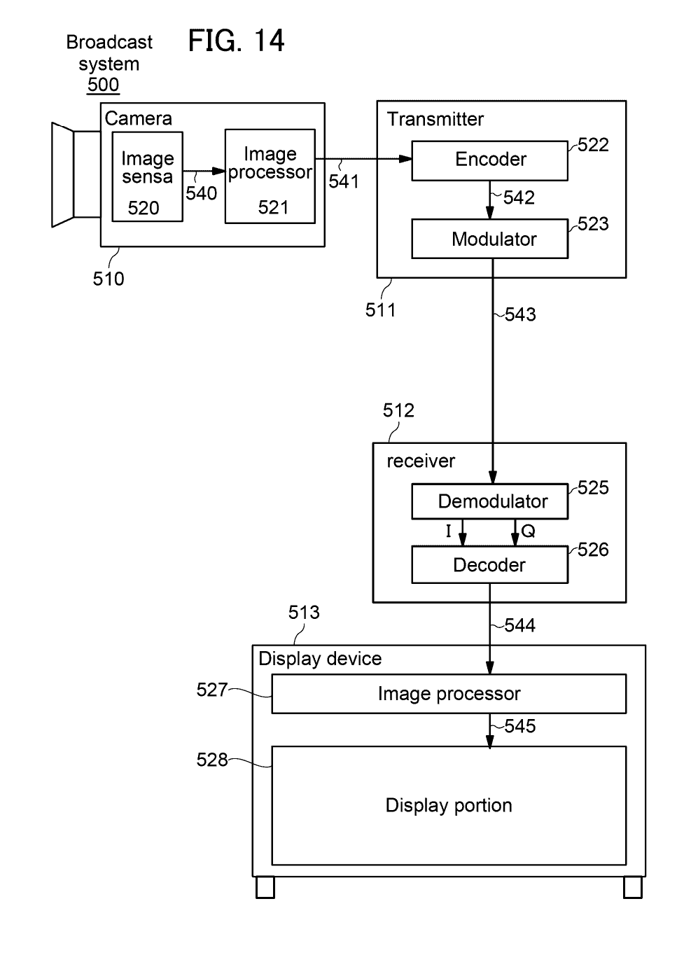

FIG. 14 is a block diagram schematically illustrating a configuration example of a broadcast system. A broadcast system 500 includes a camera 510, a transmitter 511, a receiver 512, and a display device 513. The camera 510 includes an image sensor 520 and an image processor 521. The transmitter 511 includes an encoder 522 and a modulator 523. The receiver 512 includes a demodulator 525 and a decoder 526. The display device 513 includes an image processor 527 and a display portion 528.

When the camera 510 is capable of taking an 8K video, the image sensor 520 includes a sufficient number of pixels to capture an 8K color image. For example, when one red (R) subpixel, two green (G) subpixels, and one blue (B) subpixel are included in one pixel, the image sensor 520 with an 8K camera needs at least 7680×4320×4 [R, G+G, and B] pixels, the image sensor 520 with a 4K camera needs at least 3840×2160×4 pixels, and the image sensor 520 with a 2K camera needs at least 1920×1080×4 pixels.

The image sensor 520 generates Raw data 540 which is not processed. The image processor 521 performs image processing (such as noise removal or interpolation processing) on the Raw data 540 and generates video data 541. The video data 541 is output to the transmitter 511.

The transmitter 511 processes the video data 541 and generates a broadcast signal (carrier wave) 543 that accords with a broadcast band. The encoder 522 processes the video data 541 and generates encoded data 542. The encoder 522 performs processing such as encoding of the video data 541, addition of broadcast control data (e.g., authentication data) to the video data 541, encryption, or scrambling (data rearrangement for spread spectrum).

The modulator 523 performs IQ modulation (orthogonal amplitude modulation) on the encoded data 542 to generate and output the broadcast signal 543. The broadcast signal 543 is a composite signal including data on components of I (identical phase) and Q (quadrature phase). A TV broadcast station takes a role in obtaining the video data 541 and supplying the broadcast signal 543.

The receiver 512 receives the broadcast signal 543. The receiver 512 has a function of converting the broadcast signal 543 into video data 544 that can be displayed on the display device 513. The demodulator 525 demodulates the broadcast signal 543 and decomposes it into two analog signals: an I signal and a Q signal.

The decoder 526 performs processing of converting the I signal and the Q signal into a digital signal. Moreover, the decoder 526 performs various processing on the digital signal and generates a data stream. This processing includes frame separation, decryption of a low density parity check (LDPC) code, separation of broadcast control data, descramble processing, and the like. The decoder 526 decodes the data stream and generates the video data 544. The processing for decoding includes orthogonal transform such as discrete cosine transform (DCT) and discrete sine transform (DST), intra-frame prediction processing, motion-compensated prediction processing, and the like.

The video data 544 is input to the image processor 527 of the display device 513. The image processor 527 processes the video data 544 and generates a data signal 545 that can be input to the display portion 528. Examples of the processing by the image processor 527 include image processing (gamma processing) and digital-analog conversion. When receiving the data signal 545, the display portion 528 displays an image.

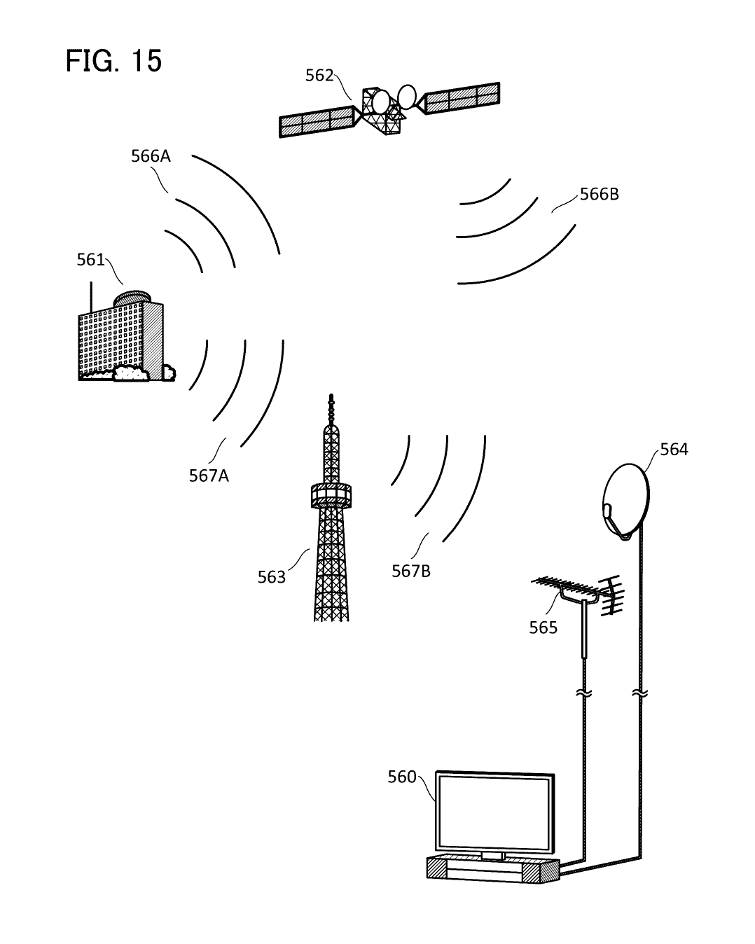

FIG. 15 schematically illustrates data transmission in the broadcast system. FIG. 15 illustrates a path in which a radio wave (a broadcast signal) transmitted from a broadcast station 561 is delivered to a television receiver 560 (a TV 560) of every household. The TV 560 is provided with the receiver 512 and the display device 513. As examples of an artificial satellite 562, a communication satellite (CS) and a broadcast satellite (BS) can be given. As examples of an antenna 564, a BS.110° C.S antenna and a CS antenna can be given. Examples of the antenna 565 include an ultra-high frequency (UHF) antenna.

Radio waves 566A and 566B are broadcast signals for a satellite broadcast. The artificial satellite 562 transmits the radio wave 566B toward the ground when receiving the radio wave 566A. The antenna 564 of every household receives the radio wave 566B, and a satellite TV broadcast can be watched on the TV 560. Alternatively, the radio wave 566B is received by an antenna of another broadcast station, and a receiver in the broadcast station processes the radio wave 566B into a signal that can be transmitted to an optical cable. The broadcast station transmits the broadcast signal to the TV 560 of every household using an optical cable network. Radio waves 567A and 567B are broadcast signals for a terrestrial broadcast. A radio wave tower 563 amplifies the received radio wave 567A and transmits it as the radio wave 567B. A terrestrial TV broadcast can be watched on the TV 560 of every household when the antenna 565 receives the radio wave 567B.

A video distribution system of this embodiment is not limited to a system for a TV broadcast. Video data to be distributed may be either moving image data or still image data.

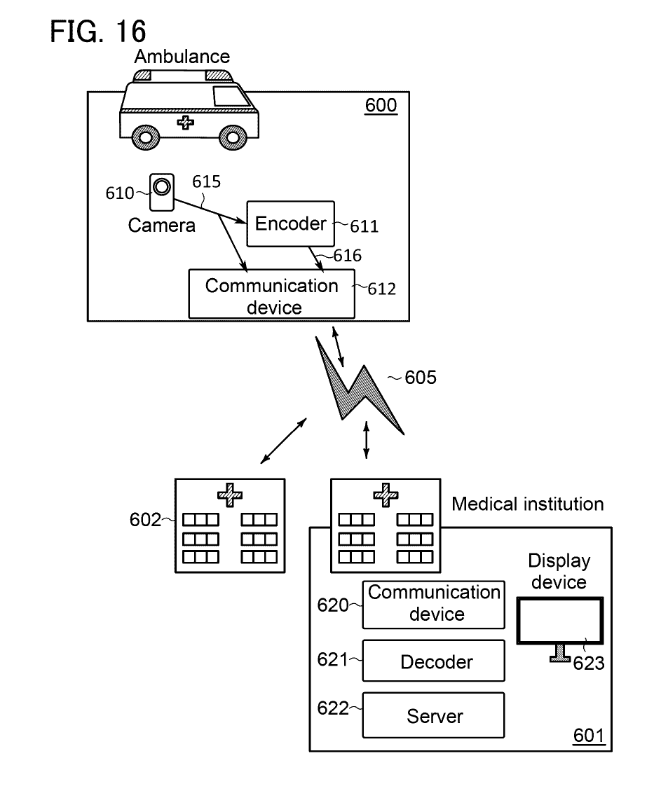

For example, the video data 541 of the camera 510 may be distributed via a high-speed IP network. The distribution system of the video data 541 can be used in, for example, the medical field for remote diagnosis and remote treatment. In medical practice, e.g., in accurate diagnostic imaging, high definition (8K, 4K, or 2K) images are required. FIG. 16 schematically illustrates an emergency medical system using the distribution system of the video data.

A high-speed network 605 performs communication between an emergency transportation vehicle (an ambulance) 600 and a medical institution 601 and between the medical institution 601 and a medical institution 602. The ambulance 600 is equipped with a camera 610, an encoder 611, and a communication device 612.

A patient taken to the medical institution 601 is photographed with the camera 610. Video data 615 obtained with the camera 610 can be transmitted in an uncompressed state by the communication device 612, so that the high-resolution video data 615 can be transmitted to the medical institution 601 with a short delay. In the case where the high-speed network 605 cannot be used for the communication between the ambulance 600 and the medical institution 601, the video data 615 can be encoded with the encoder 611 and encoded video data 616 can be transmitted.

In the medical institution 601, a communication device 620 receives the video data transmitted from the ambulance 600. When the received video data is uncompressed data, the data is transmitted via the communication device 620 and displayed on a display device 623. When the video data is compressed data, the data is decompressed with a decoder 621, transmitted to a server 622 and the display device 623, and then displayed on the display device 623. Judging from the image on the display device 623, doctors instruct crews of the ambulance 600 or staff members in the medical institution 601 who treat the patient. The doctors can check the condition of the patient in detail in the medical institution 601 while the patient is taken by the ambulance because the distribution system in FIG. 16 can transmit a high-definition image. Therefore, the doctors can instruct the ambulance crews or the staff members appropriately in a short time, resulting in improvement of a lifesaving rate of patients.

The communication of video data between the medical institution 601 and the medical institution 602 can be performed in the same way. A medical image obtained from an image diagnostic device (such as CT or MRI) of the medical institution 601 can be transmitted to the medical institution 602. Here, the ambulance 600 is given as an example of the means to transport patients; however, an aircraft such as a helicopter or a vessel may be used.

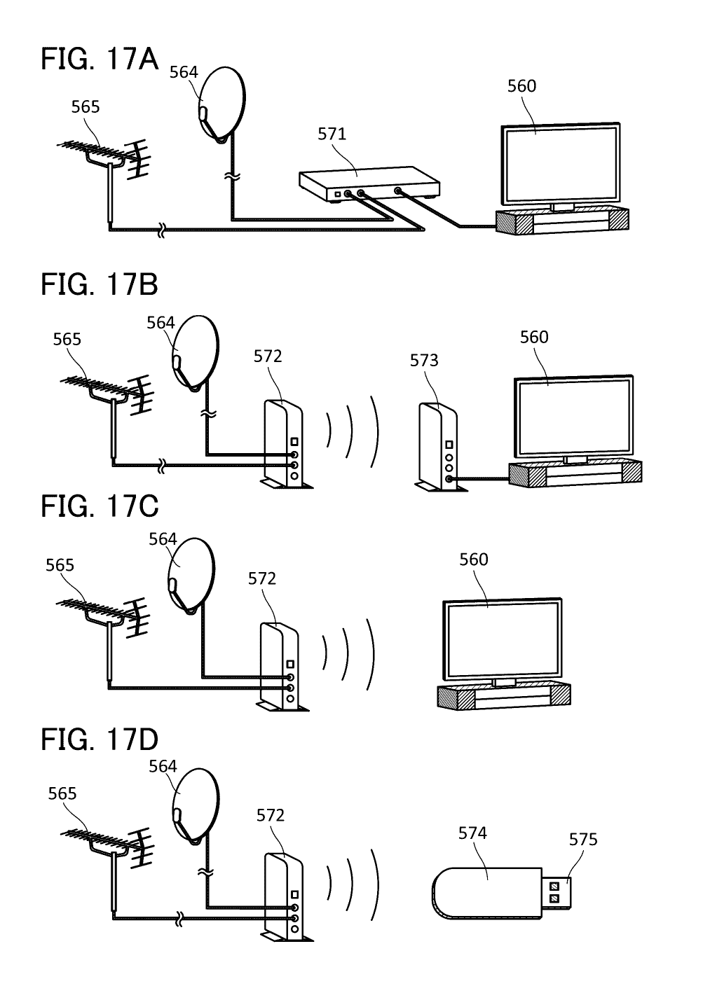

FIGS. 17A to 17D illustrate structure examples of a receiver. The TV 560 can receive a broadcast signal with a receiver and perform display. FIG. 17A illustrates a case where a receiver 571 is provided outside the TV 560. FIG. 17B illustrates another case where the antennas 564 and 565 and the TV 560 perform data transmission/reception through wireless devices 572 and 573. In this case, the wireless device 572 or 573 functions as a receiver. The wireless device 573 may be incorporated in the TV 560 as illustrated in FIG. 17C.

The size of a receiver can be reduced so that it can be portable. A receiver 574 illustrated in FIG. 17D includes a connector portion 575. If a display device and an electronic device such as an information terminal (e.g., a personal computer, a smartphone, a mobile phone, or a tablet terminal) include a terminal capable of being connected to the connector portion 575, they can be used to watch a satellite broadcast or a terrestrial broadcast.

The semiconductor device 100 described in Embodiment 1 can be used for the encoder 522 of the broadcast system 500 in FIG. 14. Alternatively, the encoder 522 can be formed by combining a dedicated IC, a processor (e.g., GPU or CPU), and the like. Alternatively, the encoder 522 can be integrated into one dedicated IC chip.

### <Encoder>

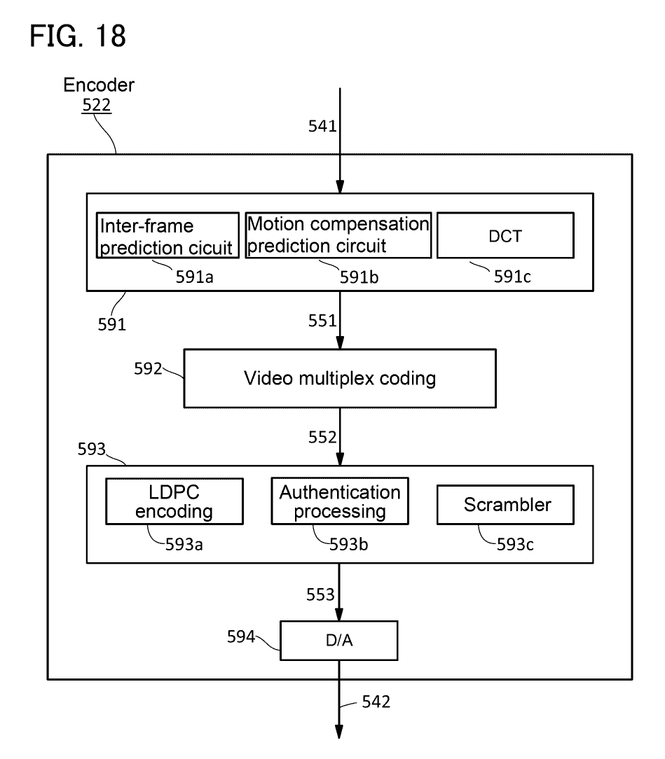

FIG. 18 is a block diagram showing an example of the encoder 522. The encoder 522 includes circuits 591 to 594.

The circuit 591 performs source encoding, and includes an inter-frame prediction circuit 591a, a motion compensation prediction circuit 591b, and a DCT circuit 591c. The circuit 592 includes a video multiplex encoding processing circuit. The circuit 593 includes a low density parity check (LDPC) encoding circuit 593a, an authentication processing circuit 593b, and a scrambler 593c. The circuit 594 is a digital-analog conversion (DAC) portion.

The circuit 591 performs source encoding of the transmitted video data 541. The source encoding means processing by which a redundant component is removed from the video data. Note that the completely original video data cannot be obtained from data output from the circuit 591; the source encoding is irreversible processing.

The inter-frame prediction circuit 591a makes a prediction image of a frame to be encoded from the previous and/or subsequent frames to encode the prediction image. The motion compensation prediction circuit 591b detects a motion, a change in shape, or the like of an object in the video data 541, calculates the amount of the change, rotation, expansion/contraction, or the like, makes a prediction image of a frame including the object, and encodes the prediction image. The DCT circuit 591c uses discrete cosine transform to convert pixel region data of the video data into frequency domain information.

The circuit 591 has a function of quantization of the source-encoded video data 541 through the inter-frame prediction circuit 591a, the motion compensation prediction circuit 591b, and the DCT circuit 591c. The quantization means operation of matching frequency components obtained by the DCT circuit 591c with the respective discrete values. This operation can reduce the large data in the video data 541. To the circuit 592, the circuit 591 transmits the video data that is source-encoded and quantized and a data stream 551 including data obtained by motion-compensated prediction.

The circuit 592 changes the data in the data stream 551 into a variable-length code and compresses it to multiplex (performs video multiplex coding). To multiplex means operation of arranging a plurality of data so that they can be transmitted as one bit column or bite column. The data subjected to video multiplex coding is transmitted to the circuit 593 as a data stream 552.

The circuit 593 mainly performs error correction coding, authentication, and encryption of the data stream 552 transmitted from the circuit 592. The LDPC encoding circuit 593a performs error correction coding and transmits data through a communication channel with noise. The authentication processing circuit 593b gives an identifier (ID) code, a password, and the like to data to be transmitted in order to prevent data recovery in an unintended receiver. The scrambler 593c converts a transmission data column of data to be transmitted into a random column irrelevant to a signal data column. The converted data can be restored to the original data by descrambling at a receiver. The circuit 593 performs error correction coding, authentication, and encryption of the data stream 552, and transmits the results as a data stream 553 to the circuit 594.

The circuit 594 performs digital-analog conversion of the data stream 553 to transmit the data stream 553 to the receiver 512. The data stream 553 subjected to digital-analog conversion is transmitted to the modulator 523 as encoded data 542.

This embodiment can be combined with any of the other embodiments in this specification as appropriate.

### Embodiment 4

This embodiment will describe a semiconductor device used for the broadcast system.

### <<Image Sensor>>

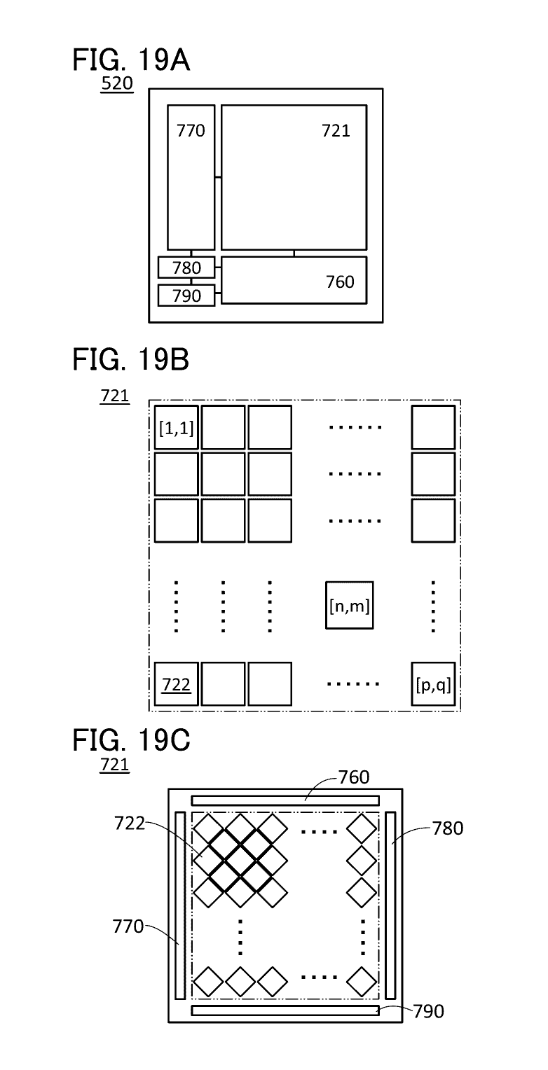

FIG. 19A is a plan view illustrating a structure example of the image sensor 520. The image sensor 520 includes a pixel portion 721 and circuits 760, 770, 780, and 790. In this specification and the like, the circuits 760, 770, 780, and 790 and the like may be referred to as a “peripheral circuit” or a “driver”. For example, the circuit 760 can be regarded as part of the peripheral circuit.

FIG. 19B illustrates a structure example of the pixel portion 721. The pixel portion 721 includes a plurality of pixels (image sensor) 722 arranged in a matrix of p columns by q rows (p and q are each a natural number of greater than or equal to 2). Note that in FIG. 19B, n is a natural number of greater than or equal to 1 and less than or equal to p, and m is a natural number of greater than or equal to 1 and less than or equal to q.

The circuits 760 and 770 are electrically connected to the plurality of pixels 722 and have a function of supplying signals for driving the plurality of pixels 722. The circuit 760 may have a function of processing an analog signal output from the pixels 722. The circuit 780 may have a function of controlling the operation timing of the peripheral circuit. For example, the circuit 780 may have a function of generating a clock signal. Furthermore, the circuit 780 may have a function of converting the frequency of a clock signal supplied from the outside. Moreover, the circuit 780 may have a function of supplying a reference potential signal (e.g., a ramp wave signal).

The peripheral circuit includes at least one of a logic circuit, a switch, a buffer, an amplifier circuit, and a converter circuit. Transistors or the like included in the peripheral circuit may be formed using part of a semiconductor that is formed to fabricate an after-mentioned pixel driver circuit 710. A semiconductor device such as an IC chip may be used as part or the whole of the peripheral circuit.

Note that in the peripheral circuit, at least one of the circuits 760, 770, 780, and 790 may be omitted. For example, when one of the circuits 760 and 790 additionally has a function of the other of the circuits 760 and 790, the other of the circuits 760 and 790 may be omitted. For another example, when one of the circuits 770 and 780 additionally has a function of the other of the circuits 770 and 780, the other of the circuits 770 and 780 may be omitted. For another example, a function of another peripheral circuit may be added to one of the circuits 760, 770, 780, and 790 to omit that peripheral circuit.

As illustrated in FIG. 19C, the circuits 760, 770, 780, and 790 may be provided along the periphery of the pixel portion 721. In the pixel portion 721 included in the image sensor 520, the pixels 722 may be obliquely arranged. When the pixels 722 are inclined, the space between the pixels in the row direction and the column direction (pitch) can be decreased. Accordingly, the quality of an image taken with the image sensor 520 can be improved.

The pixel portion 721 may be provided over the circuits 760, 770, 780, and 790 to overlap with the circuits 760, 770, 780, and 790. The provision of the pixel portion 721 over the circuits 760, 770, 780, and 790 to overlap with the circuits 760, 770, 780, and 790 can increase the area occupied by the pixel portion 721 for the image sensor 520. Accordingly, the light sensitivity, the dynamic range, the resolution, the reproducibility of a taken image, or the integration degree of the image sensor 520 can be increased.

When the pixels 722 included in the image sensor 520 are used as subpixels and the plurality of pixels 722 are provided with filters that transmit light in different wavelength ranges (color filters), data for achieving color image display can be obtained.

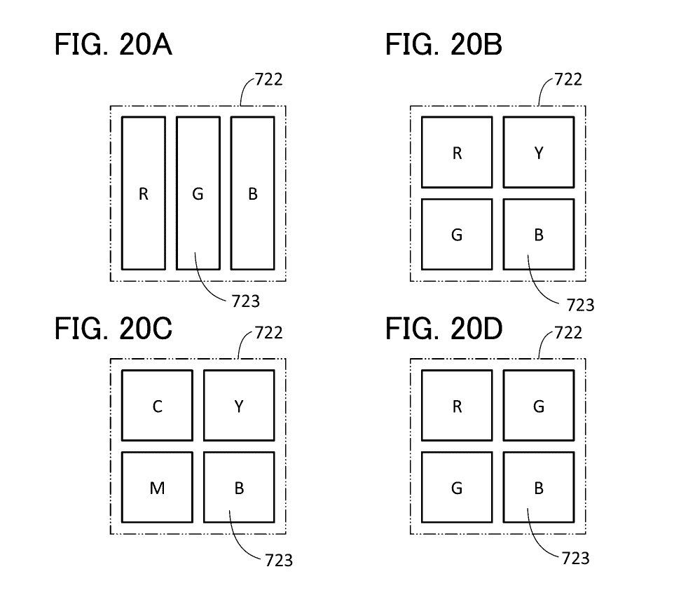

FIG. 20A is a plan view showing an example of the pixel 722 with which a color image is obtained. In FIG. 20A, a pixel 723 provided with a color filter that transmits light in a red (R) wavelength range (also referred to as “pixel 723R”), a pixel 723 provided with a color filter that transmits light in a green (G) wavelength range (also referred to as “pixel 723G”), and a pixel 723 provided with a color filter that transmits light in a blue (B) wavelength range (also referred to as “pixel 723B”) are provided. The pixel 723R, the pixel 723G, and the pixel 723B collectively function as one pixel 722.

The color filters used in the pixel 722 are not limited to red (R), green (G), and blue (B) color filters, and color filters that transmit light of cyan (C), yellow (Y), and magenta (M) may be used. When the pixels 722 each of which senses light in at least three different wavelength ranges are provided, a full-color image can be obtained.

FIG. 20B illustrates the pixel 722 including a pixel 723 provided with a color filter that transmits yellow (Y) light, in addition to the pixels 723 provided with the color filters that transmit red (R), green (G), and blue (B) light. FIG. 20C illustrates the pixel 722 including a pixel 723 provided with a color filter that transmits blue (B) light, in addition to the pixels 723 provided with the color filters that transmit cyan (C), yellow (Y), and magenta (M) light. When the pixels 722 each of which senses light in four or more different wavelength ranges are provided in this way, the reproducibility of colors of an obtained image can be increased.

The pixel number ratio (or the ratio of light receiving area) of the pixel 723R to the pixel 723G and the pixel 723B is not necessarily 1:1:1. The pixel number ratio (the ratio of light receiving area) of red to green and blue may be 1:2:1 (Bayer arrangement), as illustrated in FIG. 20D. Alternatively, the pixel number ratio (the ratio of light receiving area) of red to green and blue may be 1:6:1.

Although the number of pixels 723 used in the pixel 722 may be one, two or more is preferable. For example, when two or more pixels 723 that sense light in the same wavelength range are provided, the redundancy is increased, and the reliability of the image sensor 520 can be increased.

When an infrared (IR) filter that transmits infrared light and absorbs or reflects light in a wavelength shorter than or equal to that of visible light is used as the filter, the image sensor 520 that detects infrared light can be achieved. Alternatively, when an ultra violet (UV) filter that transmits ultraviolet light and absorbs or reflects light in a wavelength longer than or equal to that of visible light is used as the filter, the image sensor 520 that detects ultraviolet light can be achieved. Alternatively, when a scintillator that turns a radiant ray into ultraviolet light or visible light is used as the filter, the image sensor 520 can be used as a radiation detector that detects an X-ray or a y-ray.

When a neutral density (ND) filter (dimming filter) is used as a filter, a phenomenon of output saturation, which is caused when an excessive amount of light enters a photoelectric conversion element (light-receiving element), can be prevented. With a combination of ND filters with different dimming capabilities, the dynamic range of the image sensor can be increased.

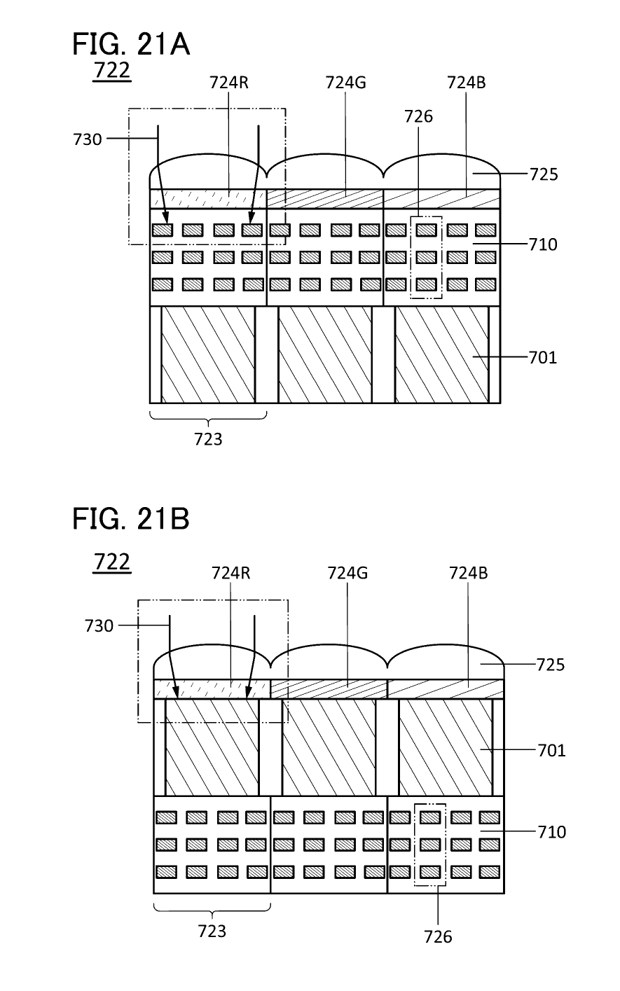

Besides the above-described filter, the pixel 723 may be provided with a lens. An arrangement example of the pixel 723, a filter 724, and a lens 725 will be described with reference to cross-sectional views in FIGS. 21A and 21B. With the lens 725, incident light can be efficiently received by a photoelectric conversion element. Specifically, as illustrated in FIG. 21A, light 730 enters a photoelectric conversion element 701 through the lens 725, the filter 724 (a filter 724R, a filter 724G, or a filter 724B), a pixel driver 710, and the like formed in the pixel 723.

However, as illustrated in a region surrounded by the two-dot chain line, part of light 730 indicated by the arrows may be blocked by part of a wiring group 726, such as a transistor and/or a capacitor. Thus, a structure in which the lens 725 and the filter 724 are provided on the photoelectric conversion element 701 side, as illustrated in FIG. 21B, may be employed such that the incident light is efficiently received by the photoelectric conversion element 701. When the light 730 is incident on the photoelectric conversion element 701 side, the image sensor 520 with high light sensitivity can be provided.

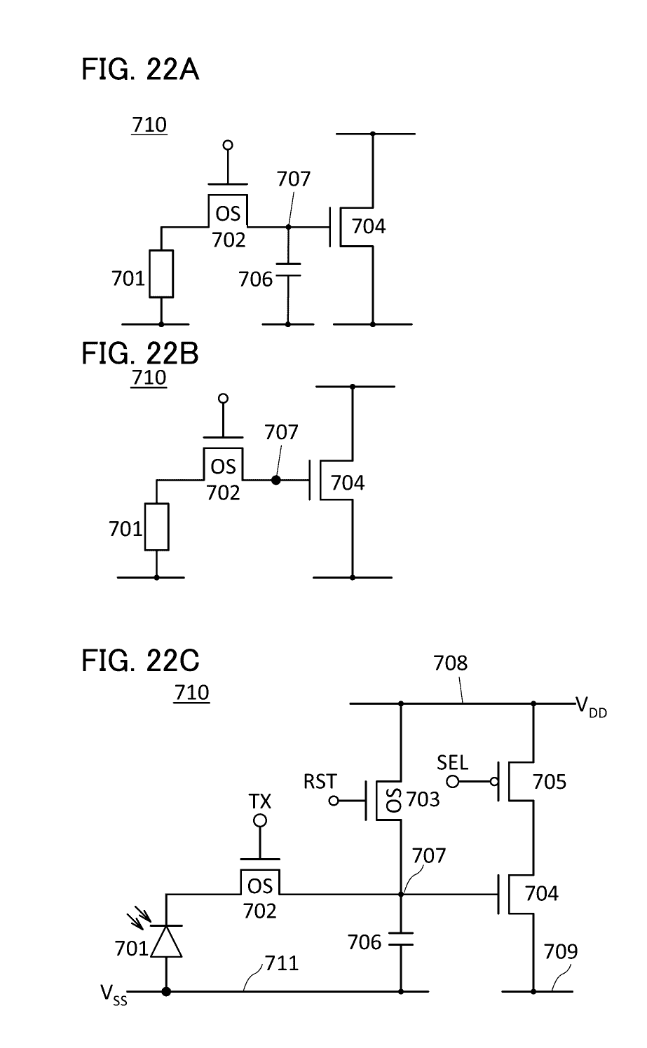

FIGS. 22A to 22C illustrate examples of the pixel driver 710 that can be used for the pixel portion 721. The pixel driver 710 illustrated in FIG. 22A includes a transistor 702, a transistor 704, and a capacitor 706 and is connected to the photoelectric conversion element 701. One of a source and a drain of the transistor 702 is electrically connected to the photoelectric conversion element 701, and the other of the source and the drain of the transistor 702 is electrically connected to a gate of the transistor 704 through a node 707 (a charge accumulation portion).

“OS” indicates that it is preferable to use an OS transistor. The same applies to the other drawings. Since the off-state current of the OS transistor is extremely low, the capacitor 706 can be made small. Alternatively, the capacitor 706 can be omitted as illustrated in FIG. 22B. Furthermore, when the transistor 702 is an OS transistor, the potential of the node 707 is less likely to be changed. Thus, an image sensor that is less likely to be affected by noise can be provided. Note that the transistor 704 may be an OS transistor.

A diode element formed using a silicon substrate with a PN junction or a PIN junction can be used as the photoelectric conversion element 701. Alternatively, a PIN diode element formed using an amorphous silicon film, a microcrystalline silicon film, or the like may be used. Alternatively, a diode-connected transistor may be used. Alternatively, a variable resistor or the like utilizing a photoelectric effect may be formed using silicon, germanium, selenium, or the like.

The photoelectric conversion element may be formed using a material capable of generating electric charge by absorbing radiation. Examples of the material capable of generating electric charge by absorbing radiation include lead iodide, mercury iodide, gallium arsenide, CdTe, and CdZn.

The pixel driver 710 illustrated in FIG. 22C includes the transistor 702, a transistor 703, the transistor 704, a transistor 705, and the capacitor 706 and is connected to the photoelectric conversion element 701. In the pixel driver 710 illustrated in FIG. 22C, a photodiode is used as the photoelectric conversion element 701. One of a source and a drain of the transistor 702 is electrically connected to a cathode of the photoelectric conversion element 701, and the other of the source and the drain of the transistor 702 is electrically connected to the node 707. An anode of the photoelectric conversion element 701 is electrically connected to a wiring 711. One of a source and a drain of the transistor 703 is electrically connected to the node 707. The other of the source and the drain of the transistor 703 is electrically connected to a wiring 708. The gate of the transistor 704 is electrically connected to the node 707. One of a source and a drain of the transistor 704 is electrically connected to a wiring 709. The other of the source and the drain of the transistor 704 is electrically connected to one of a source and a drain of the transistor 705. The other of the source and the drain of the transistor 705 is electrically connected to the wiring 708. One electrode of the capacitor 706 is electrically connected to the node 707. The other electrode of the capacitor 706 is electrically connected to the wiring 711.

The transistor 702 can function as a transfer transistor. A gate of the transistor 702 is supplied with a transfer signal TX. The transistor 703 can function as a reset transistor. A gate of the transistor 703 is supplied with a reset signal RST. The transistor 704 can function as an amplifier transistor. The transistor 705 can function as a selection transistor. A gate of the transistor 705 is supplied with a signal SEL. Moreover, VDD is supplied to the wiring 708 and Vss is supplied to the wiring 711.

Next, operation of the pixel driver 710 illustrated in FIG. 22C are described. First, the transistor 703 is turned on so that VDD is supplied to the node 707 (reset operation). Then, the transistor 703 is turned off, so that VDD is held in the node 707. Next, the transistor 702 is turned on, so that the potential of the node 707 is changed in accordance with the amount of light received by the photoelectric conversion element 701 (accumulation operation). After that, the transistor 702 is turned off so that the potential of the node 707 is stored. Then, the transistor 705 is turned on, so that a potential corresponding to the potential of the node 707 is output from the wiring 709 (selection operation). Measuring the potential of the wiring 709 can determine the amount of light received by the photoelectric conversion element 701.

An OS transistor is preferably used as each of the transistors 702 and 703. Since the off-state current of the OS transistor is extremely low as described above, the capacitor 706 can be small or omitted. Furthermore, when the transistors 702 and 703 are OS transistors, the potential of the node 707 is less likely to change. Thus, the image sensor 520 that is less likely to be affected by noise can be provided.

### <<Display Device>>

The display device 513 includes at least one of an electroluminescence (EL) element (e.g., an EL element including organic and inorganic materials, an organic EL element, or an inorganic EL element), a light-emitting diode (LED) chip (e.g., a white LED chip, a red LED chip, a green LED chip, or a blue LED chip), a transistor (a transistor that emits light depending on current), an electron emitter, a display element including a carbon nanotube, a liquid crystal element, electronic ink, an electrowetting element, an electrophoretic element, a display element using micro electro mechanical systems (MEMS) (such as a grating light valve (GLV), a digital micromirror device (DMD), a digital micro shutter (DMS), MIRASOL (registered trademark), an interferometric modulation (IMOD) element, a MEMS shutter display element, an optical-interference-type MEMS display element, or a piezoelectric ceramic display), quantum dots, and the like.

Other than the above, a display medium whose contrast, luminance, reflectance, transmittance, or the like is changed by electric or magnetic action may be included in the display device. For example, the display device may be a plasma display panel (PDP).

Note that examples of display devices having EL elements include an EL display. Examples of display devices including electron emitters are a field emission display (FED) and an SED-type flat panel display (SED: surface-conduction electron-emitter display).

Examples of display devices containing quantum dots in each pixel include a quantum dot display. Note that quantum dots may be provided not as display elements but as part of a backlight unit used for a liquid crystal display device or the like. The use of quantum dots enables display with high color purity.

Examples of display devices including liquid crystal elements include a liquid crystal display device (e.g., a transmissive liquid crystal display, a transflective liquid crystal display, a reflective liquid crystal display, a direct-view liquid crystal display, or a projection liquid crystal display).

In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes, leading to lower power consumption.

Examples of display devices including electronic ink, electronic liquid powder (registered trademark), or electrophoretic elements include electronic paper.

Note that in the case of using an LED chip for a display element or the like, graphene or graphite may be provided under an electrode or a nitride semiconductor of the LED chip. Graphene or graphite may be a multilayer film in which a plurality of layers are stacked. The provision of graphene or graphite enables easy formation of a nitride semiconductor layer thereover, such as an n-type GaN semiconductor layer including crystals. Furthermore, a p-type GaN semiconductor layer including crystals or the like can be provided thereover so that the LED chip can be formed. Note that an AIN layer may be provided between the n-type GaN semiconductor layer including crystals and graphene or graphite. The GaN semiconductor layers included in the LED chip may be formed by MOCVD. Note that when the graphene is provided, the GaN semiconductor layers included in the LED chip can be formed by a sputtering method.

In the case of a display element including MEMS, a drying agent may be provided in a space where the display element is sealed (e.g., between an element substrate over which the display element is placed and a counter substrate opposed to the element substrate). Providing a drying agent can prevent MEMS and the like from becoming difficult to move or deteriorating easily because of moisture or the like.

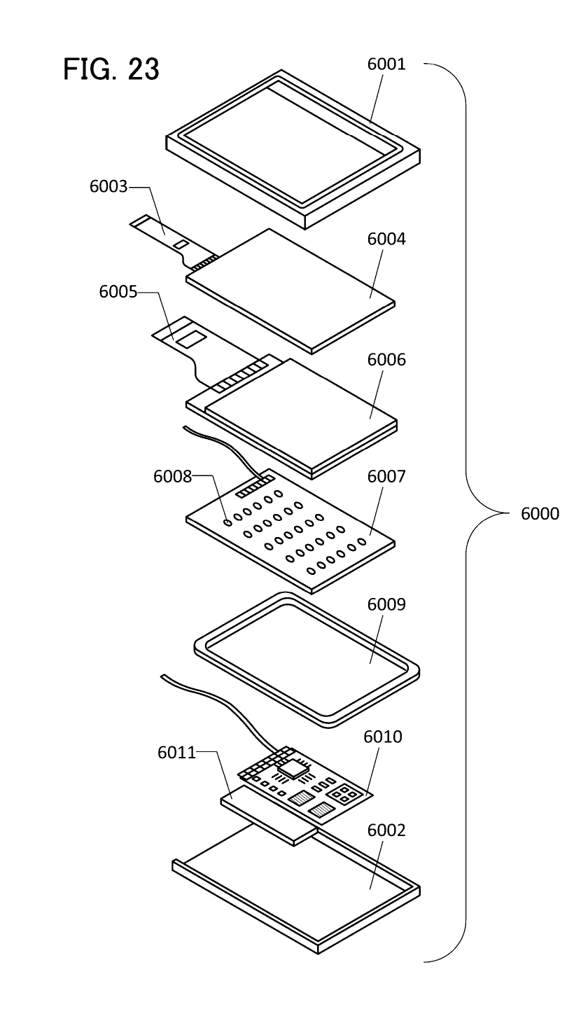

FIG. 23 illustrates a structure example of a display module used for the display device 513. In a display module 6000 in FIG. 23, a touch sensor 6004 connected to an FPC 6003, a display panel 6006 connected to an FPC 6005, a backlight unit 6007, a frame 6009, a printed board 6010, and a battery 6011 are provided between an upper cover 6001 and a lower cover 6002. Note that the backlight unit 6007, the battery 6011, the touch sensor 6004, and the like are not provided in some cases.

The semiconductor device of one embodiment of the present invention can be included in, for example, an integrated circuit mounted on the printed board 6010, and the like. The display portion 528 of the display device 513 is formed with the display panel 6006. The printed board 6010 is provided with a power supply circuit, a signal processing circuit for outputting a video signal and a clock signal, and the like. As a power source for supplying power to the power supply circuit, the battery 6011 or a commercial power source may be used. Note that the battery 6011 can be omitted in the case where a commercial power source is used as the power source. If necessary, the printed board 6010 may be provided with the receiver of one embodiment of the present invention.

The shapes and sizes of the upper cover 6001 and the lower cover 6002 can be changed as appropriate in accordance with the sizes of the touch sensor 6004, the display panel 6006, and the like.

The touch sensor 6004 can be a resistive touch panel or a capacitive touch panel and may be formed to overlap with the display panel 6006. The display panel 6006 can have a touch sensor function. For example, an electrode for a touch sensor may be provided in each pixel of the display panel 6006 so that a capacitive touch panel function is added. Alternatively, a photosensor may be provided in each pixel of the display panel 6006 so that an optical touch sensor function is added.

The backlight unit 6007 includes a light source 6008. The light source 6008 may be provided at an end portion of the backlight unit 6007 and a light diffusing plate may be used. When a light-emitting display device or the like is used for the display panel 6006, the backlight unit 6007 can be omitted. The frame 6009 protects the display panel 6006 and also functions as an electromagnetic shield for blocking electromagnetic waves generated from the printed board 6010 side. The frame 6009 may function as a radiator plate. The display module 6000 can be additionally provided with a member such as a polarizing plate, a retardation plate, or a prism sheet.

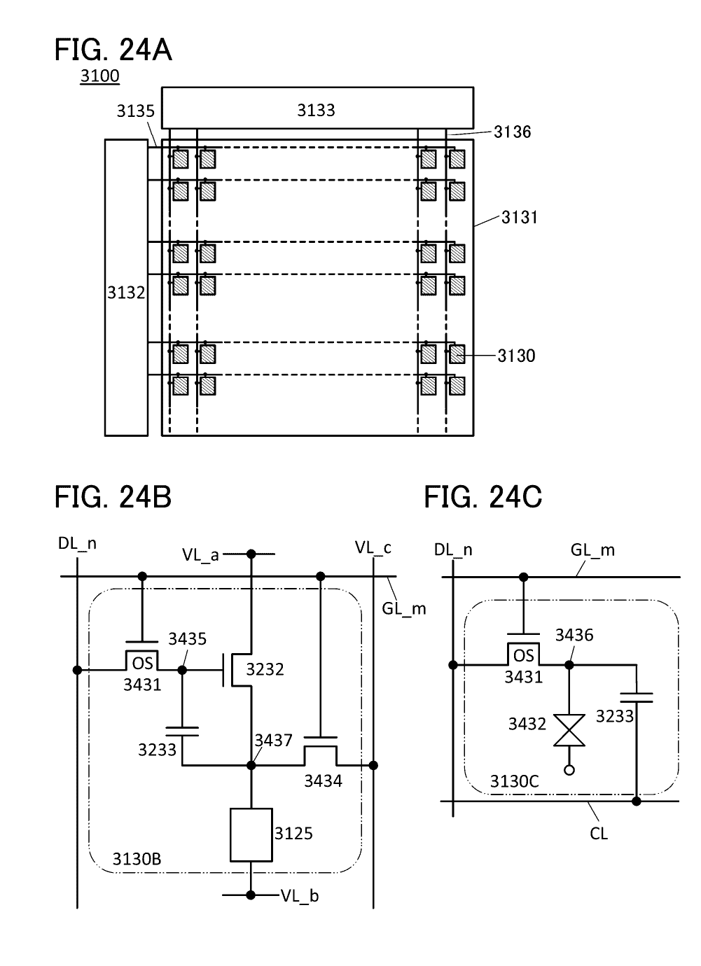

FIGS. 24A to 24C illustrate configuration examples of the display portion. A display portion 3100 in FIG. 24A includes a display area 3131 and circuits 3132 and 3133. The circuit 3132 functions as a scan line driver, for example, and the circuit 3133 functions as a signal line driver, for example.

The display portion 3100 includes m scan lines 3135 that are arranged parallel or substantially parallel to each other and whose potentials are controlled by the circuit 3132, and n signal lines 3136 that are arranged parallel or substantially parallel to each other and whose potentials are controlled by the circuit 3133. The display area 3131 includes a plurality of pixels 3130 arranged in a matrix of m rows by n columns. Note that in this embodiment, m and n are each an integer number of 2 or greater.

Each of the scan lines 3135 is electrically connected to the n pixels 3130 on the corresponding row among the pixels 3130 in the display area 3131. Each of the signal lines 3136 is electrically connected to the m pixels 3130 on the corresponding column among the pixels 3130.

FIGS. 24B and 24C are circuit diagrams illustrating configuration examples of the pixel 3130. A pixel 3130B in FIG. 24B is a pixel of a self-luminous display device, and a pixel 3130C in FIG. 24C is a pixel of a liquid crystal display device.

The pixel 3130B includes a transistor 3431, a capacitor 3233, a transistor 3232, a transistor 3434, and a light-emitting element 3125. The pixel 3130B is electrically connected to the signal line 3136 on the n-th column to which a data signal is supplied (hereinafter referred to as a signal line DL_n), the scan line 3135 on the m-th row to which a gate signal is supplied (hereinafter referred to as a scan line GL_m), and potential supply lines VL_a and VL_b.

A plurality of pixels 3130B are each used as a subpixel, and the subpixels emit light in different wavelength ranges, so that a color image can be obtained. For example, a pixel 3130 that emits light in a red wavelength range, a pixel 3130 that emits light in a green wavelength range, and a pixel 3130 that emits light in a blue wavelength range are used as one pixel.

The combination of the wavelength ranges of light is not limited to red, green, and blue and may be cyan, yellow, and magenta. When subpixels that emit light in at least three different wavelength ranges are provided in one pixel, a color image can be displayed.

Alternatively, one or more colors of yellow, cyan, magenta, white, and the like may be added to red, green, and blue. For example, a subpixel that emits light in a yellow wavelength range may be used, in addition to red, green, and blue. One or more of red, green, blue, white, and the like may be added to cyan, yellow, and magenta. For example, a subpixel that emits light in a blue wavelength range may be added in addition to cyan, yellow, and magenta. When subpixels that emit light in four or more different wavelength ranges are provided in one pixel, the reproducibility of colors of a displayed image can be further increased.

The pixel number ratio (or the ratio of light-emitting area) of red to green and blue used for one pixel need not be 1:1:1. For example, the pixel number ratio of red to green and blue may be 1:1:2. Alternatively, the pixel number ratio of red to green and blue may be 1:2:3.

A subpixel that emits white light may be combined with red, green, and blue color filters or the like to enable color display. Alternatively, a subpixel emitting light in a red wavelength range, a subpixel emitting light in a green wavelength range, and a subpixel emitting light in a blue wavelength range may be combined with a color filter transmitting light in a red wavelength, a color filter transmitting light in a green wavelength, and a color filter transmitting light in a blue wavelength, respectively.

The present invention is not limited to the application to a display device for color display but can also be applied to a display device for monochrome display.

The pixel 3130C illustrated in FIG. 24C includes the transistor 3431, the capacitor 3233, and a liquid crystal element 3432. The pixel 3130C is electrically connected to the signal line DL_n, the scan line GL_m, and a capacitor line CL.

The potential of one of a pair of electrodes of the liquid crystal element 3432 is set in accordance with the specifications of the pixel 3130C as appropriate. The alignment state of a liquid crystal in the liquid crystal element 3432 depends on data written to a node 3436. A common potential may be applied to the one of the pair of electrodes of the liquid crystal element 3432 included in each of the plurality of pixels 3130C. The potential of the capacitor line CL is set in accordance with the specifications of the pixel 3130C as appropriate. The capacitor 3233 functions as a storage capacitor for storing data written to the node 3436.

As examples of a mode of the liquid crystal element 3432, the following modes can be given: a TN mode, an STN mode, a VA mode, an axially symmetric aligned micro-cell (ASM) mode, an optically compensated birefringence (OCB) mode, a ferroelectric liquid crystal (FLC) mode, an antiferroelectric liquid crystal (AFLC) mode, an MVA mode, a patterned vertical alignment (PVA) mode, an IPS mode, an FFS mode, and a transverse bend alignment (TBA) mode. Other examples include an electrically controlled birefringence (ECB) mode, a polymer dispersed liquid crystal (PDLC) mode, a polymer network liquid crystal (PNLC) mode, and a guest-host mode. Note that the present invention is not limited to these modes, and various modes can be used.

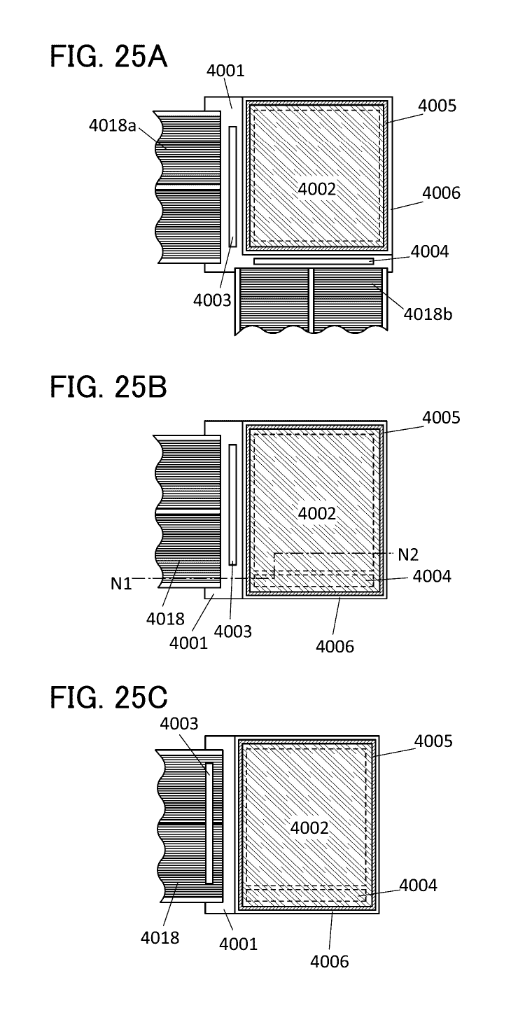

The device structure of the display panel will be described with reference to FIGS. 25A to 25C, FIGS. 26A and 26B, and FIGS. 27A and 27B. In FIG. 25A, a sealant 4005 is provided so as to surround a pixel portion 4002 provided over a substrate 4001, and the pixel portion 4002 is sealed by the sealant 4005 and a substrate 4006. In FIG. 25A, a signal line driver 4003 and a scan line driver 4004 each are formed using a single crystal semiconductor or a polycrystalline semiconductor over another substrate, and mounted in a region different from the region surrounded by the sealant 4005 over the substrate 4001. Various signals and potentials are supplied to the signal line driver 4003, the scan line driver 4004, or the pixel portion 4002 through flexible printed circuits (FPCs) 4018a and 4018b.

In FIGS. 25B and 25C, the sealant 4005 is provided so as to surround the pixel portion 4002 and the scan line driver 4004 that are provided over the substrate 4001. The substrate 4006 is provided over the pixel portion 4002 and the scan line driver 4004. Hence, the pixel portion 4002 and the scan line driver 4004 are sealed together with the display element by the substrate 4001, the sealant 4005, and the substrate 4006. In FIGS. 25B and 25C, a signal line driver 4003 formed using a single crystal semiconductor or a polycrystalline semiconductor over a substrate separately prepared is mounted in a region different from the region surrounded by the sealant 4005 over the substrate 4001. In FIGS. 25B and 25C, various signals and potentials are supplied to the signal line driver 4003, the scan line driver 4004, or the pixel portion 4002 through an FPC 4018.

Although FIGS. 25B and 25C each illustrate an example in which the signal line driver 4003 is formed separately and mounted on the substrate 4001, one embodiment of the present invention is not limited to this structure. The scan line driver may be separately formed and then mounted, or only part of the signal line driver or only part of the scan line driver may be separately formed and then mounted.

The connection method of a separately formed driver is not particularly limited; wire bonding, a chip on glass (COG), a tape carrier package (TCP), a chip on film (COF), or the like can be used. FIG. 25A illustrates an example in which the signal line driver 4003 and the scan line driver 4004 are mounted by a COG. FIG. 25B illustrates an example in which the signal line driver 4003 is mounted by a COG. FIG. 25C illustrates an example in which the signal line driver 4003 is mounted by a TCP. In some cases, the display device encompasses a panel in which a display element is sealed, and a module in which an IC or the like including a controller is mounted on the panel. The pixel portion and the scan line driver provided over the substrate 4001 include a plurality of transistors to which the transistor that is described in the above embodiment can be applied.

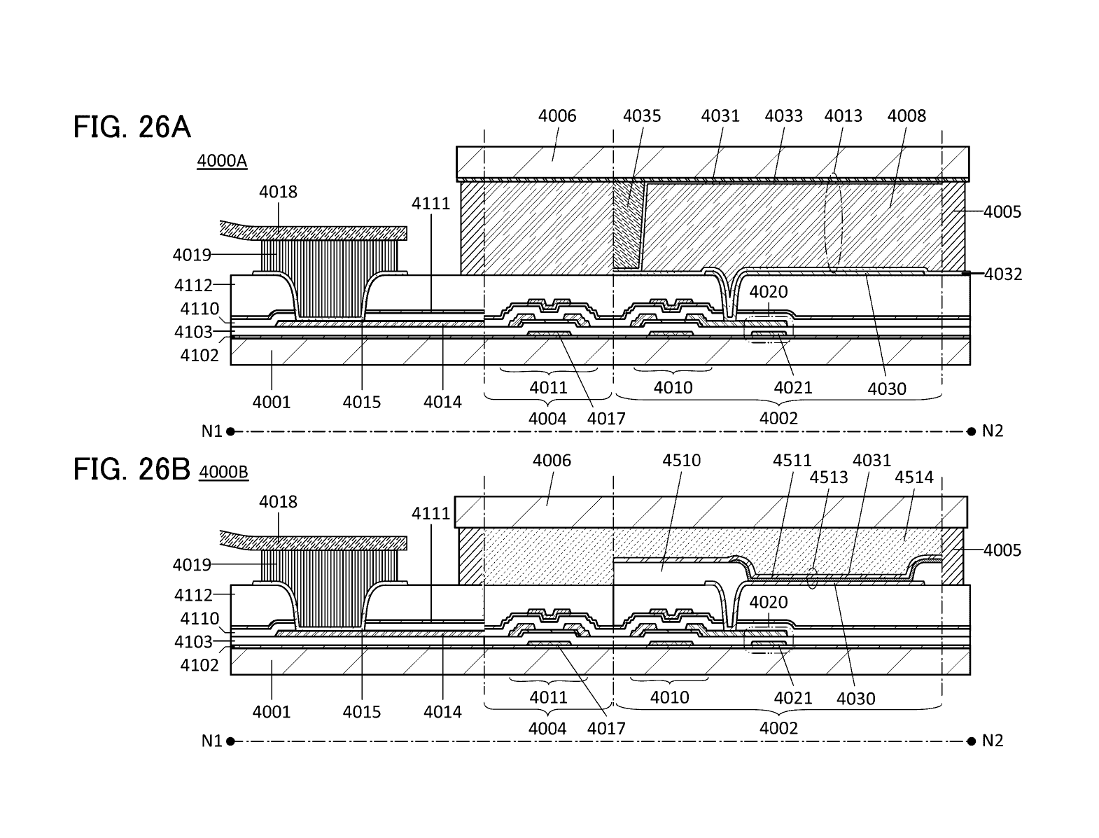

FIGS. 26A and 26B correspond to cross-sectional views taken along chain line N1-N2 in FIG. 25B. FIG. 26A illustrates a display panel 4000A of a liquid crystal display device, and FIG. 26B illustrates a display panel 4000B of a self-luminous display device.

The display panel 4000A has an electrode 4015, and the electrode 4015 is electrically connected to a terminal included in the FPC 4018 through an anisotropic conductive layer 4019. The electrode 4015 is electrically connected to a wiring 4014 in an opening formed in insulating layers 4112, 4111, and 4110. The display panel 4000A includes transistors 4010 and 4011 and a capacitor 4020. The capacitor 4020 includes a region where part of a source electrode or drain electrode of the transistor 4010 overlaps with an electrode 4021 with an insulating layer 4103 interposed therebetween. The electrode 4021 is formed using the same conductive layer as the electrode 4017. The electrode 4015 is formed of the same conductive layer as a first electrode layer 4030, and the wiring 4014 is formed of the same conductive layer as source and drain electrodes of transistors 4010 and 4011. The same applies to the display panel 4000B.

The pixel portion 4002 and the scan line driver 4004 provided over the substrate 4001 include a plurality of transistors. In FIGS. 26A and 26B, the transistor 4010 included in the pixel portion 4002 and the transistor 4011 included in the scan line driver 4004 are illustrated as an example. The insulating layers 4112, 4111, and 4110 are provided over the transistors 4010 and 4011 in FIG. 26A, and a bank 4510 is further provided over the insulating layer 4112 in FIG. 26B.

In general, the capacitance of a capacitor provided in a pixel is set in consideration of leakage current or the like of transistors provided in the pixel so that charge can be held for a predetermined period. The capacitance of the capacitor may be set considering off-state current of the transistor or the like. For example, when an OS transistor is used in a pixel portion of a liquid crystal display device, the capacitance of the capacitor can be one-third or less, or one-fifth or less, of the capacitance of a liquid crystal. Using an OS transistor can omit the formation of a capacitor.

In FIG. 26A, a liquid crystal element 4013 includes the first electrode layer 4030, a second electrode layer 4031, and a liquid crystal layer 4008. Note that an insulating layer 4032 and an insulating layer 4033 each functioning as alignment films are provided so that the liquid crystal layer 4008 is provided therebetween. The second electrode layer 4031 is provided on the substrate 4006 side, and the first electrode layer 4030 and the second electrode layer 4031 overlap with each other with the liquid crystal layer 4008 positioned therebetween.

A spacer 4035 is a columnar spacer obtained by selective etching of an insulating layer and is provided in order to control the distance between the first electrode layer 4030 and the second electrode layer 4031 (a cell gap). Alternatively, a spherical spacer may be used.

In the case where a liquid crystal element is used as the display element, thermotropic liquid crystal, low-molecular liquid crystal, high-molecular liquid crystal, polymer-dispersed liquid crystal, ferroelectric liquid crystal, anti-ferroelectric liquid crystal, or the like can be used. Such a liquid crystal material exhibits a cholesteric phase, a smectic phase, a cubic phase, a chiral nematic phase, an isotropic phase, or the like depending on conditions.

Alternatively, a liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which 5 weight percent or more of a chiral material is mixed is used for the liquid crystal layer in order to improve the temperature range. The liquid crystal composition which includes the liquid crystal exhibiting a blue phase and the chiral material has a short response time of 1 msec or less and is optically isotropic; therefore, alignment treatment is not necessary and viewing angle dependence is small. An alignment film does not need to be provided and rubbing treatment is thus not necessary; accordingly, electrostatic discharge damage caused by the rubbing treatment can be prevented and defects and damage of the liquid crystal display device in the manufacturing process can be reduced. Thus, productivity of the liquid crystal display device can be improved.

Furthermore, it is possible to use a method called domain multiplication or multi-domain design, in which a pixel is divided into some regions (subpixels) and molecules are aligned in different directions in their respective regions.

The specific resistivity of the liquid crystal material is greater than or equal to 1×10⁹ Ω·cm, preferably greater than or equal to 1×10¹¹ Ω·cm, still preferably greater than or equal to 1×10¹² Ω·cm. Note that the specific resistivity in this specification is measured at 20° C.

In the OS transistor used in this embodiment, the current in an off state (the off-state current) can be made small. Accordingly, an electrical signal such as an image signal can be held for a longer period, and a writing interval can be set longer in an on state. Accordingly, frequency of refresh operation can be reduced, which leads to an effect of suppressing power consumption.

In the OS transistor, relatively high field-effect mobility can be obtained, whereby high-speed operation is possible. Consequently, when the above transistor is used in a pixel portion of a display device, high-quality images can be obtained. Since a driver portion and a pixel portion can be separately formed over one substrate with the use of the above transistor, the number of components of the display device can be reduced.

In the display device, a black matrix (a light-blocking layer), an optical member (an optical substrate) such as a polarizing member, a retardation member, or an anti-reflection member, and the like may be provided as appropriate. For example, circular polarization may be employed by using a polarizing substrate and a retardation substrate. In addition, a backlight, a sidelight, or the like may be used as a light source.

As the display element included in the display device, a light-emitting element utilizing electroluminescence (also referred to as an “EL element”) can be used. An EL element includes a layer containing a light-emitting compound (also referred to as an “EL layer”) between a pair of electrodes. By generating a potential difference between the pair of electrodes that is greater than the threshold voltage of the EL element, holes are injected to the EL layer from the anode side and electrons are injected to the EL layer from the cathode side. The injected electrons and holes are recombined in the EL layer, so that a light-emitting substance contained in the EL layer emits light.

EL elements are classified depending on whether a light-emitting material is an organic compound or an inorganic compound. In general, the former is referred to as an organic EL element, and the latter is referred to as an inorganic EL element.

In an organic EL element, by voltage application, electrons are injected from one electrode to the EL layer and holes are injected from the other electrode to the EL layer. Then, recombination of these carriers (the electrons and holes) makes the light-emitting organic compound form an excited state and emit light when it returns from the excited state to a ground state. Based on such a mechanism, such a light-emitting element is referred to as a current-excitation type light-emitting element.

In addition to the light-emitting compound, the EL layer may further include any of a substance with a high hole-injection property, a substance with a high hole-transport property, a hole-blocking material, a substance with a high electron-transport property, a substance with a high electron-injection property, a substance with a bipolar property (a substance with a high electron- and hole-transport property), and the like.

The EL layer can be formed by an evaporation method (including a vacuum evaporation method), a transfer method, a printing method, an inkjet method, a coating method, or the like.

Inorganic EL elements are classified as a dispersed inorganic EL element and a thin-film inorganic EL element depending on their element structures. A dispersed inorganic EL element has a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localized type light emission that utilizes inner-shell electron transition of metal ions. Note that description is given here using an organic EL element as a light-emitting element.

In order to extract light emitted from the light-emitting element, at least one of a pair of electrodes is transparent. The light-emitting element and a transistor are formed over a substrate, and the light-emitting element can have any of the following emission structures: a top emission structure in which light emission is extracted from the side opposite to the substrate; a bottom emission structure in which light emission is extracted from the substrate side; and a dual emission structure in which light emission is extracted from both the side opposite to the substrate and the substrate side.

In FIG. 26B, a light-emitting element 4513 is electrically connected to the transistor 4010 in the pixel portion 4002. The structure of the light-emitting element 4513 is the stacked-layer structure including the first electrode layer 4030, a light-emitting layer 4511, and the second electrode layer 4031; however, this embodiment is not limited to this structure. The structure of the light-emitting element 4513 can be changed as appropriate depending on a direction in which light is extracted from the light-emitting element 4513, or the like.

The bank 4510 is formed using an organic insulating material or an inorganic insulating material. It is particularly preferable that the bank 4510 be formed using a photosensitive resin material to have an opening over the first electrode layer 4030 so that a side surface of the opening slopes with continuous curvature.

The light-emitting layer 4511 may be formed using a single layer or a plurality of layers stacked.

A protective layer may be formed over the second electrode layer 4031 and the bank 4510 in order to prevent entry of oxygen, hydrogen, moisture, carbon dioxide, or the like into the light-emitting element 4513. For the protective layer, silicon nitride, silicon nitride oxide, aluminum oxide, aluminum nitride, aluminum oxynitride, aluminum nitride oxide, diamond like carbon (DLC), or the like can be used. In addition, in a space which is enclosed by the substrate 4001, the substrate 4006, and the sealant 4005, a filler 4514 is provided for sealing. It is preferable that, in this manner, the light-emitting element be packaged (sealed) with a protective film (such as a laminate film or an ultraviolet curable resin film) or a cover member with high air-tightness and little degasification so that the light-emitting element is not exposed to the outside air.

As the filler 4514, an ultraviolet curable resin or a thermosetting resin can be used as well as an inert gas such as nitrogen or argon. For example, polyvinyl chloride (PVC), an acrylic resin, polyimide, an epoxy resin, a silicone resin, polyvinyl butyral (PVB), or ethylene vinyl acetate (EVA) can be used. A drying agent may be contained in the filler 4514.

A glass material such as a glass frit, or a resin that is curable at room temperature such as a two-component-mixture-type resin, a light curable resin, a thermosetting resin, and the like can be used for the sealant 4005. A drying agent may be contained in the sealant 4005.

In addition, if needed, an optical film, such as a polarizing plate, a circularly polarizing plate (including an elliptically polarizing plate), a retardation plate (a quarter-wave plate or a half-wave plate), or a color filter, may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface so as to reduce the glare can be performed.

When the light-emitting element has a microcavity structure, light with high color purity can be extracted. Furthermore, when a microcavity structure and a color filter are used in combination, the glare can be reduced and visibility of a display image can be increased.

The first electrode layer and the second electrode layer (also called a pixel electrode layer, common electrode layer, counter electrode layer, or the like) for applying voltage to the display element may have light-transmitting properties or light-reflecting properties, which depends on the direction in which light is extracted, the position where the electrode layer is provided, the pattern structure of the electrode layer, and the like.

The first electrode layer 4030 and the second electrode layer 4031 can be formed using a light-transmitting conductive material such as indium oxide containing tungsten oxide, indium zinc oxide containing tungsten oxide, indium oxide containing titanium oxide, indium tin oxide, indium tin oxide containing titanium oxide, indium zinc oxide, or indium tin oxide to which silicon oxide is added.

The first electrode layer 4030 and the second electrode layer 4031 each can also be formed using one or plural kinds selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); alloys thereof; and nitrides thereof.

Alternatively, a conductive composition containing a conductive high molecule (also called a conductive polymer) can be used for the first electrode layer 4030 and the second electrode layer 4031. As the conductive high molecule, a so-called π-electron conjugated conductive high molecule can be used. Examples include polyaniline or a derivative thereof, polypyrrole or a derivative thereof, polythiophene or a derivative thereof, and a copolymer of two or more of aniline, pyrrole, and thiophene or a derivative thereof.

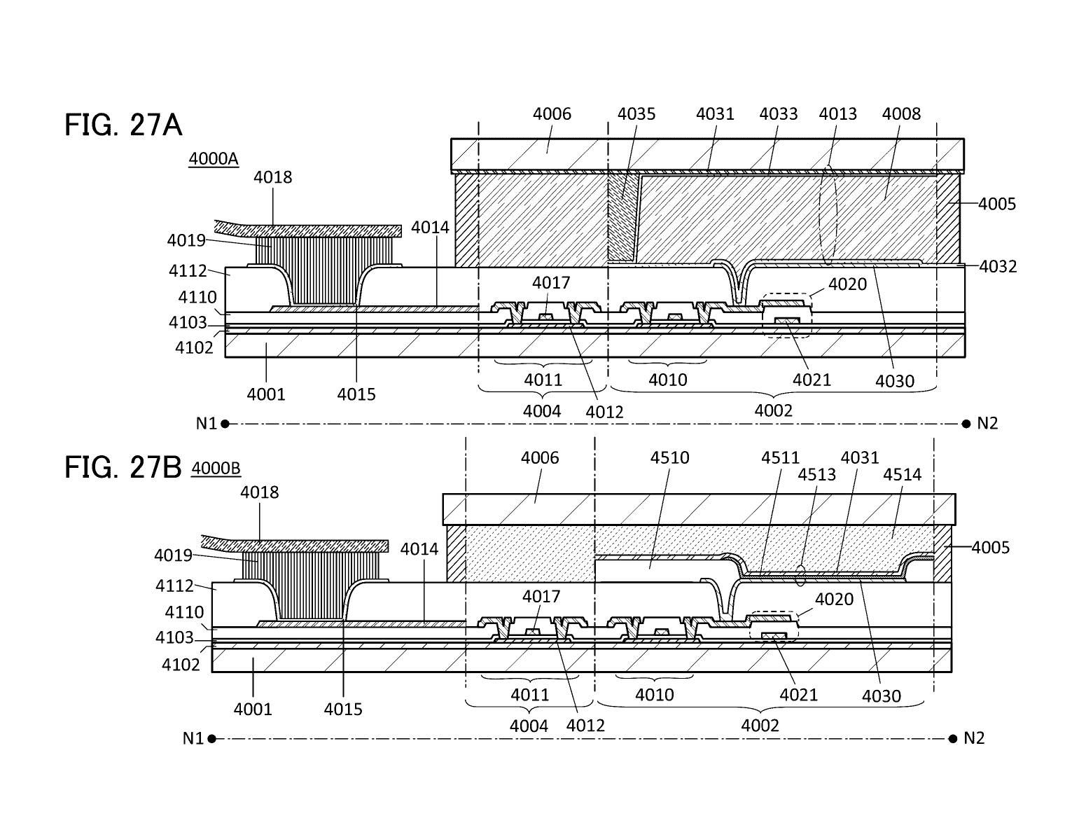

FIG. 27A is a cross-sectional view in the case where top-gate transistors are provided as the transistors 4011 and 4010 in FIG. 26A. Similarly, FIG. 27B illustrates a cross-sectional view in which top-gate transistors are provided as the transistors 4011 and 4010 illustrated in FIG. 26B.

In each of the transistors 4010 and 4011, the electrode 4017 functions as a gate electrode. The wiring 4014 functions as a source electrode or a drain electrode. The insulating layer 4103 functions as a gate insulating film. The transistors 4010 and 4011 each include a semiconductor layer 4012. For the semiconductor layer 4012, crystalline silicon, polycrystalline silicon, amorphous silicon, an oxide semiconductor, an organic semiconductor, or the like may be used. Impurities may be introduced to the semiconductor layer 4012, if necessary, to increase conductivity of the semiconductor layer 4012 or control the threshold value of the transistor.

### <<Electronic Device>>

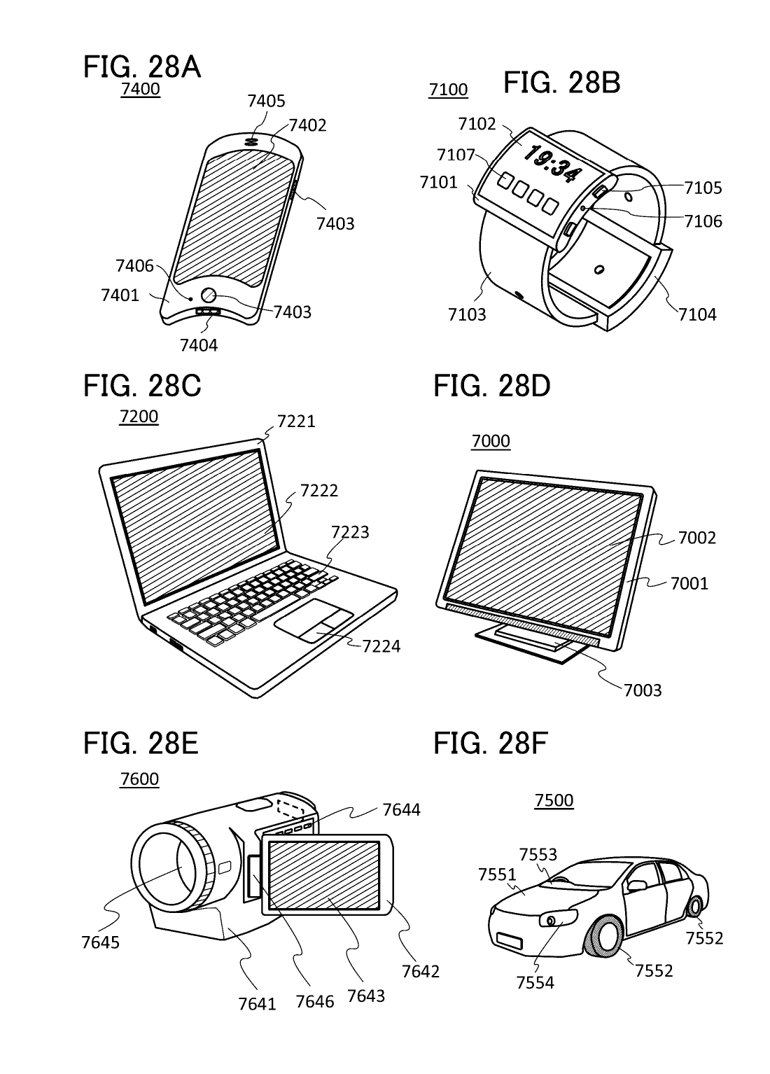

Examples of an electronic device provided with the above-described display portion include a TV device, a monitor of a computer or the like, a digital camera, a digital video camera, a digital photo frame, a mobile phone (also referred to as a cellular phone or a mobile phone device), a portable game machine, a portable information terminal, an audio reproducing device, and a large game machine such as a pachinko machine. When having flexibility, the above-described electronic device can be incorporated along a curved inside/outside wall surface of a house or a building or a curved interior/exterior surface of a car. FIGS. 28A to 28F are structural examples of the electronic device.

A mobile phone 7400 in FIG. 28A includes a display portion 7402 incorporated in a housing 7401, operation buttons 7403, an external connection port 7404, a speaker 7405, a microphone 7406, and the like. When the display portion 7402 of the mobile phone 7400 is touched with a finger or the like, data can be input to the mobile phone 7400. Further, operations such as making a call and inputting a letter can be performed by touch on the display portion 7402 with a finger or the like. With the operation buttons 7403, power ON or OFF can be switched. In addition, types of images displayed on the display portion 7402 can be switched; switching images from a mail creation screen to a main menu screen.

FIG. 28B illustrates an example of a watch-type portable information terminal. A portable information terminal 7100 shown in FIG. 28B includes a housing 7101, a display portion 7102, a band 7103, a buckle 7104, an operation button 7105, an input/output terminal 7106, and the like. The portable information terminal 7100 is capable of executing a variety of applications such as mobile phone calls, e-mailing, reading and editing texts, music reproduction, Internet communication, and a computer game. The display surface of the display portion 7102 is bent, and images can be displayed on the bent display surface. Furthermore, the display portion 7102 includes a touch sensor, and operation can be performed by touching the screen with a finger, a stylus, or the like. For example, by touching an icon 7107 displayed on the display portion 7102, an application can be started.

With the operation button 7105, a variety of functions such as time setting, power ON/OFF, ON/OFF of wireless communication, setting and cancellation of silent mode, and setting and cancellation of power saving mode can be performed. For example, the functions of the operation button 7105 can be set freely by the operating system incorporated in the portable information terminal 7100. The portable information terminal 7100 can employ near field communication that is a communication method based on an existing communication standard. In that case, for example, mutual communication between the portable information terminal 7100 and a headset capable of wireless communication can be performed, and thus hands-free calling is possible. Moreover, the portable information terminal 7100 includes the input/output terminal 7106, and data can be directly transmitted to and received from another information terminal via a connector. Charging through the input/output terminal 7106 is possible. Note that the charging operation may be performed by wireless power feeding without using the input/output terminal 7106.

FIG. 28C illustrates a notebook personal computer (PC). A PC 7200 illustrated in FIG. 28C includes a housing 7221, a display portion 7222, a keyboard 7223, a pointing device 7224, and the like.

FIG. 28D illustrates a stationary display device. A display device 7000 illustrated in FIG. 28D includes a housing 7001, a display portion 7002, a support base 7003, and the like.

FIG. 28E illustrates a video camera 7600, which includes a first housing 7641, a second housing 7642, a display portion 7643, operation keys 7644, a lens 7645, a joint 7646, and the like.

FIG. 28F illustrates a car 7500, which includes a car body 7551, wheels 7552, a dashboard 7553, lights 7554, and the like.

In the case where the display portion of the above-described electronic device includes a large number of pixels represented by 4K or 8K, for example, the electronic device preferably includes the receiver which is one embodiment of the present invention. The electronic device including the receiver which is one embodiment of the present invention can receive and display an image at high speed with low power consumption.

This embodiment can be combined with any of the other embodiments in this specification as appropriate.

### Embodiment 5

Described in this embodiment are transistors of one embodiment of the disclosed invention.

A transistor in one embodiment of the present invention preferably includes an nc-OS or a CAAC-OS, which is described in Embodiment 6.

### Structure Example 1 of Transistor

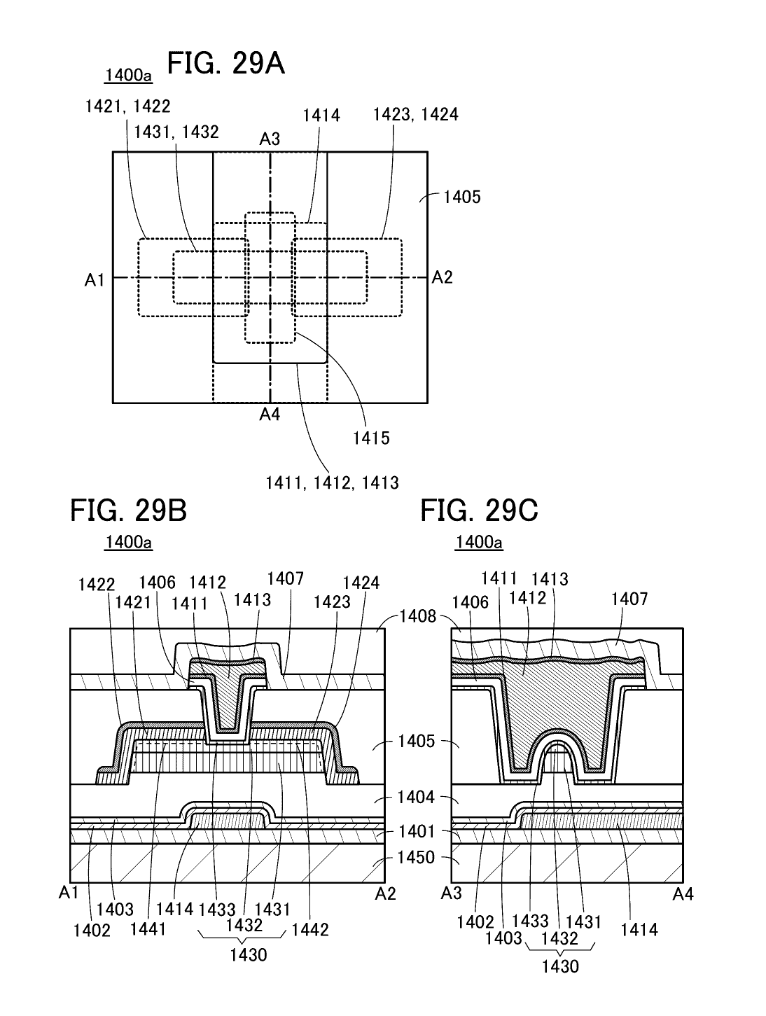

FIGS. 29A to 29C are a top view and cross-sectional views of a transistor 1400a. FIG. 29A is a top view. FIG. 29B is a cross-sectional view taken along dashed-dotted line A1-A2 in FIG. 29A and FIG. 29C is a cross-sectional view taken along dashed-dotted line A3-A4 in FIG. 29A. Note that for simplification of the drawing, some components are not illustrated in the top view in FIG. 29A. Note that the dashed-dotted line A1-A2 and the dashed-dotted line A3-A4 are sometimes referred to as a channel length direction of the transistor 1400a and a channel width direction of the transistor 1400a, respectively.

The transistor 1400a includes a substrate 1450, an insulating film 1401 over the substrate 1450, a conductive film 1414 over the insulating film 1401, an insulating film 1402 covering the conductive film 1414, an insulating film 1403 over the insulating film 1402, an insulating film 1404 over the insulating film 1403, a metal oxide 1431 and a metal oxide 1432 which are stacked in this order over the insulating film 1404, a conductive film 1421 in contact with top and side surfaces of the metal oxide 1432, a conductive film 1423 also in contact with the top and side surfaces of the metal oxide 1432, a conductive film 1422 over the conductive film 1421, a conductive film 1424 over the conductive film 1423, an insulating film 1405 over the conductive films 1422 and 1424, a metal oxide 1433 in contact with the metal oxides 1431 and 1432, the conductive films 1421 to 1424, and the insulating film 1405, an insulating film 1406 over the metal oxide 1433, a conductive film 1411 over the insulating film 1406, a conductive film 1412 over the conductive film 1411, a conductive film 1413 over the conductive film 1412, an insulating film 1407 covering the conductive film 1413, and an insulating film 1408 over the insulating film 1407. Note that the metal oxides 1431 to 1433 are collectively referred to as a metal oxide 1430.

The metal oxide 1432 is a semiconductor and serves as a channel of the transistor 1400a.

Furthermore, the metal oxides 1431 and 1432 include a region 1441 and a region 1442. The region 1441 is formed in the vicinity of a region where the conductive film 1421 is in contact with the metal oxides 1431 and 1432. The region 1442 is formed in the vicinity of a region where the conductive film 1423 is in contact with the metal oxides 1431 and 1432.

The regions 1441 and 1442 serve as low-resistance regions. The region 1441 contributes to a decrease in the contact resistance between the conductive film 1421 and the metal oxides 1431 and 1432. The region 1442 also contributes to a decrease in the contact resistance between the conductive film 1423 and the metal oxides 1431 and 1432.

The conductive films 1421 and 1422 serve as one of source and drain electrodes of the transistor 1400a. The conductive films 1423 and 1424 serve as the other of the source and drain electrodes of the transistor 1400a.

The conductive film 1422 is configured to allow less oxygen to pass therethrough than the conductive film 1421. It is thus possible to prevent a decrease in the conductivity of the conductive film 1421 due to oxidation.

The conductive film 1424 is also configured to allow less oxygen to pass therethrough than the conductive film 1423. It is thus possible to prevent a decrease in the conductivity of the conductive film 1423 due to oxidation.

The conductive films 1411 to 1413 serve as a first gate electrode of the transistor 1400a.

The conductive films 1411 and 1413 are configured to allow less oxygen to pass therethrough than the conductive film 1412. It is thus possible to prevent a decrease in the conductivity of the conductive film 1412 due to oxidation.

The insulating film 1406 serves as a first gate insulating film of the transistor 1400a.

The conductive film 1414 serves as a second gate electrode of the transistor 1400a.

The potential applied to the conductive films 1411 to 1413 may be the same as or different from that applied to the conductive film 1414. The conductive film 1414 may be omitted in some cases.

The insulating films 1401 to 1404 serve as a base insulating film of the transistor 1400a. The insulating films 1402 to 1404 also serve as a second gate insulating film of the transistor 1400a.

The insulating films 1405 to 1408 serve as a protective insulating film or an interlayer insulating film of the transistor 1400a.

As shown in FIG. 29C, the side surface of the metal oxide 1432 is surrounded by the conductive film 1411. With this structure, the metal oxide 1432 can be electrically surrounded by an electric field of the conductive film 1411. A structure in which a semiconductor is electrically surrounded by an electric field of a gate electrode is referred to as a surrounded channel (s-channel) structure. With such a structure, a channel is formed in the entire metal oxide 1432 (bulk). In the s-channel structure, a large amount of current can flow between a source and a drain of a transistor, increasing the on-state current of the transistor.

The s-channel structure, because of its high on-state current, is suitable for a semiconductor device such as large-scale integration (LSI) which requires a miniaturized transistor. A semiconductor device including the miniaturized transistor can have a high integration degree and high density.

In the transistor 1400a, a region serving as a gate electrode is formed so as to fill an opening 1415 formed in the insulating film 1405 or the like, that is, in a self-aligned manner.

As shown in FIG. 29B, the conductive films 1411 and 1422 have a region where they overlap with each other with the insulating film positioned therebetween. The conductive films 1411 and 1423 also have a region where they overlap with each other with the insulating film positioned therebetween. These regions serve as the parasitic capacitance caused between the gate electrode and the source or drain electrode and might decrease the operation speed of the transistor 1400a. This parasitic capacitance can be reduced by providing the insulating film 1405 in the transistor 1400a. The insulating film 1405 preferably contains a material with a low relative dielectric constant.

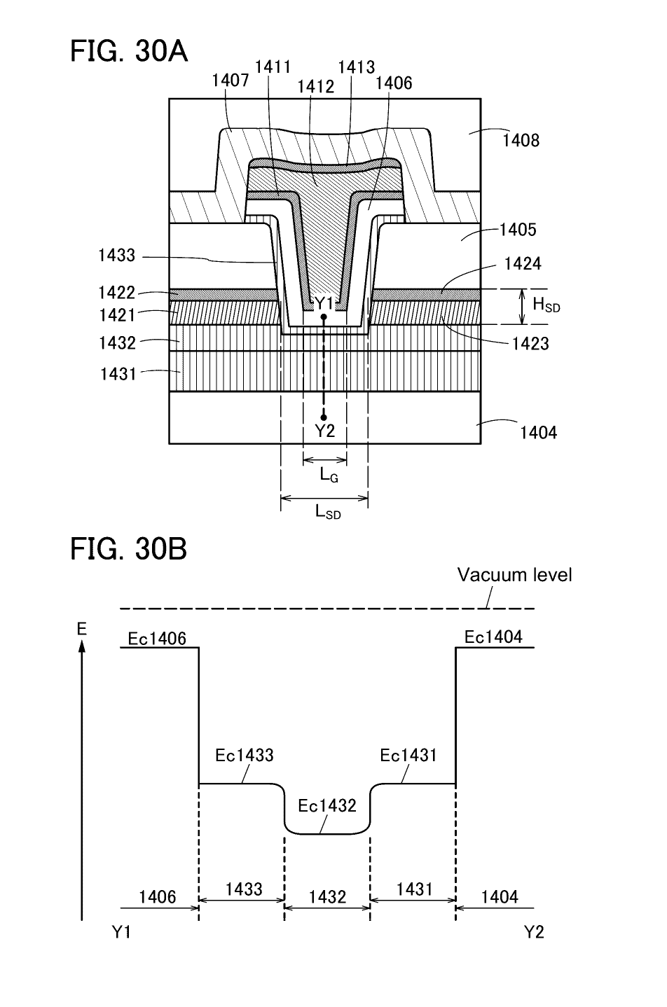

FIG. 30A is an enlarged view of the center of the transistor 1400a. In FIG. 30A, a width L_{G} denotes the length of the bottom surface of the conductive film 1411, which faces parallel to the top surface of the metal oxide 1432 with the insulating film 1406 and the metal oxide 1433 positioned therebetween. The width L_{G} is the line width of the gate electrode. In FIG. 30A, a width L_{SD} indicates the length between the conductive films 1421 and 1423. The width L_{SD} is the length between the source electrode and the drain electrode.

The width L_{SD} is generally determined by the minimum feature size. As shown in FIG. 30A, the width L_{G} is narrower than the width L_{SD}. This means that in the transistor 1400a, the line width of the gate electrode can be made narrower than the minimum feature size; specifically, the width L_{G} can be greater than or equal to 5 nm and less than or equal to 60 nm, preferably greater than or equal to 5 nm and less than or equal to 30 nm.

In FIG. 30A, a height H_{SD} denotes the total thickness of the conductive films 1421 and 1422, or the total thickness of the conductive films 1423 and 1424.

The thickness of the insulating film 1406 is preferably less than or equal to the height H_{SD}, in which case the electric field of the gate electrode can be applied to the entire channel formation region. The thickness of the insulating film 1406 is less than or equal to 30 nm, preferably less than or equal to 10 nm.

The parasitic capacitance between the conductive films 1422 and 1411 and the parasitic capacitance between the conductive films 1424 and 1411 are inversely proportional to the thickness of the insulating film 1405. For example, the thickness of the insulating film 1405 is preferably three times or more, and further preferably five times or more the thickness of the insulating film 1406, in which case the parasitic capacitance is negligibly small. As a result, the transistor 1400a can operate at high frequencies.

Components of the transistor 1400a will be described below.

### <<Metal Oxide Layer>>

First, a metal oxide that can be used as the metal oxides 1431 to 1433 will be described.

The transistor 1400a preferably has a low current (off-state current) flowing between a source and a drain in the non-conduction state. Examples of the transistor with a low off-state current include a transistor including an oxide semiconductor in a channel formation region.

The metal oxide 1432 is an oxide semiconductor containing indium (In), for example. The metal oxide 1432 can have high carrier mobility (electron mobility) by containing indium, for example. The metal oxide 1432 preferably contains an element M. The element M is preferably aluminum (Al), gallium (Ga), yttrium (Y), tin (Sn), or the like. Other elements that can be used as the element M are boron (B), silicon (Si), titanium (Ti), iron (Fe), nickel (Ni), germanium (Ge), zirconium (Zr), molybdenum (Mo), lanthanum (La), cerium (Ce), neodymium (Nd), hafnium (Hf), tantalum (Ta), tungsten (W), magnesium (Mg), and the like. Note that two or more of the above elements may be used in combination as the element M. The element M is an element having a high bonding energy with oxygen, for example. The element M is an element whose bonding energy with oxygen is higher than that of indium, for example. The element M is an element that can increase the energy gap of the metal oxide, for example. Furthermore, the metal oxide 1432 preferably contains zinc (Zn). When containing zinc, the metal oxide is easily crystallized in some cases.

Note that the metal oxide 1432 is not limited to the oxide semiconductor containing indium. The metal oxide 1432 may be an oxide semiconductor that does not contain indium and contains at least one of zinc, gallium, and tin (e.g., a zinc tin oxide or a gallium tin oxide) or the like.

For the metal oxide 1432, an oxide semiconductor with a wide energy gap is used, for example. The energy gap of the metal oxide 1432 is, for example, greater than or equal to 2.5 eV and less than or equal to 4.2 eV, preferably greater than or equal to 2.8 eV and less than or equal to 3.8 eV, more preferably greater than or equal to 3 eV and less than or equal to 3.5 eV.

The metal oxide 1432 is preferably a CAAC-OS film which is described later in Embodiment 6.

The metal oxides 1431 and 1433 include, for example, one or more elements other than oxygen included in the metal oxide 1432. Since the metal oxides 1431 and 1433 include one or more elements other than oxygen included in the metal oxide 1432, an interface state is less likely to be formed at an interface between the metal oxides 1431 and 1432 and an interface between the metal oxides 1432 and 1433.

In the case of using an In-M-Zn oxide as the metal oxide 1431, when the total proportion of In and M is assumed to be 100 atomic %, the proportions of In and M are preferably set to be lower than 50 atomic % and higher than 50 atomic %, respectively, more preferably lower than 25 atomic % and higher than 75 atomic %, respectively. When the metal oxide 1431 is formed by a sputtering method, a sputtering target with an atomic ratio of In:M:Zn=1:3:2, 1:3:4, or the like can be used.

In the case of using an In-M-Zn oxide as the metal oxide 1432, when the total proportion of In and M is assumed to be 100 atomic %, the proportions of In and M are preferably set to be higher than 25 atomic % and lower than 75 atomic %, respectively, more preferably higher than 34 atomic % and lower than 66 atomic %, respectively. When the metal oxide 1432 is formed by a sputtering method, a sputtering target with an atomic ratio of In:M:Zn=1:1:1, 1:1:1.2, 2:1:3, 3:1:2, 4:2:4.1, or the like can be used. In particular, when a sputtering target with an atomic ratio of In to Ga and Zn of 4:2:4.1 is used, the atomic ratio of In to Ga and Zn in the metal oxide 1432 may be 4:2:3 or in the neighborhood of 4:2:3.

In the case of using an In-M-Zn oxide as the metal oxide 1433, when the total proportion of In and M is assumed to be 100 atomic %, the proportions of In and M are preferably set to be lower than 50 atomic % and higher than 50 atomic %, respectively, more preferably lower than 25 atomic % and higher than 75 atomic %, respectively. For example, In:M:Zn is preferably 1:3:2 or 1:3:4. The metal oxide 1433 may be a metal oxide that is the same type as that of the metal oxide 1431.

The metal oxide 1431 or the metal oxide 1433 does not necessarily contain indium in some cases. For example, the metal oxide 1431 or the metal oxide 1433 may be gallium oxide.

The function and effect of the metal oxide 1430, which includes a stack of the metal oxides 1431 to 1433, are described with reference to the energy band diagram of FIG. 30B. FIG. 30B shows an energy band structure of a portion taken along dashed line Y1-Y2 in FIG. 30A, that is, FIG. 30B shows the energy band structure of a channel formation region of the transistor 1400a and the vicinity thereof.

In FIG. 30B, Ec1404, Ec1431, Ec1432, Ec1433, and Ec1406 indicate the energy at the bottom of the conduction band of the insulating film 1404, the metal oxide 1431, the metal oxide 1432, the metal oxide 1433, and the insulating film 1406, respectively.

Here, a difference in energy between the vacuum level and the bottom of the conduction band (the difference is also referred to as “electron affinity”) corresponds to a value obtained by subtracting an energy gap from a difference in energy between the vacuum level and the top of the valence band (the difference is also referred to as an ionization potential). Note that the energy gap can be measured using a spectroscopic ellipsometer. The energy difference between the vacuum level and the top of the valence band can be measured using an ultraviolet photoelectron spectroscopy (UPS) device.

Since the insulating films 1404 and 1406 are insulators, Ec1406 and Ec1404 are closer to the vacuum level (i.e., have a lower electron affinity) than Ec1431, Ec1432, and Ec1433.

The metal oxide 1432 is a metal oxide having higher electron affinity than those of the metal oxides 1431 and 1433. For example, as the metal oxide 1432, a metal oxide having an electron affinity higher than those of the metal oxides 1431 and 1433 by greater than or equal to 0.07 eV and less than or equal to 1.3 eV, preferably greater than or equal to 0.1 eV and less than or equal to 0.7 eV, more preferably greater than or equal to 0.15 eV and less than or equal to 0.4 eV is used. Note that the electron affinity refers to an energy gap between the vacuum level and the bottom of the conduction band.

An indium gallium oxide has a small electron affinity and a high oxygen-blocking property. Therefore, the metal oxide 1433 preferably includes an indium gallium oxide. The gallium atomic ratio [Ga/(In+Ga)] is, for example, higher than or equal to 70%, preferably higher than or equal to 80%, more preferably higher than or equal to 90%.

At this time, when gate voltage is applied, a channel is formed in the metal oxide 1432 having the highest electron affinity among the metal oxides 1431 to 1433.

Therefore, electrons move mainly in the metal oxide 1432, not in the metal oxides 1431 and 1433. Hence, the on-state current of the transistor hardly varies even when the interface state density, which inhibits electron movement, is high at the interface between the metal oxide 1431 and the insulating film 1404 or at the interface between the metal oxide 1433 and the insulating film 1406. The metal oxides 1431 and 1433 have a function as an insulating film.

In some cases, there is a mixed region of the metal oxides 1431 and 1432 between the metal oxides 1431 and 1432. Furthermore, in some cases, there is a mixed region of the metal oxides 1432 and 1433 between the metal oxides 1432 and 1433. Because the mixed region has a low interface state density, a stack of the metal oxides 1431 to 1433 has a band structure where energy at each interface and in the vicinity of the interface is changed continuously (continuous j unction).

As described above, the interface between the metal oxides 1431 and 1432 or the interface between the metal oxides 1432 and 1433 has a low interface state density. Hence, electron movement in the metal oxide 1432 is less likely to be inhibited and the on-state current of the transistor can be increased.

Electron movement in the transistor is inhibited, for example, in the case where physical unevenness in a channel formation region is large. To increase the on-state current of the transistor, for example, root mean square (RMS) roughness with a measurement area of 1 μm×1 μm of a top surface or a bottom surface of the metal oxide 1432 (a formation surface; here, the top surface of the metal oxide 1431) is less than 1 nm, preferably less than 0.6 nm, more preferably less than 0.5 nm, still more preferably less than 0.4 nm. The average surface roughness (also referred to as Ra) with the measurement area of 1 μm×1 μm is less than 1 nm, preferably less than 0.6 nm, more preferably less than 0.5 nm, still more preferably less than 0.4 nm. The maximum difference in height (P-V) with the measurement area of 1 μm×1 μm is less than 10 nm, preferably less than 9 nm, more preferably less than 8 nm, still more preferably less than 7 nm. RMS roughness, Ra, and P-V can be measured using a scanning probe microscope SPA-500 manufactured by SII Nano Technology Inc.

The electron movement is also inhibited, for example, in the case where the density of defect states is high in a region where a channel is formed. For example, in the case where the metal oxide 1432 contains oxygen vacancies (Vo), donor levels are formed by entry of hydrogen into sites of oxygen vacancies in some cases. A state in which hydrogen enters sites of oxygen vacancies is denoted by VoH in the following description in some cases. VoH is a factor of decreasing the on-state current of the transistor because VoH scatters electrons. Note that sites of oxygen vacancies become more stable by entry of oxygen than by entry of hydrogen. Thus, by decreasing oxygen vacancies in the metal oxide 1432, the on-state current of the transistor can be increased in some cases.

For example, at a certain depth in the metal oxide 1432 or in a certain region of the metal oxide 1432, the concentration of hydrogen measured by secondary ion mass spectrometry (SIMS) is set to be higher than or equal to 1×10¹⁶ atoms/cm³ and lower than or equal to 2×10²⁰ atoms/cm³, preferably higher than or equal to 1×10¹⁶ atoms/cm³ and lower than or equal to 5×10¹⁹ atoms/cm³, more preferably higher than or equal to 1×10¹⁶ atoms/cm³ and lower than or equal to 1×10¹⁹ atoms/cm³, still more preferably higher than or equal to 1×10¹⁶ atoms/cm³ and lower than or equal to 5×10¹⁸ atoms/cm³.

To decrease oxygen vacancies in the metal oxide 1432, for example, there is a method in which excess oxygen contained in the insulating film 1404 is moved to the metal oxide 1432 through the metal oxide 1431. In that case, the metal oxide 1431 is preferably a layer having an oxygen-transmitting property (a layer through which oxygen passes or is transmitted).

Note that in the case where the transistor has an s-channel structure, a channel is formed in the entire metal oxide 1432. Therefore, as the metal oxide 1432 has larger thickness, a channel region becomes larger. In other words, the thicker the metal oxide 1432 is, the larger the on-state current of the transistor is.

Moreover, the thickness of the metal oxide 1433 is preferably as small as possible to increase the on-state current of the transistor. For example, the metal oxide 1433 has a region with a thickness of less than 10 nm, preferably less than or equal to 5 nm, more preferably less than or equal to 3 nm. Meanwhile, the metal oxide 1433 has a function of blocking entry of elements other than oxygen (such as hydrogen and silicon) included in the adjacent insulator into the metal oxide 1432 where a channel is formed. Thus, the metal oxide 1433 preferably has a certain thickness. For example, the metal oxide 1433 may have a region with a thickness of greater than or equal to 0.3 nm, preferably greater than or equal to 1 nm, more preferably greater than or equal to 2 nm. The metal oxide 1433 preferably has an oxygen blocking property to inhibit outward diffusion of oxygen released from the insulating film 1404 and the like.

To improve reliability, preferably, the thickness of the metal oxide 1431 is large and the thickness of the metal oxide 1433 is small. For example, the metal oxide 1431 has a region with a thickness of greater than or equal to 10 nm, preferably greater than or equal to 20 nm, more preferably greater than or equal to 40 nm, still more preferably greater than or equal to 60 nm. An increase in the thickness of the metal oxide 1431 can increase the distance from the interface between the adjacent insulator and the metal oxide 1431 to the metal oxide 1432 where a channel is formed. Note that the metal oxide 1431 has a region with a thickness of, for example, less than or equal to 200 nm, preferably less than or equal to 120 nm, more preferably less than or equal to 80 nm, otherwise the productivity of the semiconductor device might be decreased.

For example, a region in which the concentration of silicon is higher than or equal to 1×10¹⁶ atoms/cm³ and lower than 1×10¹⁹ atoms/cm³ is provided between the metal oxides 1432 and 1431. The concentration of silicon is preferably higher than or equal to 1×10¹⁶ atoms/cm³ and lower than 5×10¹⁸ atoms/cm³, more preferably higher than or equal to 1×10¹⁶ atoms/cm³ and lower than 2×10¹⁸ atoms/cm³. A region in which the concentration of silicon is higher than or equal to 1×10¹⁶ atoms/cm³ and lower than 1×10¹⁹ atoms/cm³ is provided between the metal oxides 1432 and 1433. The concentration of silicon is preferably higher than or equal to 1×10¹⁶ atoms/cm³ and lower than 5×10¹⁸ atoms/cm³, more preferably higher than or equal to 1×10¹⁶ atoms/cm³ and lower than 2×10¹⁸ atoms/cm³. The concentration of silicon can be measured by SIMS.

It is preferable to reduce the concentration of hydrogen in the metal oxides 1431 and 1433 in order to reduce the concentration of hydrogen in the metal oxide 1432. The metal oxides 1431 and 1433 each have a region in which the concentration of hydrogen is higher than or equal to 1×10¹⁶ atoms/cm³ and lower than or equal to 2×10²⁰ atoms/cm³. The concentration of hydrogen is preferably higher than or equal to 1×10¹⁶ atoms/cm³ and lower than or equal to 5×10¹⁹ atoms/cm³, more preferably higher than or equal to 1×10¹⁶ atoms/cm³ and lower than or equal to 1×10¹⁹ atoms/cm³, still more preferably higher than or equal to 1×10¹⁶ atoms/cm³ and lower than or equal to 5×10¹⁸ atoms/cm³. The concentration of hydrogen can be measured by SIMS. It is also preferable to reduce the concentration of nitrogen in the metal oxides 1431 and 1433 in order to reduce the concentration of nitrogen in the metal oxide 1432. The metal oxides 1431 and 1433 each have a region in which the concentration of nitrogen is higher than or equal to 1×10¹⁶ atoms/cm³ and lower than 5×10¹⁹ atoms/cm³. The concentration of nitrogen is preferably higher than or equal to 1×10¹⁶ atoms/cm³ and lower than or equal to 5×10¹⁸ atoms/cm³, more preferably higher than or equal to 1×10¹⁶ atoms/cm³ and lower than or equal to 1×10¹⁸ atoms/cm³, still more preferably higher than or equal to 1×10¹⁶ atoms/cm³ and lower than or equal to 5×10¹⁷ atoms/cm³. The concentration of nitrogen can be measured by SIMS.

The metal oxides 1431 to 1433 may be formed by a sputtering method, a chemical vapor deposition (CVD) method, a molecular beam epitaxy (MBE) method, a pulsed laser deposition (PLD) method, an atomic layer deposition (ALD) method, or the like.

After the metal oxides 1431 and 1432 are formed, first heat treatment is preferably performed. The first heat treatment can be performed at a temperature higher than or equal to 250° C. and lower than or equal to 650° C., preferably higher than or equal to 450° C. and lower than or equal to 600° C., further preferably higher than or equal to 520° C. and lower than or equal to 570° C. The first heat treatment is performed in an inert gas atmosphere or an atmosphere containing an oxidizing gas at 10 ppm or more, 1% or more, or 10% or more. The first heat treatment may be performed under a reduced pressure. Alternatively, the first heat treatment may be performed in such a manner that heat treatment is performed in an inert gas atmosphere, and then another heat treatment is performed in an atmosphere containing an oxidizing gas at 10 ppm or more, 1% or more, or 10% or more in order to compensate desorbed oxygen. The crystallinity of the metal oxides 1431 and 1432 can be increased by the first heat treatment. Furthermore, impurities such as hydrogen and water can be removed by the first heat treatment.

The above three-layer structure is an example. For example, a two-layer structure without one of the metal oxides 1431 and 1433 may be employed. Alternatively, any one of semiconductors illustrated as the metal oxides 1431 to 1433 may be additionally provided over or under the metal oxide 1431 or over or under the metal oxide 1433, i.e., a four-layer structure may be employed. Further alternatively, an n-layer structure (n is an integer number of 5 or more) in which any one of semiconductors illustrated as the metal oxides 1431 to 1433 is additionally provided at two or more of the following positions may be employed: over the metal oxide 1431, under the metal oxide 1431, over the metal oxide 1433, and under the metal oxide 1433.

### <<Substrate>>

As the substrate 1450, for example, an insulator substrate, a semiconductor substrate, or a conductor substrate may be used. As the insulator substrate, a glass substrate, a quartz substrate, a sapphire substrate, a stabilized zirconia substrate (e.g., an yttria-stabilized zirconia substrate), or a resin substrate is used, for example. Examples of the semiconductor substrate include a semiconductor substrate of silicon, germanium, or the like, and a compound semiconductor substrate of silicon carbide, silicon germanium, gallium arsenide, indium phosphide, zinc oxide, or gallium oxide. A semiconductor substrate in which an insulator region is provided in the above semiconductor substrate, e.g., a silicon on insulator (SOI) substrate or the like can also be used. As the conductor substrate, a graphite substrate, a metal substrate, an alloy substrate, a conductive resin substrate, or the like is used. A substrate including a metal nitride, a substrate including a metal oxide, or the like can also be used. An insulator substrate provided with a conductor or a semiconductor, a semiconductor substrate provided with a conductor or an insulator, a conductor substrate provided with a semiconductor or an insulator, or the like can also be used. Alternatively, any of these substrates over which an element is provided may be used. Examples of the element provided over the substrate include a capacitor, a resistor, a switching element, a light-emitting element, a memory element, and the like.

A flexible substrate may be used as the substrate 1450. As a method for providing a transistor over a flexible substrate, there is a method in which a transistor is formed over a non-flexible substrate, and then the transistor is separated and transferred to the substrate 1450 which is a flexible substrate. In that case, a separation layer is preferably provided between the non-flexible substrate and the transistor. As the substrate 1450, a sheet, a film, or foil containing a fiber may be used. The substrate 1450 may have elasticity. The substrate 1450 may have a property of returning to its original shape when bending or pulling is stopped. Alternatively, the substrate 1450 may have a property of not returning to its original shape. The thickness of the substrate 1450 is, for example, greater than or equal to 5 μm and less than or equal to 700 μm, preferably greater than or equal to 10 μm and less than or equal to 500 μm, more preferably greater than or equal to 15 μm and less than or equal to 300 μm. When the substrate 1450 has a small thickness, the weight of the semiconductor device can be reduced. When the substrate 1450 has a small thickness, even in the case of using glass or the like, the substrate 1450 may have elasticity or a property of returning to its original shape when bending or pulling is stopped. Therefore, an impact applied to the semiconductor device over the substrate 1450, which is caused by dropping or the like, can be reduced. That is, a durable semiconductor device can be provided.

For the flexible substrate 1450, metal, an alloy, a resin, glass, or fiber thereof can be used, for example. The flexible substrate 1450 preferably has a lower coefficient of linear expansion because deformation due to an environment can be suppressed. The flexible substrate 1450 is preferably formed using, for example, a material whose coefficient of linear expansion is lower than or equal to 1×10⁻³/K, lower than or equal to 5×10⁻⁵/K, or lower than or equal to 1×10⁻⁵/K. Examples of the resin include polyester, polyolefin, polyamide (e.g., nylon or aramid), polyimide, polycarbonate, acrylic, and polytetrafluoroethylene (PTFE). In particular, aramid is preferably used as the material of the flexible substrate 1450 because of its low coefficient of linear expansion.

### <<Base Insulating Film>>

The insulating film 1401 has a function of electrically isolating the substrate 1450 from the conductive film 1414.

The insulating film 1401 or 1402 is formed using an insulating film having a single-layer structure or a layered structure. Examples of the material of an insulating film include aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide.

The insulating film 1402 may be formed using silicon oxide with high step coverage which is formed by reacting tetraethyl orthosilicate (TEOS), silane, or the like with oxygen, nitrous oxide, or the like.

After the insulating film 1402 is formed, the insulating film 1402 may be subjected to planarization treatment using a CMP method or the like to improve the planarity of the top surface thereof.

The insulating film 1404 preferably contains an oxide. In particular, the insulating film 1404 preferably contains an oxide material from which part of oxygen is released by heating. The insulating film 1404 preferably contains an oxide containing oxygen more than that in the stoichiometric composition. Part of oxygen is released by heating from an oxide film containing oxygen in excess of the stoichiometric composition. Oxygen released from the insulating film 1404 is supplied to the metal oxide 1430, so that oxygen vacancies in the metal oxide 1430 can be reduced. Consequently, changes in the electrical characteristics of the transistor can be reduced and the reliability of the transistor can be improved.

The oxide film containing oxygen more than that in the stoichiometric composition is an oxide film of which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis. Note that the temperature of the film surface in the TDS analysis is preferably higher than or equal to 100° C. and lower than or equal to 700° C., or higher than or equal to 100° C. and lower than or equal to 500° C.

The insulating film 1404 preferably contains an oxide that can supply oxygen to the metal oxide 1430. For example, a material containing silicon oxide or silicon oxynitride is preferably used.

Alternatively, a metal oxide such as aluminum oxide, aluminum oxynitride, gallium oxide, gallium oxynitride, yttrium oxide, yttrium oxynitride, hafnium oxide, or hafnium oxynitride may be used for the insulating film 1404.

To make the insulating film 1404 contain excess oxygen, the insulating film 1404 is formed in an oxygen atmosphere, for example. Alternatively, a region containing excess oxygen may be formed by introducing oxygen into the insulating film 1404 that has been formed. Both the methods may be combined.

For example, oxygen (at least including any of oxygen radicals, oxygen atoms, and oxygen ions) may be introduced into the insulating film 1404 that has been formed, so that a region containing excess oxygen is formed. Oxygen can be introduced by an ion implantation method, an ion doping method, a plasma immersion ion implantation method, plasma treatment, or the like.

A gas containing oxygen can be used in an oxygen introducing method. As the gas containing oxygen, oxygen, nitrous oxide, nitrogen dioxide, carbon dioxide, carbon monoxide, and the like can be used. Further, a rare gas may be included in the gas containing oxygen for the oxygen introduction treatment. Hydrogen or the like may be included. For example, a mixed gas of carbon dioxide, hydrogen, and argon may be used.

After the insulating film 1404 is formed, the insulating film 1404 may be subjected to planarization treatment using a CMP method or the like to improve the planarity of the top surface thereof.

The insulating film 1403 has a passivation function of preventing oxygen contained in the insulating film 1404 from decreasing by bonding to metal contained in the conductive film 1414.

The insulating film 1403 has a function of blocking oxygen, hydrogen, water, alkali metal, alkaline earth metal, and the like. Providing the insulating film 1403 can prevent outward diffusion of oxygen from the metal oxide 1430 and entry of hydrogen, water, or the like into the metal oxide 1430 from the outside.

The insulating film 1403 can be, for example, a nitride insulating film. The nitride insulating film is formed using silicon nitride, silicon nitride oxide, aluminum nitride, aluminum nitride oxide, or the like. Note that instead of the nitride insulating film, an oxide insulating film having a blocking effect against oxygen, hydrogen, water, and the like, may be provided. As the oxide insulating film, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

The threshold voltage of the transistor 1400a can be controlled by injecting electrons into a charge trap layer. The charge trap layer is preferably provided in the insulating film 1402 or the insulating film 1403. For example, when the insulating film 1403 is formed using hafnium oxide, aluminum oxide, tantalum oxide, aluminum silicate, or the like, the insulating film 1403 can function as a charge trap layer.

### <<Gate Electrode>>

The conductive films 1411 to 1414 each preferably have a single-layer structure or a layered structure of a conductive film containing a low-resistance material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), cobalt (Co), ruthenium (Ru), platinum (Pt), iridium (Ir), and strontium (Sr), an alloy of such a low-resistance material, or a compound containing such a material as its main component. It is particularly preferable to use a high-melting-point material that has both heat resistance and conductivity, such as tungsten or molybdenum. In addition, the conductive film is preferably formed using a low-resistance conductive material such as aluminum or copper. The conductive film is preferably formed using a Cu—Mn alloy, since in that case, manganese oxide formed at the interface with an insulator containing oxygen has a function of preventing Cu diffusion.

### <<Source Electrode and Drain Electrode>>

The conductive films 1421 to 1424 each preferably have a single-layer structure or a layered structure of a conductive film containing a low-resistance material selected from copper (Cu), tungsten (W), molybdenum (Mo), gold (Au), aluminum (Al), manganese (Mn), titanium (Ti), tantalum (Ta), nickel (Ni), chromium (Cr), lead (Pb), tin (Sn), iron (Fe), cobalt (Co), ruthenium (Ru), platinum (Pt), iridium (Ir), and strontium (Sr), an alloy of such a low-resistance material, or a compound containing such a material as its main component. It is particularly preferable to use a high-melting-point material that has both heat resistance and conductivity, such as tungsten or molybdenum. In addition, the conductive film is preferably formed using a low-resistance conductive material such as aluminum or copper. The conductive film is preferably formed using a Cu—Mn alloy, since in that case, manganese oxide formed at the interface with an insulator containing oxygen has a function of preventing Cu diffusion.

The conductive films 1421 to 1424 are preferably formed using a conductive oxide including noble metal, such as iridium oxide, ruthenium oxide, or strontium ruthenate. Such a conductive oxide hardly takes oxygen from an oxide semiconductor even when it is in contact with the oxide semiconductor and hardly generates oxygen vacancies in the oxide semiconductor.

### <<Low-Resistance Region>>

The regions 1441 and 1442 are formed when, for example, the conductive films 1421 and 1423 take oxygen from the metal oxides 1431 and 1432. Oxygen is more likely to be extracted as the temperature is higher. Oxygen vacancies are formed in the regions 1441 and 1442 through several heating steps in the manufacturing process of the transistor. In addition, hydrogen enters sites of the oxygen vacancies by heating, increasing the carrier concentration in the regions 1441 and 1442. As a result, the resistance of the regions 1441 and 1442 is reduced.

### <<Gate Insulating Film>>

The insulating film 1406 preferably contains an insulator with a high relative dielectric constant. For example, the insulating film 1406 preferably contains gallium oxide, hafnium oxide, an oxide containing aluminum and hafnium, oxynitride containing aluminum and hafnium, an oxide containing silicon and hafnium, or oxynitride containing silicon and hafnium.

The insulating film 1406 preferably has a layered structure containing silicon oxide or silicon oxynitride and an insulator with a high relative dielectric constant. Because silicon oxide and silicon oxynitride have thermal stability, combination of silicon oxide or silicon oxynitride with an insulator with a high relative dielectric constant allows the layered structure to be thermally stable and have a high relative dielectric constant. For example, when aluminum oxide, gallium oxide, or hafnium oxide is closer to the metal oxide 1433, entry of silicon from silicon oxide or silicon oxynitride into the metal oxide 1432 can be suppressed.

When silicon oxide or silicon oxynitride is closer to the metal oxide 1433, for example, trap centers might be formed at the interface between aluminum oxide, gallium oxide, or hafnium oxide and silicon oxide or silicon oxynitride. The trap centers can shift the threshold voltage of the transistor in the positive direction by trapping electrons in some cases.

### <<Interlayer Insulating Film and Protective Insulating Film>>

The insulating film 1405 preferably contains an insulator with a low relative dielectric constant. For example, the insulating film 1405 preferably contains silicon oxide, silicon oxynitride, silicon nitride oxide, silicon nitride, or a resin. Alternatively, the insulating film 1405 preferably has a layered structure containing silicon oxide or silicon oxynitride and a resin. Because silicon oxide and silicon oxynitride have thermal stability, combination of silicon oxide or silicon oxynitride with a resin allows the layered structure to be thermally stable and have a low relative dielectric constant. Examples of the resin include polyester, polyolefin, polyamide (e.g., nylon or aramid), polyimide, polycarbonate, and acrylic.

The insulating film 1407 has a function of blocking oxygen, hydrogen, water, alkali metal, alkaline earth metal, and the like. Providing the insulating film 1407 can prevent outward diffusion of oxygen from the metal oxide 1430 and entry of hydrogen, water, or the like into the metal oxide 1430 from the outside.

The insulating film 1407 can be, for example, a nitride insulating film. The nitride insulating film is formed using silicon nitride, silicon nitride oxide, aluminum nitride, aluminum nitride oxide, or the like. Note that instead of the nitride insulating film, an oxide insulating film having a blocking effect against oxygen, hydrogen, water, and the like, may be provided. As the oxide insulating film, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given.

An aluminum oxide film is preferably used as the insulating film 1407 because it is highly effective in preventing transmission of both oxygen and impurities such as hydrogen and moisture.

When the insulating film 1407 is formed by a method using plasma containing oxygen, e.g., by a sputtering method or a CVD method, oxygen can be added to side and top surfaces of the insulating films 1405 and 1406. It is preferable to perform second heat treatment at any time after the formation of the insulating film 1407. Through the second heat treatment, oxygen added to the insulating films 1405 and 1406 is diffused in the insulating films to reach the metal oxide 1430, whereby oxygen vacancies in the metal oxide 1430 can be reduced.

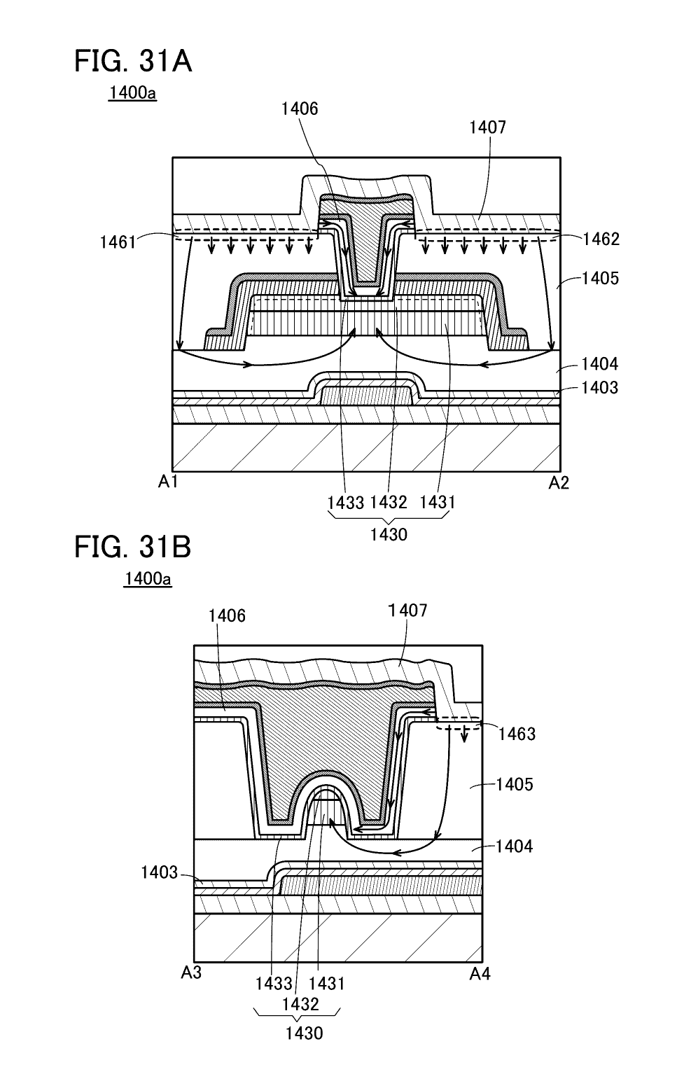

In schematic views of FIGS. 31A and 31B, oxygen added to the insulating films 1405 and 1406 in the formation of the insulating film 1407 is diffused in the insulating films through the second heat treatment and reaches the metal oxide 1430. In FIG. 31A, oxygen diffusion in the cross-sectional view of FIG. 29B is indicated by arrows. In FIG. 31B, oxygen diffusion in the cross-sectional view of FIG. 29C is indicated by arrows.

As shown in FIGS. 31A and 31B, oxygen added to the side surface of the insulating film 1406 is diffused in the insulating film 1406 and reaches the metal oxide 1430. In addition, a region 1461, a region 1462, and a region 1463 each containing excess oxygen are sometimes formed in the vicinity of the interface between the insulating films 1407 and 1405. Oxygen contained in the regions 1461 to 1463 reaches the metal oxide 1430 through the insulating films 1405 and 1404. In the case where the insulating film 1405 includes silicon oxide and the insulating film 1407 includes aluminum oxide, a mixed layer of silicon, aluminum, and oxygen is formed in the regions 1461 to 1463 in some cases.

The insulating film 1407 has a function of blocking oxygen and prevents oxygen from being diffused over the insulating film 1407. The insulating film 1403 also has a function of blocking oxygen and prevents oxygen from being diffused under the insulating film 1403.

Note that the second heat treatment may be performed at a temperature that allows oxygen added to the insulating films 1405 and 1406 to be diffused to the metal oxide 1430. For example, the description of the first heat treatment may be referred to for the second heat treatment. Alternatively, the temperature of the second heat treatment is preferably lower than that of the first heat treatment. The second heat treatment is performed at a temperature lower than that of the first heat treatment by higher than or equal to 20° C. and lower than or equal to 150° C., preferably higher than or equal to 40° C. and lower than or equal to 100° C. Accordingly, superfluous release of oxygen from the insulating film 1404 can be inhibited. Note that in the case where heating at the time of formation of the layers doubles as the second heat treatment, the second heat treatment is not necessarily performed.

As described above, oxygen can be supplied to the metal oxide 1430 from above and below through the formation of the insulating film 1407 and the second heat treatment.

Alternatively, oxygen can be added to the insulating films 1405 and 1406 by forming a film containing indium oxide, e.g., an In-M-Zn oxide, as the insulating film 1407.

The insulating film 1408 can be formed using an insulator including one or more kinds of materials selected from aluminum oxide, aluminum nitride oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide. Alternatively, for the insulating film 1408, a resin such as a polyimide resin, a polyamide resin, an acrylic resin, a siloxane resin, an epoxy resin, or a phenol resin can be used. The insulating film 1408 may be a stack including any of the above materials.

### Structure Example 2 of Transistor

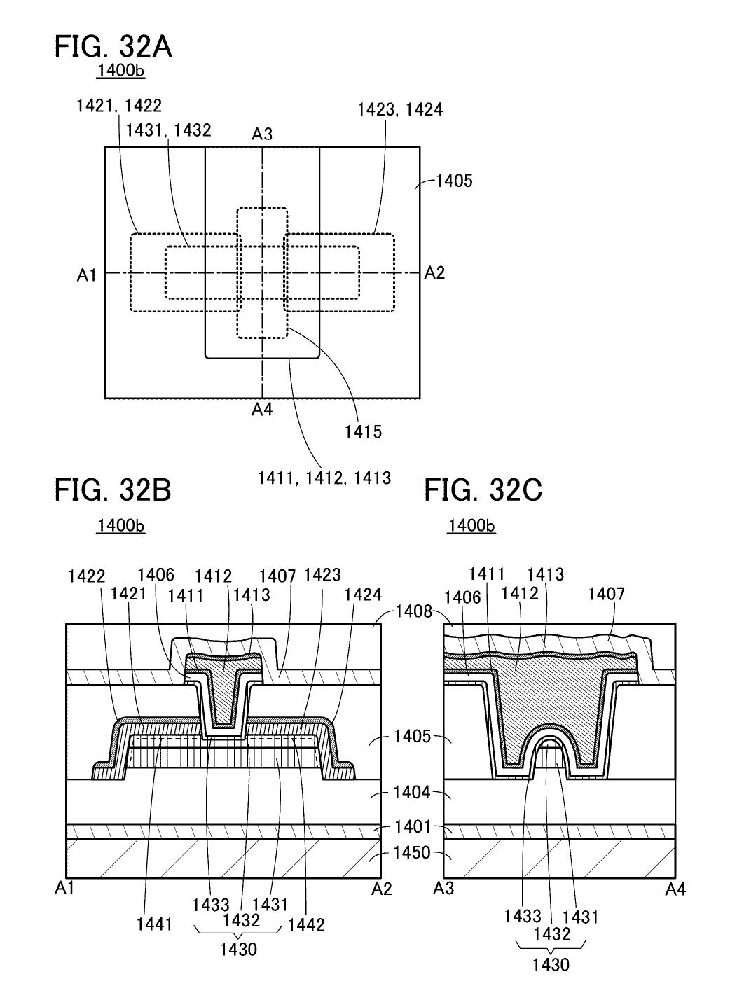

The conductive film 1414 and the insulating films 1402 and 1403 can be omitted from the transistor 1400a shown in FIGS. 29A to 29C. An example of such a structure is shown in FIGS. 32A to 32C.

FIGS. 32A to 32C are a top view and cross-sectional views of a transistor 1400b. FIG. 32A is a top view. FIG. 32B is a cross-sectional view taken along dashed-dotted line A1-A2 in FIG. 32A and FIG. 32C is a cross-sectional view taken along dashed-dotted line A3-A4 in FIG. 32A. Note that for simplification of the drawing, some components are not illustrated in the top view of FIG. 32A. Note that the dashed-dotted line A1-A2 and the dashed-dotted line A3-A4 are sometimes referred to as a channel length direction of the transistor 1400b and a channel width direction of the transistor 1400b, respectively.

### Structure Example 3 of Transistor

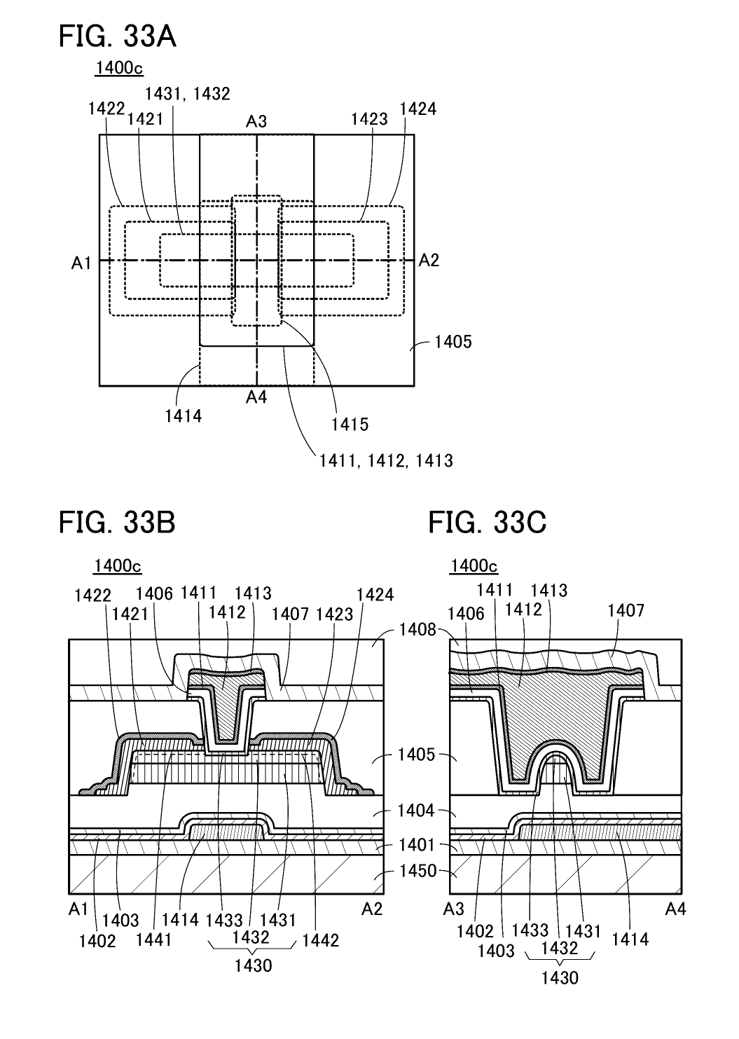

In the transistor 1400a shown in FIGS. 29A to 29C, parts of the conductive films 1421 and 1423 that overlap with the gate electrode (the conductive films 1411 to 1413) can be reduced in thickness. An example of such a structure is shown in FIGS. 33A to 33C.

FIGS. 33A to 33C are a top view and cross-sectional views of a transistor 1400c. FIG. 33A is a top view. FIG. 33B is a cross-sectional view taken along dashed-dotted line A1-A2 in FIG. 33A and FIG. 33C is a cross-sectional view taken along dashed-dotted line A3-A4 in FIG. 33A. Note that for simplification of the drawing, some components in the top view in FIG. 33A are not illustrated. Note that the dashed-dotted line A1-A2 and the dashed-dotted line A3-A4 are sometimes referred to as a channel length direction of the transistor 1400c and a channel width direction of the transistor 1400c, respectively.

In the transistor 1400c shown in FIG. 33B, part of the conductive film 1421 that overlaps with the gate electrode is reduced in thickness, and the conductive film 1422 covers the conductive film 1421. Part of the conductive film 1423 that overlaps with the gate electrode is also reduced in thickness, and the conductive film 1424 covers the conductive film 1423.

The transistor 1400c, which has the structure shown in FIG. 33B, can have an increased distance between the gate and source electrodes or between the gate and drain electrodes. This results in a reduction in the parasitic capacitance formed between the gate electrode and the source and drain electrodes. As a result, the transistor can operate at high-speed.

### Structure Example 4 of Transistor

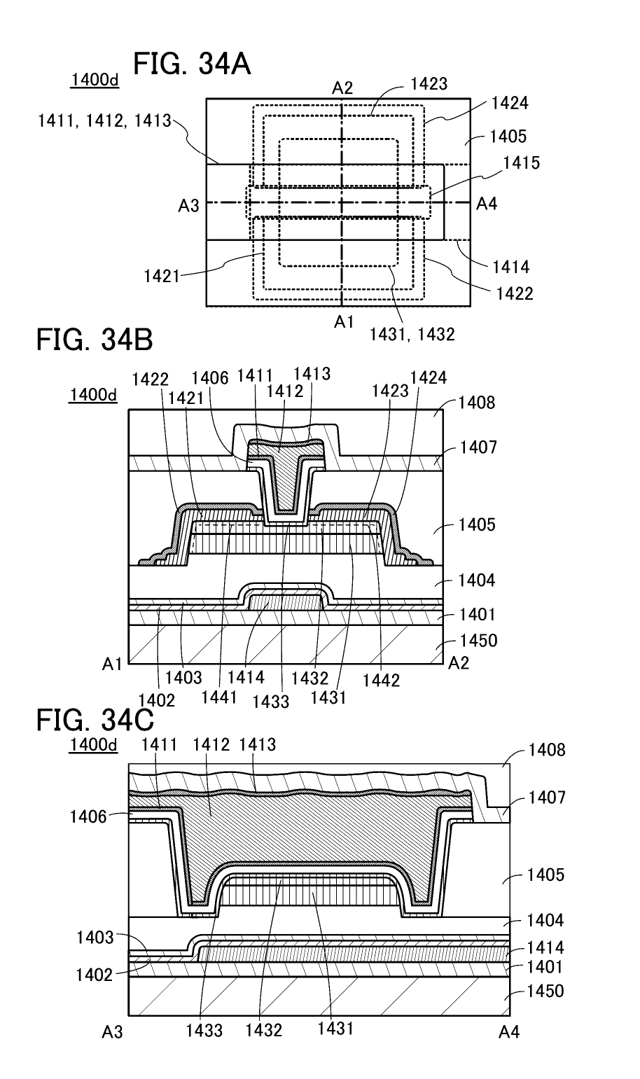

In the transistor 1400c shown in FIGS. 33A to 33C, the width of the metal oxides 1431 and 1432 can be increased in the A3-A4 direction. An example of such a structure is shown in FIGS. 34A to 34C.

FIGS. 34A to 34C are a top view and cross-sectional views of a transistor 1400d. FIG. 34A is a top view. FIG. 34B is a cross-sectional view taken along dashed-dotted line A1-A2 in FIG. 34A and FIG. 34C is a cross-sectional view taken along dashed-dotted line A3-A4 in FIG. 34A. Note that for simplification of the drawing, some components are not illustrated in the top view in FIG. 34A. Note that the dashed-dotted line A1-A2 and the dashed-dotted line A3-A4 are sometimes referred to as a channel length direction of the transistor 1400d and a channel width direction of the transistor 1400d, respectively.

The transistor 1400d, which has the structure shown in FIGS. 34A to 34C, can have an increased on-state current.

### Structure Example 5 of Transistor

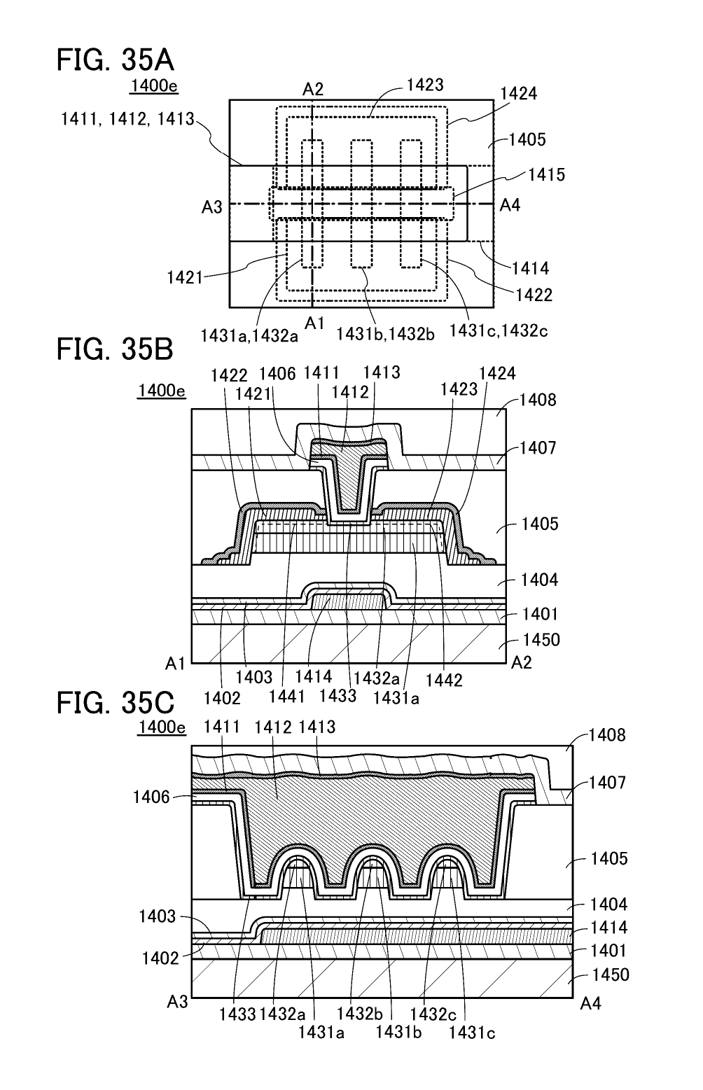

In the transistor 1400c shown in FIGS. 33A to 33C, a plurality of regions (hereinafter referred to as fins) including the metal oxides 1431 and 1432 may be provided in the A3-A4 direction. An example of this case is shown in FIGS. 35A to 35C.

FIGS. 35A to 35C are a top view and cross-sectional views of a transistor 1400e. FIG. 35A is a top view. FIG. 35B is a cross-sectional view taken along dashed-dotted line A1-A2 in FIG. 35A and FIG. 35C is a cross-sectional view taken along dashed-dotted line A3-A4 in FIG. 35A. Note that for simplification of the drawing, some components are not illustrated in the top view in FIG. 35A. Note that the dashed-dotted line A1-A2 and the dashed-dotted line A3-A4 are sometimes referred to as a channel length direction of the transistor 1400e and a channel width direction of the transistor 1400e, respectively.

The transistor 1400e includes a first fin consisting of metal oxides 1431a and 1432a, a second fin consisting of metal oxides 1431b and 1432b, and a third fin consisting of metal oxides 1431c and 1432c.

In the transistor 1400e, the metal oxides 1432a to 1432c where a channel is formed are surrounded by the gate electrode. Hence, a gate electric field can be applied to the entire channel, so that the transistor can have a high on-state current.

### Structure Example 6 of Transistor

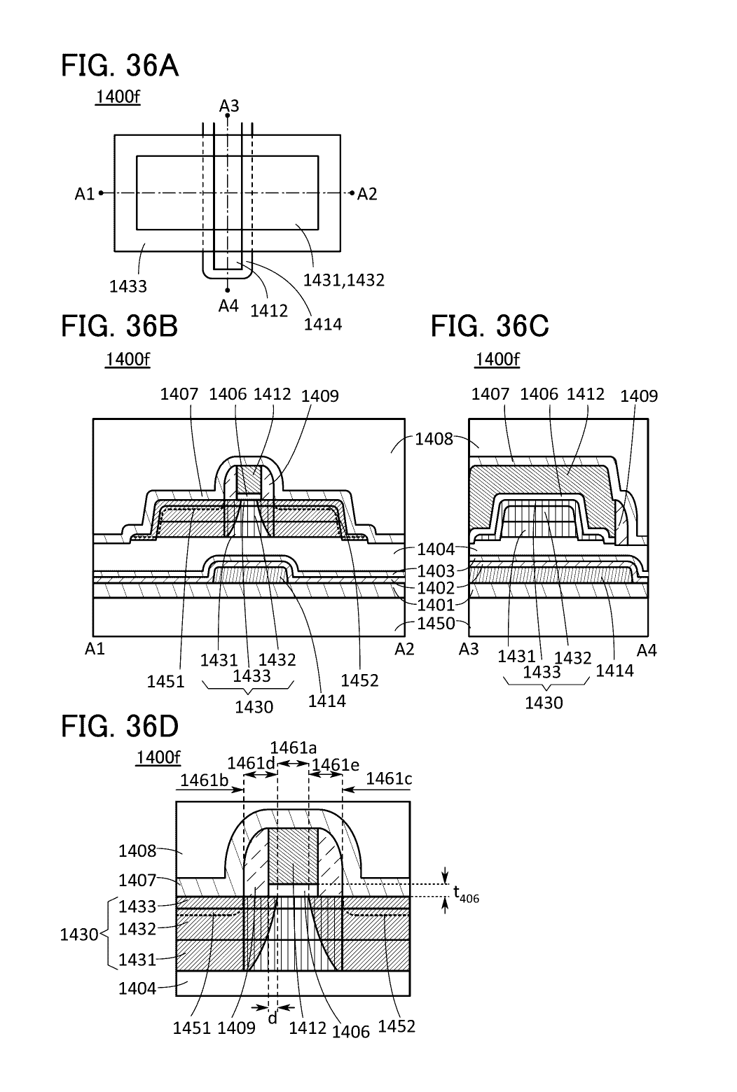

FIGS. 36A to 36D are a top view and cross-sectional views of a transistor 1400f FIG. 36A is a top view of the transistor 1400f. FIG. 36B is a cross-sectional view taken along dashed-dotted line A1-A2 in FIG. 36A and FIG. 36C is a cross-sectional view taken along dashed-dotted line A3-A4 in FIG. 36A. Note that the dashed-dotted line A1-A2 and the dashed-dotted line A3-A4 are sometimes referred to as a channel length direction and a channel width direction, respectively. The transistor 1400f has the s-channel structure like the transistor 1400a and the like. In the transistor 1400f, an insulating film 1409 is provided in contact with the side surface of the conductive film 1412 used as a gate electrode. The insulating film 1409 and the conductive film 1412 are covered with the insulating film 1407 and the insulating film 1408. The insulating film 1409 serves as a sidewall insulating film of the transistor 1400f As in the transistor 1400a, the gate electrode may be a stack of the conductive films 1411 to 1413.

The insulating film 1406 and the conductive film 1412 overlap with the conductive film 1414 and the metal oxide 1432 at least partly. The side edge of the conductive film 1412 in the channel length direction is preferably approximately aligned with the side edge of the insulating film 1406 in the channel length direction. Here, the insulating film 1406 serves as a gate insulating film of the transistor 1400f, and the conductive film 1412 serves as a gate electrode of the transistor 1400f.

The metal oxide 1432 has a region that overlaps with the conductive film 1412 with the metal oxide 1433 and the insulating film 1406 positioned therebetween. Preferably, the outer edge of the metal oxide 1431 is approximately aligned with the outer edge of the metal oxide 1432, and the outer edge of the metal oxide 1433 is outside of the outer edges of the metal oxides 1431 and 1432. However, the shape of the transistor in this embodiment is not limited to the shape where the outer edge of the metal oxide 1433 is outside of the outer edge of the metal oxide 1431. For example, the outer edge of the metal oxide 1431 may be outside of the outer edge of the metal oxide 1433, or the side edge of the metal oxide 1431 may be approximately aligned with the side edge of the metal oxide 1433.

FIG. 36D is an enlarged view of part of FIG. 36B. As shown in FIG. 36D, regions 1461a to 1461e are formed in the metal oxide 1430. The regions 1461b to 1461e have a higher concentration of dopant and therefore have a lower resistance than the region 1461a. Furthermore, the regions 1461b and 1461c have a higher concentration of hydrogen and therefore have an even lower resistance than the regions 1461d and 1461e. The concentration of a dopant in the region 1461a is, for example, less than or equal to 5%, less than or equal to 2%, or less than or equal to 1% of the maximum concentration of a dopant in the region 1461b or 1461c. Note that the dopant may be rephrased as a donor, an acceptor, an impurity, or an element.

As shown in FIG. 36D, in the metal oxide 1430, the region 1461a substantially overlaps with the conductive film 1412, and the regions 1461b to 1461e are the regions other than the region 1461a. In the regions 1461b and 1461c, the top surface of the metal oxide 1433 is in contact with the insulating film 1407. In the regions 1461d and 1461e, the top surface of the metal oxide 1433 is in contact with the insulating film 1409 or 1406. That is, as shown in FIG. 36D, the boundary between the regions 1461b and 1461d overlaps with the boundary between the side edges of the insulating films 1407 and 1409. The same applies to the boundary between the regions 1461c and 1461e. Here, part of the regions 1461d and 1461e preferably overlaps with part of a region (a channel formation region) of the metal oxide 1432 that overlaps with the conductive film 1412. For example, preferably, the side edges of the regions 1461d and 1461e in the channel length direction are inside of the conductive film 1412 and the distance between the side edge of the conductive film 1412 and each of the side edges of the regions 1461d and 1461e is d. In that case, the thickness t₄₀₆ of the insulating film 1406 and the distance d preferably satisfy 0.25 t₄₀₆<d<t₄₀₆.

In the above manner, the regions 1461d and 1461e are formed in part of the region where the metal oxide 1430 and the conductive film 1412 overlap with each other. Accordingly, the channel formation region of the transistor 1400f is in contact with the low-resistance regions 1461d and 1461e and a high-resistance offset region is not formed between the region 1461a and each of the regions 1461d and 1461e, so that the on-state current of the transistor 1400f can be increased. Furthermore, since the side edges of the regions 1461d and 1461e in the channel length direction are formed so as to satisfy the above range, the regions 1461d and 1461e can be prevented from being formed too deeply in the channel formation region and always conducted.

The regions 1461b to 1461e are formed by ion doping treatment such as an ion implantation method. Therefore, as illustrated in FIG. 36D, in some cases, the boundary between the regions 1461d and 1461a around the lower surface of the metal oxide 1431 is formed closer to the A1 side of the dashed-dotted line A1-A2 than the boundary between the regions 1461d and 1461a around the upper surface of the metal oxide 1433 is; in other words, the boundary is formed closer to the A1 side in the deeper region. The distance d in that case is the distance between the boundary between the regions 1461d and 1461a which is closest to the inner part of the conductive film 1412 in the direction of the dashed-dotted line A1-A2 and the side edge of the conductive film 1412 at A1 side in the direction of the dashed-dotted line A1-A2. Similarly, the boundary between the regions 1461e and 1461a around the lower surface of the metal oxide 1431 is formed closer to the A2 side of the dashed-dotted line A1-A2 than the boundary between the regions 1461e and 1461a around the upper surface of the metal oxide 1433 is; in other words, the boundary is formed closer to the A2 side in the deeper region. The distance d in that case is the distance between the boundary between the regions 1461e and 1461a which is closest to the inner part of the conductive film 1412 in the direction of the dashed-dotted line A1-A2 and the side edge of the conductive film 1412 at A2 side in the direction of the dashed-dotted line A1-A2.

In some cases, for example, the regions 1461d and 1461e in the metal oxide 1431 do not overlap with the conductive film 1412. In that case, at least part of the regions 1461d and 1461e in the metal oxide 1431 or 1432 is preferably formed in a region overlapping with the conductive film 1412.

In addition, low-resistance regions 1451 and 1452 are preferably formed in the metal oxide 1431, the metal oxide 1432, and the metal oxide 1433 in the vicinity of the interface with the insulating film 1407. The low-resistance regions 1451 and 1452 contain at least one of elements included in the insulating film 1407. Preferably, part of the low-resistance regions 1451 and 1452 is substantially in contact with or overlaps partly with the region (the channel formation region) of the metal oxide 1432 that overlaps with the conductive film 1412.

Since a large part of the metal oxide 1433 is in contact with the insulating film 1407, the low-resistance regions 1451 and 1452 are likely to be formed in the metal oxide 1433. The low-resistance regions 1451 and 1452 in the metal oxide 1433 contain a higher concentration of elements included in the insulating film 1407 than the other regions of the metal oxide 1433 (e.g., the region of the metal oxide 1433 that overlaps with the conductive film 1412).

The low-resistance regions 1451 and 1452 are formed in the regions 1461b and 1461c, respectively. Ideally, the metal oxide 1430 has a structure in which the concentration of added elements is the highest in the low-resistance regions 1451 and 1452, the second highest in the regions 1461b to 1461e other than the low-resistance regions 1451 and 1452, and the lowest in the region 1461a. The added elements refer to a dopant for forming the regions 1461b and 1461c and an element added from the insulating film 1407 to the low-resistance regions 1451 and 1452.

Although the low-resistance regions 1451 and 1452 are formed in the transistor 1400f, the semiconductor device shown in this embodiment is not limited to this structure. For example, the low-resistance regions 1451 and 1452 are not necessarily formed in the case where the regions 1461b and 1461c have a sufficiently low resistance.

### Structure Example 7 of Transistor

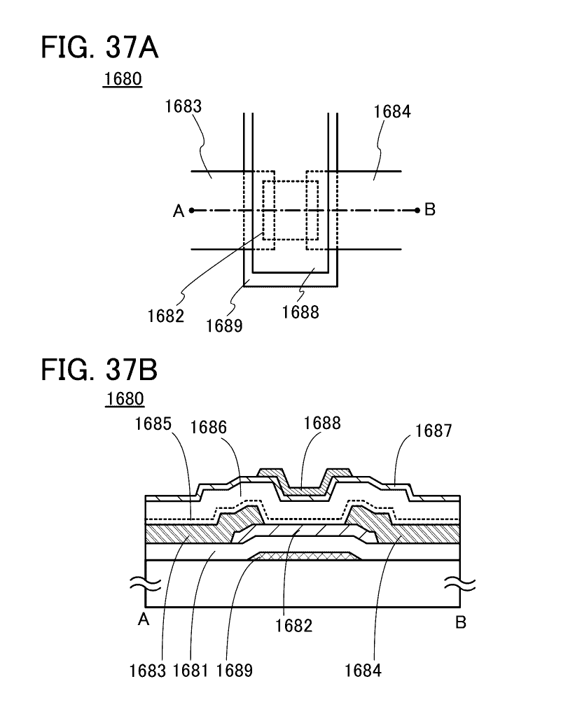

FIGS. 37A and 37B are a top view and a cross-sectional view of a transistor 1680. FIG. 37A is a top view, and FIG. 37B is a cross-sectional view taken along dashed-dotted line A-B in FIG. 37A. Note that for simplification of the drawing, some components are increased or reduced in size, or omitted in FIGS. 37A and 37B. The dashed-dotted line A-B direction may be referred to as a channel length direction.

The transistor 1680 shown in FIG. 37B includes a conductive film 1689 serving as a first gate, a conductive film 1688 serving as a second gate, a semiconductor 1682, a conductive film 1683 and a conductive film 1684 serving as a source and a drain, an insulating film 1681, an insulating film 1685, an insulating film 1686, and an insulating film 1687.

The conductive film 1689 is on an insulating surface. The conductive film 1689 overlaps with the semiconductor 1682 with the insulating film 1681 provided therebetween. The conductive film 1688 overlaps with the semiconductor 1682 with the insulating films 1685, 1686, and 1687 provided therebetween. The conductive films 1683 and 1684 are connected to the semiconductor 1682.

The description of the conductive films 1411 to 1414 in FIGS. 29A to 29C can be referred to for the details of the conductive films 1689 and 1688.

The conductive films 1689 and 1688 may be supplied with different potentials, or may be supplied with the same potential at the same time. Owing to the conductive film 1688 serving as the second gate electrode in the transistor 1680, threshold voltage can be stable. Note that the conductive film 1688 is not necessarily provided.

The description of the metal oxide 1432 in FIGS. 29A to 29C can be referred to for the details of the semiconductor 1682. The semiconductor 1682 may be a single layer or a stack including a plurality of semiconductor layers.

The description of the conductive films 1421 to 1424 in FIGS. 29A to 29C can be referred to for the details of the conductive films 1683 and 1684.

The description of the insulating film 1406 in FIGS. 29A to 29C can be referred to for the details of the insulating film 1681.

The insulating films 1685 to 1687 are sequentially stacked over the semiconductor 1682 and the conductive films 1683 and 1684 in FIG. 37B; however, an insulating film provided over the semiconductor 1682 and the conductive films 1683 and 1684 may be a single layer or a stack including a plurality of insulating films.

In the case of using an oxide semiconductor as the semiconductor 1682, the insulating film 1686 preferably contains oxygen at a proportion higher than or equal to that in the stoichiometric composition and has a function of supplying part of oxygen to the semiconductor 1682 by heating. Note that in the case where the semiconductor 1682 is damaged at the time of formation of the insulating film 1686 when the insulating film 1686 is directly formed on the semiconductor 1682, the insulating film 1685 is preferably provided between the semiconductor 1682 and the insulating film 1686, as shown in FIG. 37B. The insulating film 1685 preferably allows oxygen to pass therethrough, and causes little damage to the semiconductor 1682 when the insulating film 1685 is formed compared with the case of the insulating film 1686. If the insulating film 1686 can be formed directly on the semiconductor 1682 while damage to the semiconductor 1682 is reduced, the insulating film 1685 is not necessarily provided.

For the insulating films 1685 and 1686, a material containing silicon oxide or silicon oxynitride is preferably used, for example. Alternatively, a metal oxide such as aluminum oxide, aluminum oxynitride, gallium oxide, gallium oxynitride, yttrium oxide, yttrium oxynitride, hafnium oxide, or hafnium oxynitride can be used.

The insulating film 1687 preferably has an effect of blocking diffusion of oxygen, hydrogen, and water. Alternatively, the insulating film 1687 preferably has an effect of blocking diffusion of hydrogen and water.

As an insulating film has higher density and becomes denser or has a fewer dangling bonds and becomes more chemically stable, the insulating film has a higher blocking effect. An insulating film that has an effect of blocking diffusion of oxygen, hydrogen, and water can be formed using, for example, aluminum oxide, aluminum oxynitride, gallium oxide, gallium oxynitride, yttrium oxide, yttrium oxynitride, hafnium oxide, or hafnium oxynitride. An insulating film that has an effect of blocking diffusion of hydrogen and water can be formed using, for example, silicon nitride or silicon nitride oxide.

In the case where the insulating film 1687 has an effect of blocking diffusion of water, hydrogen, and the like, impurities such as water and hydrogen that exist in a resin in a panel or exist outside the panel can be prevented from entering the semiconductor 1682. In the case where an oxide semiconductor is used as the semiconductor 1682, part of water or hydrogen that enters the oxide semiconductor serves as an electron donor (donor). Thus, the use of the insulating film 1687 having the blocking effect can prevent a shift in the threshold voltage of the transistor 1680 due to generation of donors.

In addition, in the case where an oxide semiconductor is used as the semiconductor 1682, the insulating film 1687 has an effect of blocking diffusion of oxygen, so that diffusion of oxygen from the oxide semiconductor to the outside can be prevented. Accordingly, oxygen vacancies in the oxide semiconductor that serve as donors are reduced, so that a shift in the threshold voltage of the transistor 1680 due to generation of donors can be prevented.

This embodiment can be combined with any of the other embodiments in this specification as appropriate.

### Embodiment 6

Described in this embodiment is a structure of an oxide semiconductor film capable of being used for the OS transistors described in the above embodiments.

### <Structure of Oxide Semiconductor>

An oxide semiconductor is classified into a single crystal oxide semiconductor and a non-single-crystal oxide semiconductor. Examples of a non-single-crystal oxide semiconductor include a c-axis-aligned and a-b-plane anchored crystalline oxide semiconductor (CAAC-OS), a polycrystalline oxide semiconductor, a nanocrystalline oxide semiconductor (nc-OS), an amorphous-like oxide semiconductor (a-like OS), and an amorphous oxide semiconductor.

From another perspective, an oxide semiconductor is classified into an amorphous oxide semiconductor and a crystalline oxide semiconductor. Examples of a crystalline oxide semiconductor include a single crystal oxide semiconductor, a CAAC-OS, a polycrystalline oxide semiconductor, and an nc-OS.

An amorphous structure is generally thought to be isotropic and have no non-uniform structure, to be metastable and not have fixed positions of atoms, to have a flexible bond angle, and to have a short-range order but have no long-range order, for example.

In other words, a stable oxide semiconductor cannot be regarded as a completely amorphous oxide semiconductor. Moreover, an oxide semiconductor that is not isotropic (e.g., an oxide semiconductor that has a periodic structure in a microscopic region) cannot be regarded as a completely amorphous oxide semiconductor. In contrast, an a-like OS, which is not isotropic, has an unstable structure that contains a void. Because of its instability, an a-like OS is close to an amorphous oxide semiconductor in terms of physical properties.

### <CAAC-OS>

First, a CAAC-OS is described.

A CAAC-OS is one of oxide semiconductors having a plurality of c-axis aligned crystal parts (also referred to as pellets).

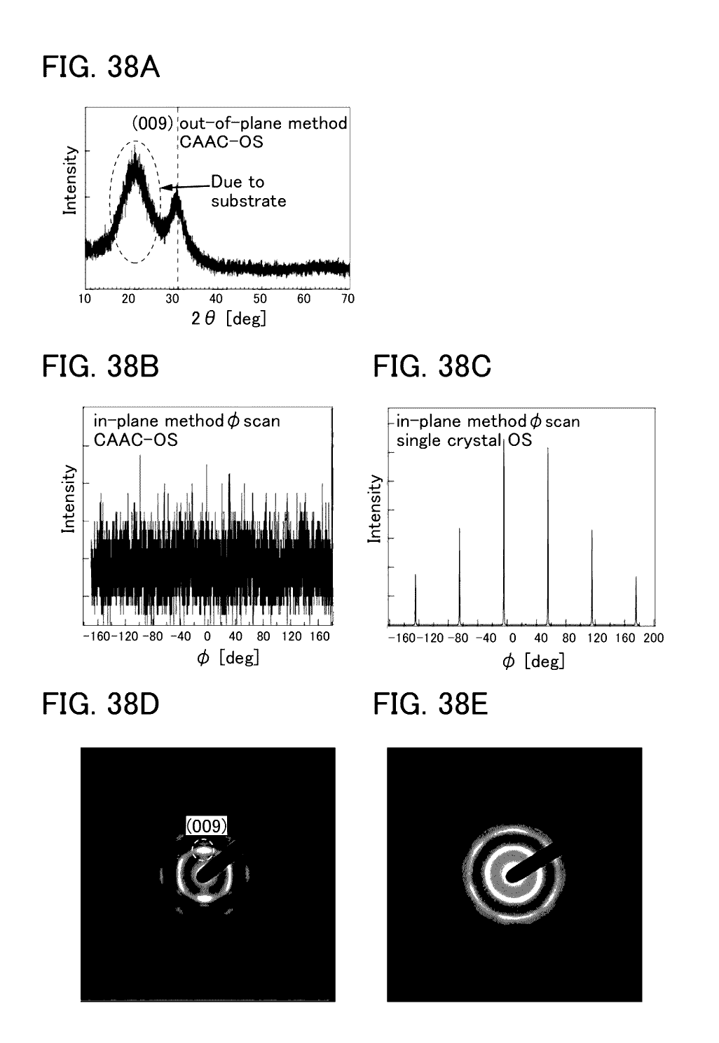

Analysis of a CAAC-OS by X-ray diffraction (XRD) is described. For example, when the structure of a CAAC-OS including an InGaZnO₄ crystal that is classified into the space group R-3m is analyzed by an out-of-plane method, a peak appears at a diffraction angle (2θ) of around 31° as shown in FIG. 38A. This peak is derived from the (009) plane of the InGaZnO₄ crystal, which indicates that crystals in the CAAC-OS have c-axis alignment, and that the c-axes are aligned in a direction substantially perpendicular to a surface over which the CAAC-OS film is formed (also referred to as a formation surface) or the top surface of the CAAC-OS film. Note that a peak sometimes appears at a 2θ of around 36° in addition to the peak at a 2θ of around 31°. The peak at 2θ of around 36° is attributed to a crystal structure classified into the space group Fd-3m; thus, this peak is preferably not exhibited in the CAAC-OS.

On the other hand, in structural analysis of the CAAC-OS by an in-plane method in which an X-ray is incident on the CAAC-OS in a direction parallel to the formation surface, a peak appears at a 2θ of around 56°. This peak is derived from the (110) plane of the InGaZnO₄ crystal. When analysis (φ scan) is performed with 2θ fixed at around 56° and with the sample rotated using a normal vector to the sample surface as an axis (φ axis), as shown in FIG. 38B, a peak is not clearly observed. In contrast, in the case where single crystal InGaZnO₄ is subjected to φ scan with 2θ fixed at around 56°, as shown in FIG. 38C, six peaks which are derived from crystal planes equivalent to the (110) plane are observed. Accordingly, the structural analysis using XRD shows that the directions of a-axes and b-axes are irregularly oriented in the CAAC-OS.

Next, a CAAC-OS analyzed by electron diffraction is described. For example, when an electron beam with a probe diameter of 300 nm is incident on a CAAC-OS including an InGaZnO₄ crystal in a direction parallel to the formation surface of the CAAC-OS, a diffraction pattern (also referred to as a selected-area electron diffraction pattern) shown in FIG. 38D can be obtained. In this diffraction pattern, spots derived from the (009) plane of an InGaZnO₄ crystal are included. Thus, the electron diffraction also indicates that pellets included in the CAAC-OS have c-axis alignment and that the c-axes are aligned in a direction substantially perpendicular to the formation surface or the top surface of the CAAC-OS. Meanwhile, FIG. 38E shows a diffraction pattern obtained in such a manner that an electron beam with a probe diameter of 300 nm is incident on the same sample in a direction perpendicular to the sample surface. As shown in FIG. 38E, a ring-like diffraction pattern is observed. Thus, the electron diffraction using an electron beam with a probe diameter of 300 nm also indicates that the a-axes and b-axes of the pellets included in the CAAC-OS do not have regular orientation. The first ring in FIG. 38E is considered to be derived from the (010) plane, the (100) plane, and the like of the InGaZnO₄ crystal. The second ring in FIG. 38E is considered to be derived from the (110) plane and the like.

In a combined analysis image (also referred to as a high-resolution TEM image) of a bright-field image and a diffraction pattern of a CAAC-OS, which is obtained using a transmission electron microscope (TEM), a plurality of pellets can be observed. However, even in the high-resolution TEM image, a boundary between pellets, that is, a grain boundary is not clearly observed in some cases. Thus, in the CAAC-OS, a reduction in electron mobility due to the grain boundary is less likely to occur.

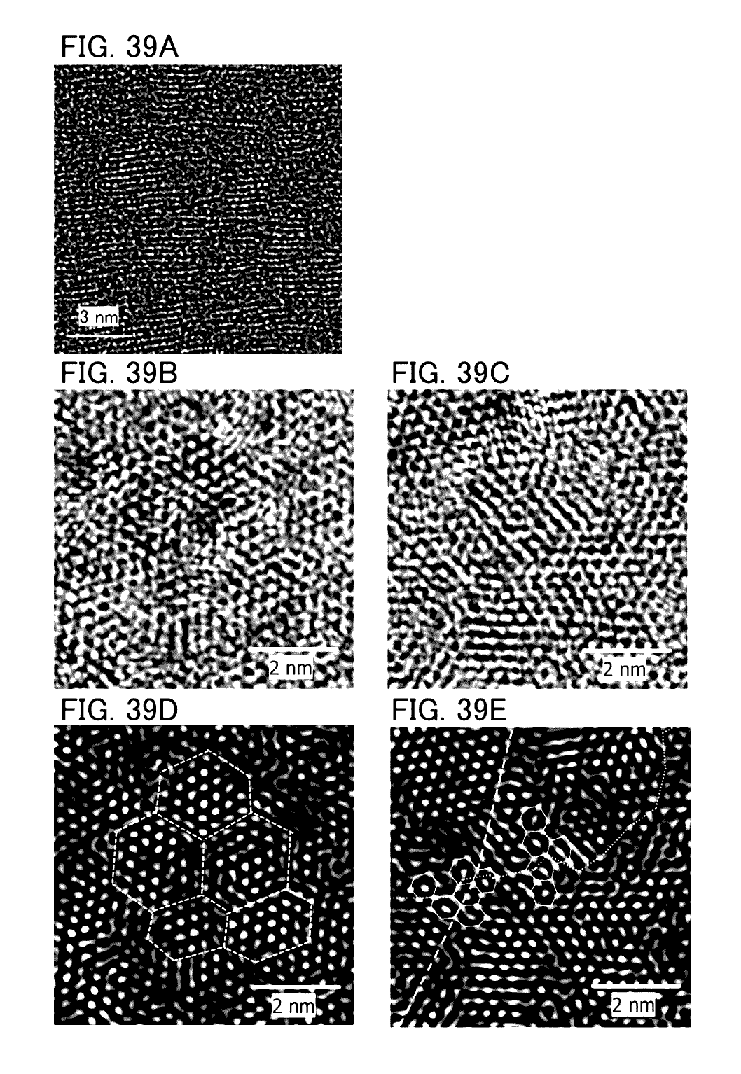

FIG. 39A shows a high-resolution TEM image of a cross section of the CAAC-OS which is observed from a direction substantially parallel to the sample surface. The high-resolution TEM image is obtained with a spherical aberration corrector function. The high-resolution TEM image obtained with a spherical aberration corrector function is particularly referred to as a Cs-corrected high-resolution TEM image. The Cs-corrected high-resolution TEM image can be observed with, for example, an atomic resolution analytical electron microscope JEM-ARM200F manufactured by JEOL Ltd.

FIG. 39A shows pellets in which metal atoms are arranged in a layered manner. FIG. 39A shows that the size of a pellet is greater than or equal to 1 nm or greater than or equal to 3 nm. Therefore, the pellet can also be referred to as a nanocrystal (nc). Furthermore, the CAAC-OS can also be referred to as an oxide semiconductor including c-axis aligned nanocrystals (CANC). A pellet reflects unevenness of a formation surface or a top surface of the CAAC-OS, and is parallel to the formation surface or the top surface of the CAAC-OS.

FIGS. 39B and 39C show Cs-corrected high-resolution TEM images of a plane of the CAAC-OS observed from a direction substantially perpendicular to the sample surface. FIGS. 39D and 39E are images obtained through image processing of FIGS. 39B and 39C. The method of image processing is as follows. The image in FIG. 39B is subjected to fast Fourier transform (FFT), so that an FFT image is obtained. Then, mask processing is performed such that a range of from 2.8 nm⁻¹ to 5.0 nm⁻¹ from the origin in the obtained FFT image remains. After the mask processing, the FFT image is processed by inverse fast Fourier transform (IFFT) to obtain a processed image. The image obtained in this manner is called an FFT filtering image. The FFT filtering image is a Cs-corrected high-resolution TEM image from which a periodic component is extracted, and shows a lattice arrangement.

In FIG. 39D, a portion where a lattice arrangement is broken is denoted with a dashed line. A region surrounded by a dashed line is one pellet. The portion denoted with the dashed line is a junction of pellets. The dashed line draws a hexagon, which means that the pellet has a hexagonal shape. Note that the shape of the pellet is not always a regular hexagon but is a non-regular hexagon in many cases.

In FIG. 39E, a dotted line denotes a portion between a region where a lattice arrangement is well aligned and another region where a lattice arrangement is well aligned, and a dashed line denotes the direction of the lattice arrangement. A clear crystal grain boundary cannot be observed even in the vicinity of the dotted line. When a lattice point in the vicinity of the dotted line is regarded as a center and surrounding lattice points are joined, a distorted hexagon, pentagon, and/or heptagon can be formed, for example. That is, a lattice arrangement is distorted so that formation of a crystal grain boundary is inhibited. This is probably because the CAAC-OS can tolerate distortion owing to a low density of the atomic arrangement in an a-b plane direction, an interatomic bond distance changed by substitution of a metal element, and the like.

As described above, the CAAC-OS has c-axis alignment, its pellets (nanocrystals) are connected in an a-b plane direction, and the crystal structure has distortion. For this reason, the CAAC-OS can also be referred to as an oxide semiconductor including a c-axis-aligned a-b-plane-anchored (CAA) crystal.

The CAAC-OS is an oxide semiconductor with high crystallinity. Entry of impurities, formation of defects, or the like might decrease the crystallinity of an oxide semiconductor. This means that the CAAC-OS has small amounts of impurities and defects (e.g., oxygen vacancies).

Note that the impurity means an element other than the main components of the oxide semiconductor, such as hydrogen, carbon, silicon, or a transition metal element. For example, an element (specifically, silicon or the like) having higher strength of bonding to oxygen than a metal element included in an oxide semiconductor extracts oxygen from the oxide semiconductor, which results in disorder of the atomic arrangement and reduced crystallinity of the oxide semiconductor. A heavy metal such as iron or nickel, argon, carbon dioxide, or the like has a large atomic radius (or molecular radius), and thus disturbs the atomic arrangement of the oxide semiconductor and decreases crystallinity.

The characteristics of an oxide semiconductor having impurities or defects might be changed by light, heat, or the like. Impurities contained in the oxide semiconductor might serve as carrier traps or carrier generation sources, for example. For example, an oxygen vacancy in the oxide semiconductor might serve as a carrier trap or serve as a carrier generation source when hydrogen is captured therein.

The CAAC-OS having small amounts of impurities and oxygen vacancies is an oxide semiconductor with low carrier density (specifically, lower than 8×10¹¹ cm⁻³, preferably lower than 1×10¹¹ cm⁻³, further preferably lower than 1×10¹⁰ cm⁻³, and is higher than or equal to 1×10⁻⁹ cm⁻³). Such an oxide semiconductor is referred to as a highly purified intrinsic or substantially highly purified intrinsic oxide semiconductor. A CAAC-OS has a low impurity concentration and a low density of defect states. Thus, the CAAC-OS can be referred to as an oxide semiconductor having stable characteristics.

<nc-OS>

Next, an nc-OS is described.

Analysis of an nc-OS by XRD is described. When the structure of an nc-OS is analyzed by an out-of-plane method, a peak indicating orientation does not appear. That is, a crystal of an nc-OS does not have orientation.

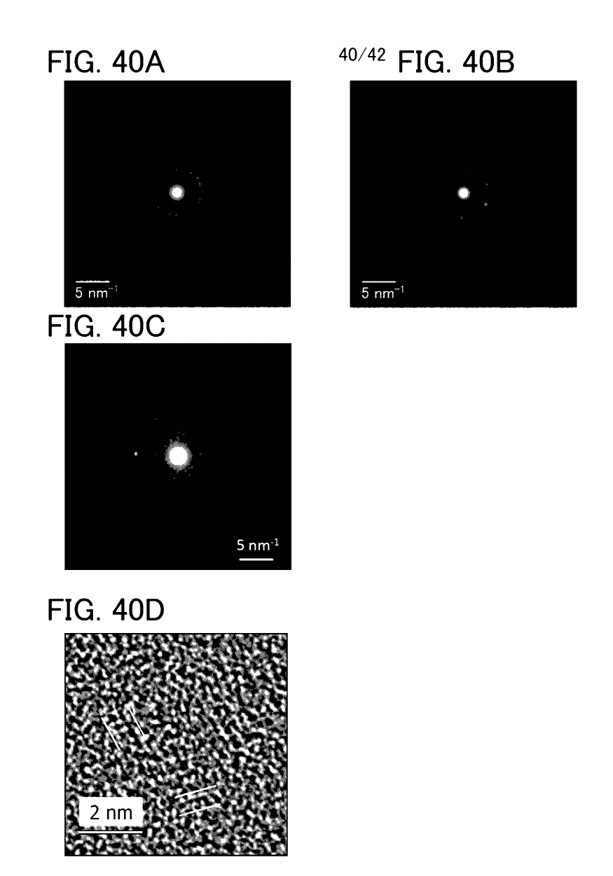

For example, when an electron beam with a probe diameter of 50 nm is incident on a 34-nm-thick region of thinned nc-OS including an InGaZnO₄ crystal in a direction parallel to the formation surface, a ring-shaped diffraction pattern (a nanobeam electron diffraction pattern) shown in FIG. 40A is observed. FIG. 40B shows a diffraction pattern obtained when an electron beam with a probe diameter of 1 nm is incident on the same sample. As shown in FIG. 40B, a plurality of spots are observed in a ring-like region. In other words, ordering in an nc-OS is not observed with an electron beam with a probe diameter of 50 nm but is observed with an electron beam with a probe diameter of 1 nm.

Furthermore, an electron diffraction pattern in which spots are arranged in an approximately regular hexagonal shape is observed in some cases as shown in FIG. 40C when an electron beam having a probe diameter of 1 nm is incident on a region with a thickness of less than 10 nm. This means that an nc-OS has a well-ordered region, i.e., a crystal, in the range of less than 10 nm in thickness. Note that an electron diffraction pattern having regularity is not observed in some regions because crystals are aligned in various directions.

FIG. 40D shows a Cs-corrected high-resolution TEM image of a cross section of an nc-OS observed from the direction substantially parallel to the formation surface. In a high-resolution TEM image, an nc-OS has a region in which a crystal part is observed, such as the part indicated by additional lines in FIG. 40D, and a region in which a crystal part is not clearly observed. In most cases, the size of a crystal part included in the nc-OS is greater than or equal to 1 nm and less than or equal to 10 nm, or specifically, greater than or equal to 1 nm and less than or equal to 3 nm. Note that an oxide semiconductor including a crystal part whose size is greater than 10 nm and less than or equal to 100 nm is sometimes referred to as a microcrystalline oxide semiconductor. For example, in a high-resolution TEM image of the nc-OS film, a grain boundary is not always found clearly. Note that there is a possibility that the origin of the nanocrystal is the same as that of a pellet in a CAAC-OS. Therefore, a crystal part of the nc-OS may be referred to as a pellet in the following description.

As described above, in the nc-OS, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different pellets in the nc-OS. Thus, the orientation of the whole film is not observed. Accordingly, the nc-OS cannot be distinguished from an a-like OS or an amorphous oxide semiconductor, depending on an analysis method.

Since there is no regularity of crystal orientation between the pellets (nanocrystals), the nc-OS can also be referred to as an oxide semiconductor including random aligned nanocrystals (RANC) or an oxide semiconductor including non-aligned nanocrystals (NANC).

The nc-OS is an oxide semiconductor that has high regularity as compared to an amorphous oxide semiconductor. Therefore, the nc-OS is likely to have a lower density of defect states than an a-like OS and an amorphous oxide semiconductor. Note that there is no regularity of crystal orientation between different pellets in the nc-OS. Therefore, the nc-OS has a higher density of defect states than the CAAC-OS.

### <A-Like OS>

An a-like OS has a structure between those of the nc-OS and the amorphous oxide semiconductor.

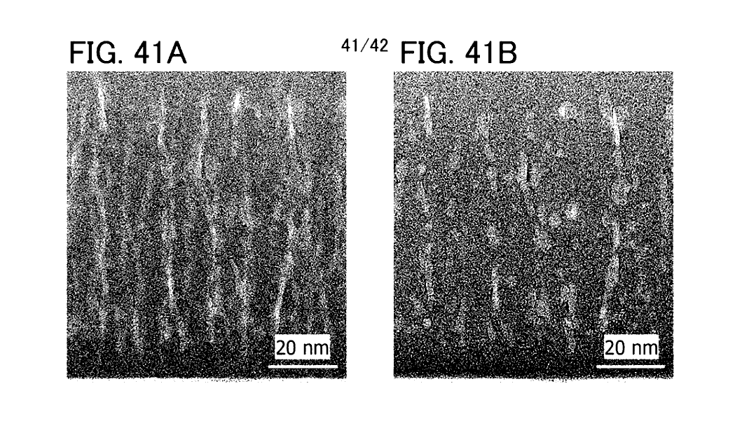

FIGS. 41A and 41B are high-resolution cross-sectional TEM images of an a-like OS. FIG. 41A is the high-resolution cross-sectional TEM image of the a-like OS at the start of the electron irradiation. FIG. 41B is the high-resolution cross-sectional TEM image of a-like OS after the electron (e⁻) irradiation at 4.3×10⁸ e⁻/nm². FIGS. 41A and 41B show that stripe-like bright regions extending vertically are observed in the a-like OS from the start of the electron irradiation. It can be also found that the shape of the bright region changes after the electron irradiation. Note that the bright region is presumably a void or a low-density region.

The a-like OS has an unstable structure because it includes a void. To verify that an a-like OS has an unstable structure as compared with a CAAC-OS and an nc-OS, a change in structure caused by electron irradiation is described below.

An a-like OS, an nc-OS, and a CAAC-OS are prepared as samples. Each of the samples is an In—Ga—Zn oxide.

First, a high-resolution cross-sectional TEM image of each sample is obtained. The high-resolution cross-sectional TEM images show that all the samples have crystal parts.

It is known that a unit cell of an InGaZnO₄ crystal has a structure in which nine layers including three In—O layers and six Ga—Zn—O layers are stacked in the c-axis direction. The distance between the adjacent layers is equivalent to the lattice spacing on the (009) plane (also referred to as d value). The value is calculated to be 0.29 nm from crystal structural analysis. Accordingly, a portion where the spacing between lattice fringes is greater than or equal to 0.28 nm and less than or equal to 0.30 nm is regarded as a crystal part of InGaZnO₄ in the following description. Each of lattice fringes corresponds to the a-b plane of the InGaZnO₄ crystal.

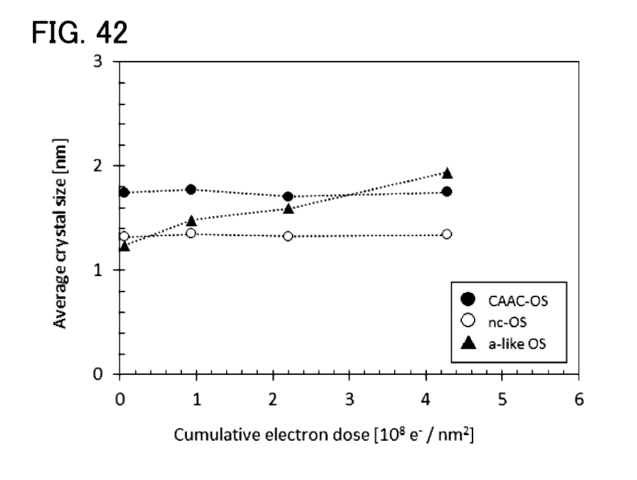

FIG. 42 shows change in the average size of crystal parts (at 22 points to 30 points) in each sample. Note that the crystal part size corresponds to the length of a lattice fringe. FIG. 42 indicates that the crystal part size in the a-like OS increases with an increase in the cumulative electron dose in obtaining TEM images, for example. As shown in FIG. 42, a crystal part of approximately 1.2 nm (also referred to as an initial nucleus) at the start of TEM observation grows to a size of approximately 1.9 nm at a cumulative electron (e) dose of 4.2×10⁸ e⁻/nm². In contrast, the crystal part size in the nc-OS and the CAAC-OS shows little change from the start of electron irradiation to a cumulative electron dose of 4.2×10⁸ e/nm². As shown in FIG. 42, the crystal part sizes in an nc-OS and a CAAC-OS are approximately 1.3 nm and approximately 1.8 nm, respectively, regardless of the cumulative electron dose. For the electron beam irradiation and TEM observation, a Hitachi H-9000NAR transmission electron microscope was used. The conditions of electron beam irradiations were as follows: the accelerating voltage was 300 kV; the current density was 6.7×10⁵ e⁻/(nm²·s); and the diameter of irradiation region was 230 nm.

In this manner, growth of the crystal part in the a-like OS is sometimes induced by electron irradiation. In contrast, in the nc-OS and the CAAC-OS, growth of the crystal part is hardly induced by electron irradiation. Therefore, the a-like OS has an unstable structure as compared with the nc-OS and the CAAC-OS.

The a-like OS has a lower density than the nc-OS and the CAAC-OS because it includes a void. Specifically, the density of the a-like OS is higher than or equal to 78.6% and lower than 92.3% of the density of the single crystal oxide semiconductor having the same composition. The density of each of the nc-OS and the CAAC-OS is higher than or equal to 92.3% and lower than 100% of the density of the single crystal oxide semiconductor having the same composition. Note that it is difficult to deposit an oxide semiconductor having a density of lower than 78% of the density of the single crystal oxide semiconductor.

For example, in the case of an oxide semiconductor having an atomic ratio of In:Ga:Zn=1:1:1, the density of single crystal InGaZnO₄ with a rhombohedral crystal structure is 6.357 g/cm³. Accordingly, in the case of the oxide semiconductor having an atomic ratio of In:Ga:Zn=1:1:1, the density of the a-like OS is higher than or equal to 5.0 g/cm³ and lower than 5.9 g/cm³. For example, in the case of the oxide semiconductor having an atomic ratio of In:Ga:Zn=1:1:1, the density of each of the nc-OS and the CAAC-OS is higher than or equal to 5.9 g/cm³ and lower than 6.3 g/cm³.

Note that in the case where an oxide semiconductor having a certain composition does not exist in a single crystal structure, single crystal oxide semiconductors with different compositions are combined at an adequate ratio, which makes it possible to calculate density equivalent to that of a single crystal oxide semiconductor with the desired composition. The density of a single crystal oxide semiconductor having the desired composition can be calculated using a weighted average according to the combination ratio of the single crystal oxide semiconductors with different compositions. Note that it is preferable to use as few kinds of single crystal oxide semiconductors as possible to calculate the density.

As described above, oxide semiconductors have various structures and various properties. Note that an oxide semiconductor may be a stacked layer including two or more of an amorphous oxide semiconductor, an a-like OS, an nc-OS, and a CAAC-OS, for example.

This embodiment can be combined with any of the other embodiments in this specification as appropriate.

(Supplementary Notes on the Description in this Specification and the Like)

The following are notes on the description of the structures in the above embodiments.

### <Notes on One Embodiment of the Present Invention Described in Embodiments>

One embodiment of the present invention can be constituted by appropriately combining the structure described in an embodiment with any of the structures described in the other embodiments. In addition, in the case where a plurality of structural examples is given in one embodiment, any of the structure examples can be combined as appropriate.

Note that what is described (or part thereof) in an embodiment can be applied to, combined with, or replaced with another content (or part thereof) in the same embodiment and/or what is described (or part thereof) in another embodiment or other embodiments.

Note that in each embodiment, a content described in the embodiment is a content described with reference to a variety of diagrams or a content described with a text described in this specification.

Note that by combining a diagram (or part thereof) illustrated in one embodiment with another part of the diagram, a different diagram (or part thereof) illustrated in the embodiment, and/or a diagram (or part thereof) illustrated in one or a plurality of different embodiments, much more diagrams can be formed.

### <Notes on Ordinal Numbers>

In this specification and the like, ordinal numbers such as first, second, and third are used in order to avoid confusion among components. Thus, the terms do not limit the number or order of components. In the present specification and the like, a “first” component in one embodiment can be referred to as a “second” component in other embodiments or claims. Furthermore, in the present specification and the like, a “first” component in one embodiment can be referred to without the ordinal number in other embodiments or claims.

### <Notes on the Description for Drawings>

Embodiments are described with reference to drawings. However, the embodiments can be implemented with various modes. It will be readily appreciated by those skilled in the art that modes and details can be changed in various ways without departing from the spirit and scope of the present invention. Thus, the present invention should not be interpreted as being limited to the description of the embodiments. Note that in the structures of the embodiments, the same portions or portions having similar functions are denoted by the same reference numerals in different drawings, and the description of such portions is not repeated.

In this specification and the like, terms for explaining arrangement, such as over and under, are used for convenience to describe the positional relation between components with reference to drawings. Furthermore, the positional relation between components is changed as appropriate in accordance with a direction in which the components are described. Therefore, the terms for explaining arrangement are not limited to those used in this specification and may be changed to other terms as appropriate depending on the situation.

The term “over” or “under” does not necessarily mean that a component is placed “directly above and in contact with” or “directly below and in contact with” another component. For example, the expression “electrode B over insulating layer A” does not necessarily mean that the electrode B is on and in direct contact with the insulating layer A and can mean the case where another component is provided between the insulating layer A and the electrode B.

Furthermore, in a block diagram in this specification and the like, components are functionally classified and shown by blocks that are independent from each other. However, in an actual circuit and the like, such components are sometimes hard to classify functionally, and there is a case in which one circuit is concerned with a plurality of functions or a case in which a plurality of circuits are concerned with one function. Therefore, the segmentation of a block in the block diagrams is not limited by any of the components described in the specification, and can be differently determined as appropriate depending on situations.

In drawings, the size, the layer thickness, or the region is determined arbitrarily for description convenience. Therefore, embodiments of the present invention are not limited to such a scale. Note that the drawings are schematically shown for clarity, and embodiments of the present invention are not limited to shapes or values shown in the drawings. For example, the following can be included: variation in signal, voltage, or current due to noise or difference in timing.

In drawings such as plan views (also referred to as layout views) and perspective views, some of components might not be illustrated for clarity of the drawings.

In the drawings, the same components, components having similar functions, components formed of the same material, or components formed at the same time are denoted by the same reference numerals in some cases, and the description thereof is not repeated in some cases.

<Notes on Expressions that can be Rephrased>

In this specification and the like, in describing connections of a transistor, expressions “one of a source and a drain” (or a first electrode or a first terminal) and “the other of the source and the drain” (or a second electrode or a second terminal) are used. This is because a source and a drain of a transistor are interchangeable depending on the structure, operation conditions, or the like of the transistor. Note that the source or the drain of the transistor can also be referred to as a source (or drain) terminal, a source (or drain) electrode, or the like as appropriate depending on the situation. In this specification and the like, two terminals except a gate are sometimes referred to as a first terminal and a second terminal or as a third terminal and a fourth terminal. In this specification and the like, in the case where a transistor has two or more gates, these gates are referred to as a first gate and a second gate or a front gate and a back gate in some cases. In particular, a “front gate” refers to a terminal (electrode) controlling a conduction state/non-conduction state between a source and a drain and a “back gate” refers to a terminal (electrode) controlling a threshold voltage of the transistor.

In addition, in this specification and the like, the term such as an “electrode” or a “wiring” does not limit a function of a component. For example, an “electrode” is used as part of a “wiring” in some cases, and vice versa. Further, the term “electrode” or “wiring” can also mean a combination of a plurality of “electrodes” and “wirings” formed in an integrated manner.

In this specification and the like, “voltage” and “potential” can be replaced with each other. The term “voltage” refers to a potential difference from a reference potential. When the reference potential is a ground potential, for example, “voltage” can be replaced with “potential.” The ground potential does not necessarily mean 0 V. Potentials are relative values, and the potential applied to a wiring or the like is changed depending on the reference potential, in some cases.

In this specification and the like, the terms “film,” “layer,” and the like can be interchanged with each other depending on the case or circumstances. For example, the term “conductive layer” can be changed into the term “conductive film” in some cases. Moreover, the term “insulating film” can be changed into the term “insulating layer” in some cases, or can be replaced with a word not including the term “film” or “layer.” For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “wiring,” “signal line,” “power supply line,” and the like can be interchanged with each other depending on circumstances or conditions. For example, the term “wiring” can be changed into the term such as “signal line” or “power supply line” in some cases. The term such as “signal line” or “power supply line” can be changed into the term “wiring” in some cases. The term such as “power supply line” can be changed into the term such as “signal line” in some cases. The term such as “signal line” can be changed into the term such as “power supply line” in some cases. The term “potential” that is applied to a wiring can be changed into the term “signal” or the like depending on circumstances or conditions. Inversely, the term “signal” or the like can be changed into the term “potential” in some cases.

<Notes on Definitions of Terms>

The following are definitions of the terms mentioned in the above embodiments.

### <<Semiconductor>>

In this specification, a “semiconductor” may have characteristics of an “insulator” in some cases when the conductivity is sufficiently low, for example. Further, a “semiconductor” and an “insulator” cannot be strictly distinguished from each other in some cases because a border between the “semiconductor” and the “insulator” is not clear. Accordingly, a “semiconductor” in this specification can be called an “insulator” in some cases. Similarly, an “insulator” in this specification can be called a “semiconductor” in some cases.

Further, a “semiconductor” includes characteristics of a “conductor” in some cases when the conductivity is sufficiently high, for example. Further, a “semiconductor” and a “conductor” cannot be strictly distinguished from each other in some cases because a border between the “semiconductor” and the “conductor” is not clear. Accordingly, a “semiconductor” in this specification can be called a “conductor” in some cases. Similarly, a “conductor” in this specification can be called a “semiconductor” in some cases.

Note that an impurity in a semiconductor refers to, for example, elements other than the main components of a semiconductor layer. For example, an element with a concentration of lower than 0.1 atomic % is an impurity. When an impurity is contained, the density of states (DOS) may be formed in a semiconductor, the carrier mobility may be decreased, or the crystallinity may be decreased, for example. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components; specific examples are hydrogen (included in water), lithium, sodium, silicon, boron, phosphorus, carbon, and nitrogen. In the case of an oxide semiconductor, oxygen vacancies may be formed by entry of impurities such as hydrogen. Furthermore, when the semiconductor is a silicon layer, examples of an impurity which changes the characteristics of the semiconductor include oxygen, Group 1 elements except hydrogen, Group 2 elements, Group 13 elements, and Group 15 elements.

### <<Transistor>>

In this specification, a transistor is an element having at least three terminals of a gate, a drain, and a source. The transistor includes a channel formation region between the drain (a drain terminal, a drain region, or a drain electrode) and the source (a source terminal, a source region, or a source electrode) and current can flow through the drain, the channel formation region, and the source. Note that in this specification and the like, a channel formation region refers to a region through which current mainly flows.

Further, functions of a source and a drain might be switched when transistors having different polarities are employed or a direction of current flow is changed in circuit operation, for example. Therefore, the terms “source” and “drain” can be switched in this specification and the like.

### <<Switch>>

In this specification and the like, a switch is in a conductive state (on state) or in a non-conductive state (off state) to determine whether current flows therethrough or not. Alternatively, a switch has a function of selecting and changing a current path.

For example, an electrical switch, a mechanical switch, or the like can be used as a switch. That is, any element can be used as a switch as long as it can control current, without limitation to a certain element.

Examples of the electrical switch are a transistor (e.g., a bipolar transistor or a MOS transistor), a diode (e.g., a PN diode, a PIN diode, a Schottky diode, a metal-insulator-metal (MIM) diode, a metal-insulator-semiconductor (MIS) diode, or a diode-connected transistor), and a logic circuit in which such elements are combined.

In the case of using a transistor as a switch, an “on state” of the transistor refers to a state in which a source electrode and a drain electrode of the transistor are electrically short-circuited. Furthermore, an “off state” of the transistor refers to a state in which the source electrode and the drain electrode of the transistor are electrically disconnected. In the case where a transistor operates just as a switch, the polarity (conductivity type) of the transistor is not particularly limited to a certain type.

An example of a mechanical switch is a switch formed using a technology of micro electro mechanical systems (MEMS), such as a digital micromirror device (DMD). Such a switch includes an electrode which can be moved mechanically, and operates by controlling conduction and non-conduction in accordance with movement of the electrode.

### <<Channel Length>>

In this specification and the like, the channel length refers to, for example, the distance between a source (source region or source electrode) and a drain (drain region or drain electrode) in a region where a semiconductor (or a portion where current flows in a semiconductor when a transistor is on) and a gate electrode overlap with each other or a region where a channel is formed in a top view of the transistor.

In one transistor, channel lengths in all regions are not necessarily the same. In other words, the channel length of one transistor is not limited to one value in some cases. Therefore, in this specification, the channel length is any one of values, the maximum value, the minimum value, or the average value, in a region where a channel is formed.

### <<Channel Width>>

In this specification and the like, the channel width refers to, for example, the length of a portion where a source and a drain face each other in a region where a semiconductor (or a portion where a current flows in a semiconductor when a transistor is on) and a gate electrode overlap with each other, or a region where a channel is formed in a top view of the transistor.

In one transistor, channel widths in all regions do not necessarily have the same value. In other words, a channel width of one transistor is not fixed to one value in some cases. Therefore, in this specification, the channel width is any one of values, the maximum value, the minimum value, or the average value, in a region where a channel is formed.

Note that depending on transistor structures, a channel width in a region where a channel is formed actually (hereinafter referred to as an effective channel width) is different from a channel width shown in a top view of a transistor (hereinafter referred to as an apparent channel width) in some cases. For example, in a transistor having a three-dimensional structure, an effective channel width is greater than an apparent channel width shown in a top view of the transistor, and its influence cannot be ignored in some cases. For example, in a miniaturized transistor having a three-dimensional structure, the proportion of a channel region formed in a side surface of a semiconductor is high in some cases. In that case, an effective channel width obtained when a channel is actually formed is greater than an apparent channel width shown in the top view.

In a transistor having a three-dimensional structure, an effective channel width is difficult to measure in some cases. For example, to estimate an effective channel width from a design value, it is necessary to assume that a semiconductor has a known shape. Therefore, in the case where the shape of a semiconductor is unclear, it is difficult to measure an effective channel width accurately.

Therefore, in this specification, in a top view of a transistor, an apparent channel width that is a length of a portion where a source and a drain face each other in a region where a semiconductor and a gate electrode overlap with each other is referred to as a surrounded channel width (SCW) in some cases. Furthermore, in this specification, in the case where the term “channel width” is simply used, it may represent a surrounded channel width or an apparent channel width. Alternatively, in this specification, in the case where the term “channel width” is simply used, it may represent an effective channel width in some cases. Note that the values of a channel length, a channel width, an effective channel width, an apparent channel width, a surrounded channel width, and the like can be determined by obtaining and analyzing a cross-sectional TEM image and the like.

Note that in the case where electric field mobility, a current value per channel width, and the like of a transistor are obtained by calculation, a surrounded channel width may be used for the calculation. In that case, a value different from one in the case where an effective channel width is used for the calculation is obtained in some cases.

### <<High-Level Potential and Low-Level Potential>>

In this specification, when there is a description saying that a high-level potential is applied to a wiring, the high-level potential sometimes means at least one of the following potentials: a potential high enough to turn on an n-channel transistor with a gate connected to the wiring; and a potential high enough to turn off a p-channel transistor with a gate connected to the wiring. Thus, when high-level potentials are applied to different two or more wirings, the high-level potentials applied to the wirings may be at different levels.

In this specification, when there is a description saying that a low-level potential is applied to a wiring, the low-level potential sometimes means at least one of the following potentials: a potential low enough to turn off an n-channel transistor with a gate connected to the wiring; and a potential low enough to turn on a p-channel transistor with a gate connected to the wiring. Thus, when low-level potentials are applied to different two or more wirings, the low-level potentials applied to the wirings may be at different levels.

### <<Connection>>

In this specification and the like, when it is described that X and Y are connected, the case where X and Y are electrically connected, the case where X and Y are functionally connected, and the case where X and Y are directly connected are included therein. Accordingly, a connection relation other than the predetermined connection relation, for example, a connection relation other than that shown in drawings and texts, is also allowed.

Here, X, Y, and the like each denote an object (e.g., a device, an element, a circuit, a wiring, an electrode, a terminal, a conductive film, a layer, or the like).

For example, in the case where X and Y are electrically connected, one or more elements that enable electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, a switch is conducting or not conducting (is turned on or off) to determine whether current flows therethrough or not.

For example, in the case where X and Y are functionally connected, one or more circuits that enable functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, and a buffer circuit; a signal generation circuit; a memory circuit; or a control circuit) can be connected between X and Y. Note that, for example, in the case where a signal output from X is transmitted to Y even when another circuit is interposed between X and Y, X and Y are functionally connected.

Note that when it is explicitly described that X and Y are electrically connected, the case where X and Y are electrically connected (i.e., the case where X and Y are connected with another element or another circuit provided therebetween), the case where X and Y are functionally connected (i.e., the case where X and Y are functionally connected with another circuit provided therebetween), and the case where X and Y are directly connected (i.e., the case where X and Y are connected without another element or another circuit provided therebetween) are included therein. That is, when it is explicitly described that “X and Y are electrically connected,” the description is the same as the case where it is explicitly only described that “X and Y are connected.”

Note that, for example, the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y, can be expressed by using any of the following expressions.

The expressions include, for example, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order,” “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order,” and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order.” When the connection order in a circuit configuration is defined by an expression similar to the above examples, a source (or a first terminal or the like) and a drain (or a second terminal or the like) of a transistor can be distinguished from each other to specify the technical scope. Note that these expressions are examples and there is no limitation on the expressions. Here, X, Y, Z1, and Z2 each denote an object (e.g., a device, an element, a circuit, a wiring, an electrode, a terminal, a conductive film, and a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

### <<Parallel and Perpendicular>>

In this specification, the term “parallel” indicates that the angle formed between two straight lines is greater than or equal to −10° and less than or equal to 10°, and accordingly also includes the case where the angle is greater than or equal to −5° and less than or equal to 5°. In addition, the term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°, and accordingly also includes the case where the angle is greater than or equal to 85° and less than or equal to 95°. The term “substantially perpendicular” indicates that the angle formed between two straight lines is greater than or equal to 60° and less than or equal to 120°.

### <<Trigonal and Rhombohedral>>

In this specification, trigonal and rhombohedral crystal systems are included in a hexagonal crystal system.

### EXPLANATION OF REFERENCE

NU[1]: neuron circuit, NU[2]: neuron circuit, NU[3]: neuron circuit, NU[4]: neuron circuit, NU[5]: neuron circuit, NU [k]: neuron circuit, NU[n−1]: neuron circuit, NU[n]: neuron circuit, NU[i]: neuron circuit, SU[1, 2]: synapse circuit, SU[1, 3]: synapse circuit, SU[1, k]: synapse circuit, SU[1, n−1]: synapse circuit, SU[1, n]: synapse circuit, SU[2, 1]: synapse circuit, SU[2, 3]: synapse circuit, SU[2, 4]: synapse circuit, SU[2, k]: synapse circuit, SU[2, n−1]: synapse circuit, SU[2, n]: synapse circuit, SU[3, 4]: synapse circuit, SU[3, 5]: synapse circuit, SU[4, 5]: synapse circuit, SU[4, 1]: synapse circuit, SU[5, 1]: synapse circuit, SU[5, 2]: synapse circuit, SU[k, 1]: synapse circuit, SU[k, 2]: synapse circuit, SU[k, n−1]: synapse circuit, SU[k, n]: synapse circuit, SU[n−1, 1]: synapse circuit, SU[n−1, 2]: synapse circuit, SU[n−1, k]: synapse circuit, SU[n−1, n]: synapse circuit, SU[n, 1]: synapse circuit, SU[n, 2]: synapse circuit, SU[n, k]: synapse circuit, SU[n, n−1]: synapse circuit, DIN[1]: external input signal, DIN[2]: external input signal, DIN[3]: external input signal, DIN[4]: external input signal, DIN[5]: external input signal, DIN[k]: external input signal, DIN[n−1]: external input signal, DIN[n]: external input signal, DIN[i]: external input signal, DOUT[1]: external output signal, DOUT[2]: external output signal, DOUT[3]: external output signal, DOUT[4]: external output signal, DOUT[5]: external output signal, DOUT[k]: external output signal, DOUT[n−1]: external output signal, DOUT[n]: external output signal, DOUT[i]: external output signal, S[1]: signal, S[2]: signal, S[k]: signal, S[n−1]: signal, S[n]: signal, S[i]: signal, S[j]: signal, I[j, i]: signal (current), I[i, j]: signal (current), NU-I: input neuron circuit portion, NU-H: hidden neuron circuit portion, NU-O: output neuron circuit portion, CRCT: circuit, CMP: comparator, R: resistor, SLCT: selector, FF: flip-flop circuit, D: input terminal, Q: output terminal, CK: clock signal, GND: ground potential, Vref: reference potential, AM: analog memory, RC: reset circuit, WCTL: writing control circuit, WGT[j, i]: weighting circuit, WGT[i, j]: weighting circuit, CP1: charge pump circuit, CP2: charge pump circuit, Aᵢₙ₁: internal input terminal, Aᵢₙ₂: internal input terminal, Aₒᵤₜ: internal output terminal, Bᵢₙ: internal input terminal, Bout: internal output terminal, Cᵢₙ₁: internal input terminal, Cᵢₙ₂: internal input terminal, Cₒᵤₜ₁: internal output terminal, Cₒᵤₜ₂: internal output terminal, Tr1: transistor, Tr2: transistor, Tr3: transistor, Tr4: transistor, Tr5: transistor, Tr6: transistor, Tr7: transistor, Tr8: transistor, Tr9: transistor, BG5: wiring, BG6: wiring, BG7: wiring, BG8: wiring, RESET: wiring, INV: inverter, Cl: capacitor, C2: capacitor, CW: capacitor, NA: node, LAC1: AND circuit, LAC2: AND circuit, LAC3: AND circuit, LG: logic circuit, VDD: potential, V0: potential, V00: potential, CTL1: control signal, CTL2: control signal, CTL3: control signal, S1-1: Step, S1-2: Step, S1-3: Step, S1-4: Step, S1-5: Step, S1-6: Step, S2-1: Step, S2-2: Step, S2-3: Step, S2-4: Step, S3-1: Step, S3-2: Step, S3-3: Step, S3-4: Step, DL_n: signal line, GL_m: scan line, RST: signal, SEL: signal, TX: signal, VL_a: potential supply line, VL_b: potential supply line, 10: image data, 11: triangle, 12: circle, 20: image data, 30: image data, 31: region, 40: image data, 41: region, 100: semiconductor device, 110: semiconductor device, 500: broadcast system, 510: camera, 511: transmitter, 512: receiver, 513: display device, 520: image sensor, 521: image processor, 522: encoder, 523: modulator, 525: demodulator, 526: decoder, 527: image processor, 528: display portion, 540: Raw data, 541: video data, 542: encoded data, 543: broadcast signal, 544: video data, 545: data signal, 551: data stream, 552: data stream, 553: data stream, 560: television receiver (TV), 561: broadcast station, 562: artificial satellite, 563: radio wave tower, 564: antenna, 565: antenna, 566A: radio wave, 566B: radio wave, 567A: radio wave, 567B: radio wave, 571: receiver, 572: wireless device, 573: wireless device, 574: receiver, 575: connector portion, 591: circuit, 591a: inter-frame prediction circuit, 591b: motion compensation prediction circuit, 591c: DCT circuit, 592: circuit, 593: circuit, 593a: LDPC encoding circuit, 593b: authentication processing circuit, 593c: scrambler, 594: circuit, 600: ambulance, 601: medical institution, 602: medical institution, 605: high-speed network, 610: camera, 611: encoder, 612: communication device, 615: video data, 616: image data, 620: communication device, 621: decoder, 623: display device, 701: photoelectric conversion element, 702: transistor, 703: transistor, 704: transistor, 705: transistor, 706: capacitor, 707: node, 708: wiring, 709: wiring, 710: pixel driver, 711: wiring, 721: pixel portion, 722: pixel, 723: pixel, 724: filter, 724R: filter, 724G: filter, 724B: filter, 725: lens, 726: wiring group, 730: light, 760: circuit, 770: circuit, 780: circuit, 790: circuit, 1400a: transistor, 1400b: transistor, 1400c: transistor, 1400d: transistor, 1400e: transistor, 1400f: transistor, 1401: insulating film, 1402: insulating film, 1403: insulating film, 1404: insulating film, 1405: insulating film, 1406: insulating film, 1407: insulating film, 1408: insulating film, 1409: insulating film, 1411: conductive film, 1412: conductive film, 1413: conductive film, 1414: conductive film, 1415: opening, 1421: conductive film, 1422: conductive film, 1423: conductive film, 1424: conductive film, 1430: metal oxide, 1431: metal oxide, 1431a: metal oxide, 1431b: metal oxide, 1431c: metal oxide, 1432: metal oxide, 1432a: metal oxide, 1432b: metal oxide, 1432c: metal oxide, 1433: metal oxide, 1441: region, 1442: region, 1450: substrate, 1451: low-resistance region, 1452: low-resistance region, 1461: region, 1461a: region, 1461b: region, 1461c: region, 1461d: region, 1461e: region, 1462: region, 1463: region, 1680: transistor, 1681: insulating film, 1682: semiconductor, 1683: conductive film, 1684: conductive film, 1685: insulating film, 1686: insulating film, 1687: insulating film, 1688: conductive film, 1689: conductive film, 3100: display portion, 3125: light-emitting element, 3130: pixel, 3130B: pixel, 3130C: pixel, 3131: display area, 3132: circuit, 3133: circuit, 3135: scan line, 3136: signal line, 3232: transistor, 3233: capacitor, 3431: transistor, 3432: liquid crystal element, 3434: transistor, 3436: node, 4000A: display panel, 4000B: display panel, 4001: substrate, 4002: pixel portion, 4003: signal line driver, 4004: scan line driver, 4005: sealant, 4006: substrate, 4008: liquid crystal layer, 4010: transistor, 4011: transistor, 4012: semiconductor layer, 4013: liquid crystal element, 4014: wiring, 4015: electrode, 4017: electrode, 4018: FPC, 4018a: FPC, 4018b: FPC, 4019: anisotropic conductive layer, 4020: capacitor, 4021: electrode, 4030: electrode layer, 4031: electrode layer, 4032: insulating layer, 4033: insulating layer, 4035: spacer, 4103: insulating layer, 4110: insulating layer, 4111: insulating layer, 4112: insulating layer, 4510: bank, 4511: light-emitting layer, 4513: light-emitting element, 4514: filler, 6000: display module, 6001: upper cover, 6002: lower cover, 6003: FPC, 6004: touch sensor, 6005: FPC, 6006: display panel, 6007: backlight unit, 6008: light source, 6009: frame, 6010: printed board, 6011: battery, 7000: display device, 7001: housing, 7002: display portion, 7003: support base, 7100: portable information terminal, 7101: housing, 7102: display portion, 7103: band, 7104: buckle, 7105: operation button, 7106: input/output terminal, 7107: icon, 7200: PC, 7221: housing, 7222: display portion, 7223: keyboard, 7224: pointing device, 7400: mobile phone, 7401: housing, 7402: display portion, 7403: operation button, 7404: external connection port, 7405: speaker, 7406: microphone, 7500: car, 7551: car body, 7552: wheel, 7553: dashboard, 7554: light, 7600: video camera, 7641: first housing, 7642: second housing, 7643: display portion, 7644: operation key, 7645: lens, and 7646: joint.

This application is based on Japanese Patent Application serial no. 2015-170829 filed with Japan Patent Office on Aug. 31, 2015, the entire contents of which are hereby incorporated by reference.

1. A semiconductor device comprising first to fourth circuits,
wherein the first circuit comprises a first charge pump circuit, a second charge pump circuit, an analog memory, and a logic circuit,
wherein the first charge pump circuit and the second charge pump circuit each include a first transistor,
wherein the first transistor comprises an oxide semiconductor in a channel formation region,
wherein the logic circuit comprises a first input terminal, a second input terminal, a first output terminal, and a second output terminal,
wherein the second circuit comprises a third input terminal and a third output terminal,
wherein the third circuit has a same circuit structure as the second circuit,
wherein the third circuit comprises a fourth input terminal and a fourth output terminal,
wherein the fourth circuit comprises a fifth input terminal, a sixth input terminal, and a fifth output terminal,
wherein the first input terminal is electrically connected to the fifth input terminal and the third output terminal,
wherein the second input terminal is electrically connected to the fourth output terminal,
wherein the first output terminal is electrically connected to the first charge pump circuit,
wherein the second output terminal is electrically connected to the second charge pump circuit,
wherein the analog memory is electrically connected to the first charge pump circuit, the second charge pump circuit, and the sixth input terminal, and
wherein the fifth output terminal is electrically connected to the fourth input terminal.

2. The semiconductor device according to claim 1, further comprising a fifth circuit,
wherein the fifth circuit has a same circuit structure as the fourth circuit,
wherein the fifth circuit comprises a seventh input terminal, an eighth input terminal, and a sixth output terminal,
wherein the seventh input terminal is electrically connected to the second input terminal and the fourth output terminal,
wherein the eighth input terminal is electrically connected to the sixth input terminal and the analog memory, and
wherein the sixth output terminal is electrically connected to the third input terminal.

3. The semiconductor device according to claim 1,
wherein the fourth circuit comprises second to fifth transistors and an inverter,
wherein a first terminal of the second transistor is electrically connected to a first terminal of the third transistor,
wherein a first terminal of the fourth transistor is electrically connected to a first terminal of the fifth transistor,
wherein a gate of the third transistor is electrically connected to an input terminal of the inverter and the fifth input terminal,
wherein a gate of the fourth transistor is electrically connected to the sixth input terminal, and
wherein a gate of the fifth transistor is electrically connected to an output terminal of the inverter.

4. The semiconductor device according to claim 1,
wherein the fourth circuit comprises second to fifth transistors and an inverter,
wherein a first terminal of the second transistor is electrically connected to a first terminal of the third transistor,
wherein a first terminal of the fourth transistor is electrically connected to a first terminal of the fifth transistor,
wherein a gate of the third transistor is electrically connected to an output terminal of the inverter,
wherein a gate of the fourth transistor is electrically connected to the sixth input terminal, and
wherein a gate of the fifth transistor is electrically connected to an input terminal of the inverter and the fifth input terminal.

5. The semiconductor device according to claim 1,
wherein the second circuit comprises a resistor, a comparator, a flip-flop circuit, and a selector,
wherein an output terminal of the flip-flop circuit is electrically connected to a first input terminal of the selector,
wherein a non-inverting input terminal of the comparator is electrically connected to the resistor and the third input terminal,
wherein an output terminal of the comparator is electrically connected to a second input terminal of the selector, and
wherein an output terminal of the selector is electrically connected to the third output terminal.

6. The semiconductor device according to claim 1, wherein the first transistor comprises a back gate.

7. The semiconductor device according to claim 1, further comprising a sixth transistor,
wherein a first terminal of the sixth transistor is electrically connected to an analog memory.

8. An electronic device comprising an encoder configured to encode video data with the semiconductor device according to claim 1,
wherein the video data comprises first data and second data,
wherein the semiconductor device compares the first data and the second data when the first data and the second data are input to the semiconductor device, and
wherein a displacement vector from the first data to the second data is obtained when the first data and the second data match.

9. A semiconductor device comprising first to fourth circuits,
wherein the first circuit comprises a first charge pump circuit, a second charge pump circuit, an analog memory, and a logic circuit,
wherein the first charge pump circuit and the second charge pump circuit each include a first transistor, a second transistor, and a capacitor,
wherein the first transistor comprises an oxide semiconductor in a channel formation region,
wherein the second transistor comprises an oxide semiconductor in a channel formation region,
wherein a first terminal of the first transistor and a first terminal of the second transistor are electrically connected to a first terminal of the capacitor,
wherein the logic circuit comprises a first input terminal, a second input terminal, a first output terminal, and a second output terminal,
wherein the second circuit comprises a third input terminal and a third output terminal,
wherein the third circuit has a same circuit structure as the second circuit,
wherein the third circuit comprises a fourth input terminal and a fourth output terminal,
wherein the fourth circuit comprises a fifth input terminal, a sixth input terminal, and a fifth output terminal,
wherein the first input terminal is electrically connected to the fifth input terminal and the third output terminal,
wherein the second input terminal is electrically connected to the fourth output terminal,
wherein the first output terminal is electrically connected to the first charge pump circuit,
wherein the second output terminal is electrically connected to the second charge pump circuit,
wherein the analog memory is electrically connected to the first charge pump circuit, the second charge pump circuit, and the sixth input terminal, and
wherein the fifth output terminal is electrically connected to the fourth input terminal.

10. The semiconductor device according to claim 9, further comprising a fifth circuit,
wherein the fifth circuit has a same circuit structure as the fourth circuit,
wherein the fifth circuit comprises a seventh input terminal, an eighth input terminal, and a sixth output terminal,
wherein the seventh input terminal is electrically connected to the second input terminal and the fourth output terminal,
wherein the eighth input terminal is electrically connected to the sixth input terminal and the analog memory, and
wherein the sixth output terminal is electrically connected to the third input terminal.

11. The semiconductor device according to claim 9,
wherein the fourth circuit comprises second to fifth transistors and an inverter,
wherein a first terminal of the second transistor is electrically connected to a first terminal of the third transistor,
wherein a first terminal of the fourth transistor is electrically connected to a first terminal of the fifth transistor,
wherein a gate of the third transistor is electrically connected to an input terminal of the inverter and the fifth input terminal,
wherein a gate of the fourth transistor is electrically connected to the sixth input terminal, and
wherein a gate of the fifth transistor is electrically connected to an output terminal of the inverter.

12. The semiconductor device according to claim 9,
wherein the fourth circuit comprises second to fifth transistors and an inverter,
wherein a first terminal of the second transistor is electrically connected to a first terminal of the third transistor,
wherein a first terminal of the fourth transistor is electrically connected to a first terminal of the fifth transistor,
wherein a gate of the third transistor is electrically connected to an output terminal of the inverter,
wherein a gate of the fourth transistor is electrically connected to the sixth input terminal, and
wherein a gate of the fifth transistor is electrically connected to an input terminal of the inverter and the fifth input terminal.

13. The semiconductor device according to claim 9,
wherein the second circuit comprises a resistor, a comparator, a flip-flop circuit, and a selector,
wherein an output terminal of the flip-flop circuit is electrically connected to a first input terminal of the selector,
wherein a non-inverting input terminal of the comparator is electrically connected to the resistor and the third input terminal,
wherein an output terminal of the comparator is electrically connected to a second input terminal of the selector, and
wherein an output terminal of the selector is electrically connected to the third output terminal.

14. The semiconductor device according to claim 9, wherein the first transistor comprises a back gate.

15. The semiconductor device according to claim 9, further comprising a sixth transistor,
wherein a first terminal of the sixth transistor is electrically connected to an analog memory.

16. An electronic device comprising an encoder configured to encode video data with the semiconductor device according to claims 9,
wherein the video data comprises first data and second data,
wherein the semiconductor device compares the first data and the second data when the first data and the second data are input to the semiconductor device, and
wherein a displacement vector from the first data to the second data is obtained when the first data and the second data match.
